(19) United States
(12) Patent Application Publication
(10) Pub. No.: US 2009/0111050 A1
(43) Pub. Date: Apr. 30, 2009

(54) Novel Photosensitive Resin Compositions

(76) Inventors: Ahmad A. Naiini, East Greenwich, RI (US); William Weber, East Providence, RI (US)

Correspondence Address: FISH & RICHARDSON PC, P.O. BOX 1022, MINNEAPOLIS, MN, 55440-1022, US

(21) Appl. No.: 12/252,203

(22) Filed: Oct. 15, 2008

Related U.S. Application Data
(60) Provisional application No. 60/999,168, filed on Oct. 16, 2007.
(60) Provisional application No. 61/033,857, filed on Mar. 5, 2008.

(51) Int. Cl. G03F 7/028; G03F 7/004; G03F 7/20; C08G 77/14

(52) U.S. Cl. 430/283.1; 430/270.1; 430/322; 430/325; 528/26

(57) ABSTRACT

This disclosure relates to compositions that include (a) at least one polybenzoxazole precursor polymer; and (b) at least one silicon-containing polymer comprising a moiety of Structure (V):

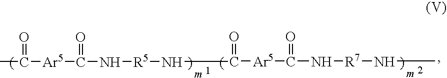

in which R⁵, R⁷, Ar⁵, m¹, and m² are defined in the specification.

### RELATED APPLICATIONS

This application claims priority from U.S. Provisional Patent Application No. 60/999,168, filed Oct. 16, 2007 and U.S. Provisional Patent Application No. 61/033,857, filed Mar. 5, 2008. The contents of the prior applications are hereby incorporated by reference.

### FIELD OF THE INVENTION

The present disclosure relates to buffer coat resin compositions, as well as related polymers, articles, devices, and processes. More specifically, the present disclosure relates to positive tone photosensitive buffer coat resin compositions, processes of using the compositions, and electronic parts produced by these processes.

### BACKGROUND OF THE INVENTION

Positive-working photosensitive polybenzoxazole precursor compositions have found applications in the microelectronic industry as dielectric and protective coatings in the fabrication of integrated circuit devices and integrated circuit packaging structures. A common feature of these applications is the need to process the photosensitive compositions on substrates that are hybrid structures of silicon, silicon oxide, silicon nitride, or silicate glasses with patterned metallic conductors fabricated on their surface. Such metallic conductors may be made of aluminum, copper, silver, gold, chromium, tantalum, titanium, aluminum-copper alloys, or aluminum-copper-silicon alloys. The photosensitive compositions must have good adhesion to all substrate materials in order to function as dielectric and protective coatings. In addition, hybrid structures bearing relief images fabricated from the photosensitive compositions are frequently subjected to a variety of subsequent process steps, many of which result in exposure of the construction to aggressive chemicals such as solutions containing hydrofluoric acid, alkanolamine based cleaners, and metal plating solutions that can degrade coating adhesion.

Positive-working photosensitive polybenzoxazole precursor compositions are typically low-contrast imaging systems due to solubility of the unexposed film in aqueous base developers. The solubility of the unexposed film results in film thickness loss during image development and can potentially result in adhesion loss at the substrate to film interface of the relief images, as well as other stresses and other problems caused by the decrease in film thickness. Accordingly, it is desirable to provide a means to obtain excellent adhesion of the coating composition to all substrate materials while limiting unexposed film loss during the imaging process.

This disclosure describes positive working photosensitive polybenzoxazole precursor compositions containing a silicon containing polymer having improved adhesion and lower unexposed film loss during the imaging process.

### SUMMARY OF THE INVENTION

In one aspect, the present disclosure features a composition that includes at least one polybenzoxazole (PBO) precursor polymer and at least one silicon-containing polymer. The silicon-containing polymer includes a moiety of Structure (V):

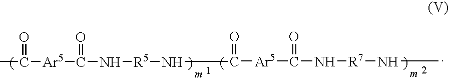

In Structure (V), each R⁵ in a monomer repeat unit independently is

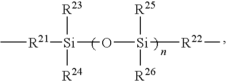

in which each R²¹ and each R²² in a monomer repeat unit independently are a divalent aliphatic or aromatic group, each R²³, each R²⁴, each R²⁵ and each R²⁶ in a monomer repeat unit independently are a monovalent aliphatic or aromatic group, and n is an integer of 1-100; each R⁷ in a monomer repeat unit is a non-silicon containing divalent aromatic group, a non-silicon containing divalent aliphatic group, a non-silicon containing divalent heterocyclic group, or mixtures thereof; each Ar⁵ in a monomer repeat unit is a divalent aromatic group, a divalent aliphatic group, a divalent heterocyclic group, or mixtures thereof; m¹ is an integer of 5-1000; and m² is an integer of 0-500. In some embodiments, Ar⁵ is not a divalent aromatic group substituted with a carboxylic acid group. The composition can further include a photoactive compound (e.g., a diazonaphthquinone compound or a photoacid generator compound). For example, when the PBO precursor polymer does not contain a photoactive moiety on the polymer, the composition further includes at least one photoactive compound. The composition can also include a solvent.

The silicon-containing polymer can include a non-endcapped polymer of Structure (V), an endcapped polymer of Structure (VI):

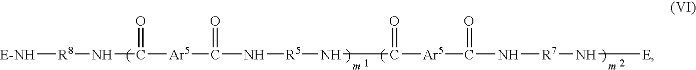

or an endcapped polymer of Structure (VI*):

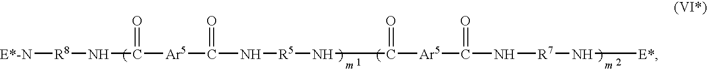

in which R⁸ is R⁵ or R⁷, E is a monovalent organic group (e.g., a carbonyl, carbonyloxy, or sulfonyl group), and E* is a divalent organic group (e.g., E*, together with the nitrogen atom to which it is attached, is an imide group).

The PBO precursor polymer can be of Structure (I), (II), (III), (III*), (IV), or (IV*):

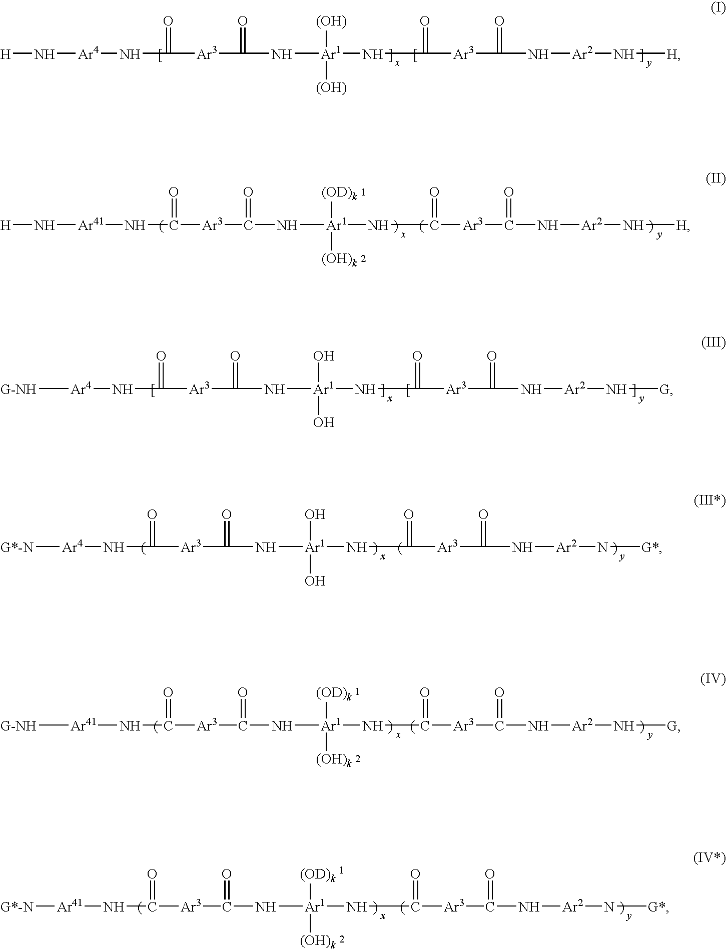

in which each Ar¹ in a monomer repeat unit independently can be a tetravalent aromatic group, a tetravalent heterocyclic group, or mixtures thereof; each Ar² in a monomer repeat unit independently can be a divalent aromatic, divalent heterocyclic, divalent alicyclic, or divalent aliphatic group that optionally contains silicon; each Ar³ in a monomer repeat unit independently can be a divalent aromatic group, a divalent aliphatic group, a divalent heterocyclic group, or mixtures thereof; Ar⁴ can be Ar¹(OH)₂ or Ar²; Ar⁴¹ is Ar¹(OH)₂, Ar¹(OD)ₖ¹(OH)ₖ², or Ar²; x can be from about 4 to about 1000; y can be from 0 to about 900; k¹ can be a positive number of up to about 0.5; k² can be a number from about 1.5 to about 2 provided that (k¹+k²)=2; G can be a monovalent organic group having a carbonyl, carbonyloxy or sulfonyl group; G* can be a divalent organic group having at least one carbonyl or sulfonyl group; and each D in a monomer repeat unit independently can be one of the following moieties:

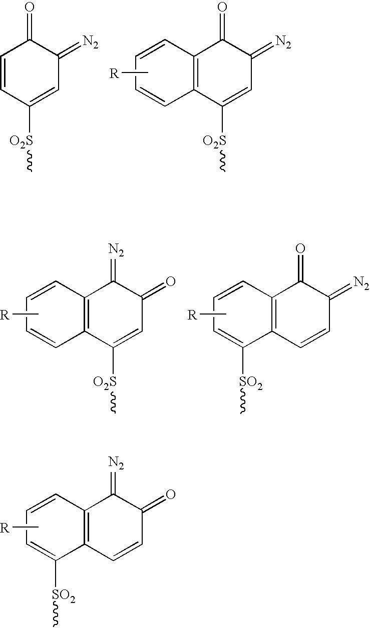

in which R can be a hydrogen atom, a halogen, a C₁-C₄ alkyl group, a C₁-C₄ alkoxy group, cyclopentyl, or cyclohexyl. In such embodiments, the composition can further include a solvent and/or a diazonaphthquinone compound as a photoactive compound.

The PBO precursor polymer can also be of Structure (XV), (XVI), or (XVI*):

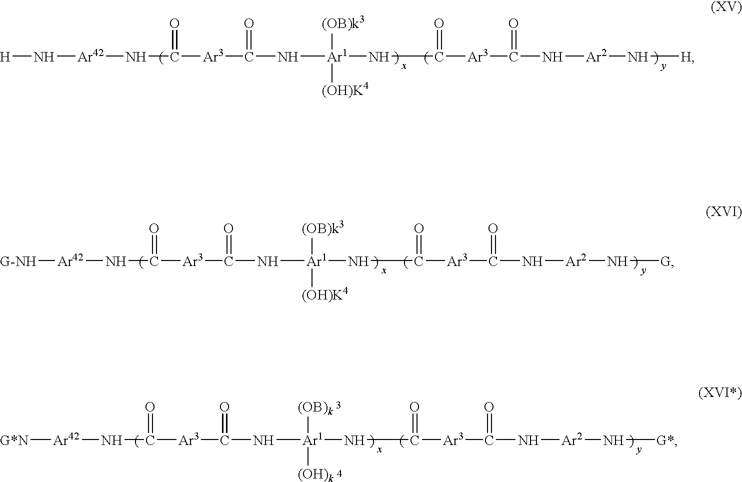

in which each Ar¹ in a monomer repeat unit independently can be a tetravalent aromatic group, a tetravalent heterocyclic group, or mixtures thereof; each Ar² in a monomer repeat unit independently can be a divalent aromatic, divalent heterocyclic, divalent alicyclic, or divalent aliphatic group that optionally contains silicon; each Ar³ in a monomer repeat unit independently can be a divalent aromatic group, a divalent aliphatic group, a divalent heterocyclic group, or mixtures thereof; Ar⁴² can be Ar¹(OB)ₖ³(OH)ₖ⁴ or Ar²; x can be an integer from about 4 to about 1000; y can be an integer from 0 to about 500 provided that x+y≦1000; each B in a monomer repeat unit independently can be an acid sensitive group R²⁷ or a moiety A-O—R²⁸, in which R²⁸ can be an acid sensitive group; A can be a divalent aromatic, aliphatic or heterocyclic group which is not acid labile and makes an -A-OH moiety an alkali solubilizing group; k³ can be a number between 0.1 and 2; k⁴ can be a number between 0 and 1.9 provided that k³+k⁴=2; G can be a monovalent organic group having a carbonyl, carbonyloxy or sulfonyl group; and G* can be a divalent organic group having at least one carbonyl or sulfonyl group. In such embodiments, the composition can further include a solvent and/or a photoacid generator compound as a photoactive compound.

In another aspect, the present disclosure features a composition that includes at least one polybenzoxazole precursor polymer described above and at least one silicon-containing polymer of Structure (VI) or (VI*):

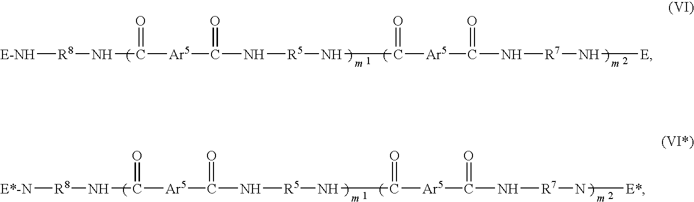

in which each R⁵ in a monomer repeat unit independently can be

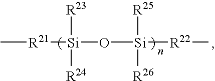

in which each R²¹ and each R²² in a monomer repeat unit independently can be a divalent aliphatic or aromatic group, each R²³, each R²⁴, each R²⁵ and each R²⁶ in a monomer repeat unit independently can be a monovalent aliphatic or aromatic group, and n is an integer of 1-100; each R⁷ in a monomer repeat unit can be a non-silicon containing divalent aromatic group, a non-silicon containing divalent aliphatic group, a non-silicon containing divalent heterocyclic group, or mixtures thereof; each Ar⁵ in a monomer repeat unit can be a divalent aromatic group, a divalent aliphatic group, a divalent heterocyclic group, or mixtures thereof; E can be a monovalent organic group; E* can be a divalent organic group; m¹ can be an integer of 5-1000; and m² can be an integer of 0-500.

In another aspect, the present disclosure features a composition that includes at least one PBO precursor polymer of Structure (XV), (XVI), or (XVI*) described above and at least one silicon-containing polymer comprising a moiety of Structure (V):

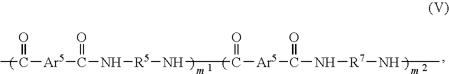

in which each R⁵ in a monomer repeat unit independently can be

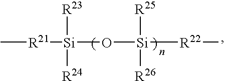

in which each R²¹ and each R²² in a monomer repeat unit independently can be a divalent aliphatic or aromatic group, each R²³, each R²⁴, each R²⁵ and each R²⁶ in a monomer repeat unit independently can be a monovalent aliphatic or aromatic group, and n can be an integer of 1-100; each R⁷ in a monomer repeat unit independently can be a non-silicon containing divalent aromatic group, a non-silicon containing divalent aliphatic group, a non-silicon containing divalent heterocyclic group, or mixtures thereof; R⁸ can be R⁵ or R⁷; each Ar⁵ in a monomer repeat unit independently can be a divalent aromatic group, a divalent aliphatic group, a divalent heterocyclic group, or mixtures thereof; E can be a monovalent organic group; E* can be a divalent organic group; m¹ can be an integer of 5-1000; and m² can be an integer of 0-500. The silicon-containing polymer can include a non-endcapped polymer of Structure (V), an endcapped polymer of Structure (VI), or an endcapped polymer of Structure (VI*).

In another aspect, the present disclosure features a composition that includes at least one polybenzoxazole precursor polymer and at least one silicon-containing polymer having a moiety of Structure (V), in which R⁵ can be

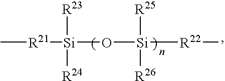

in which R²¹ and R²² can be each independently a divalent aliphatic or aromatic group, R²³, R²⁴, R²⁵ and R²⁶ can each be independently a monovalent aliphatic or aromatic group, and n is an integer of 1-100; R⁷ can be a non-silicon containing divalent aromatic group, a non-silicon containing divalent aliphatic group, a non-silicon containing divalent heterocyclic group, or mixtures thereof; Ar⁵ can be a divalent aromatic group, a divalent aliphatic group, a divalent heterocyclic group, or mixtures thereof; m¹ can be an integer of 5-1000; and m² can be an integer of 0-500.

In the silicon-containing polymers described above, R²⁵ in one siloxane unit in R⁵ can be different from R²⁵ in another siloxane unit or R²⁶ in one siloxane unit in R⁵ is different from R²⁶ in another siloxane unit. In such embodiments, R⁵ can be

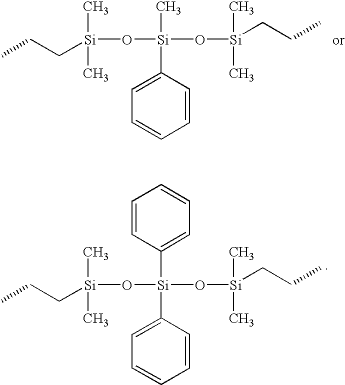

In another aspect, the present disclosure features an article that includes a substrate and a buffer coat supported by the substrate. The buffer coat can be prepared by one or more of the compositions described above.

The buffer coat can have less than about 5% (e.g., less than about 1% or less than about 0.1%) of adhesion loss when subjecting to a tape peel test according to the procedure described in ASTM-3359. The article can be semiconductor devices, such as semiconductor chips or interlayer dielectrics.

In a further aspect, the present disclosure features an article that includes a substrate and a buffer coat supported by the substrate. The buffer coat includes a polybenzoxazole polymer and a silicon-containing polymer, and has less than about 5% (e.g., less than about 1% or less than about 0.1%) of adhesion loss when subjecting to a tape peel test according to the procedure described in ASTM-3359.

In still another aspect, the present disclosure features a method that includes treating one of the compositions described above on a substrate to form a relief image on the substrate. The method can further include applying the composition to the substrate prior to treating the composition. Treating the composition can further include baking the composition to form a baked composition; exposing the baked composition to actinic radiation to form an exposed composition; developing the exposed composition with an aqueous developer, thereby forming an uncured relief image on the substrate; and curing the uncured relief image.

In still another aspect, the present disclosure features a composition containing at least one polyamic acid and at least one silicon-containing polymer having a moiety of Structure (V) described above, as well as a method treating this composition on a substrate to form a relief image on the substrate.

In yet another aspect, the present disclosure features a polymer of Structure (VI) or (VI*) described above.

Optionally, the photosensitive composition may contain other additives, which may include photosensitizers, basic compounds, surfactants, dyes, adhesion promoters, and leveling agents.

The present disclosure also relates to processes for preparing heat-resistant relief structures from the aforementioned positive working photosensitive compositions and the articles of manufacture obtained by the combination of the compositions and the methods of use according to the disclosure.

A heat resistant positive working photosensitive composition can be spin-coated on a substrate to create a film, which can then be subjected to patterning through a photolithographic process. After photolithographic processing, the patterned film can be converted to a heat resistant polybenzoxazole relief image by application of additional heat. The photosensitive resin compositions can be used as stress buffer coatings, alpha particle barrier films, interlayer dielectrics, and patterned engineering plastic layers in the manufacturing of microelectronic devices.

### DETAILED DESCRIPTION OF THE INVENTION

The present disclosure relates to photosensitive resin compositions. In the context of this disclosure, the terms “prebake” and “softbake” are considered synonymous. The terms “photoactive” and “photosensitive” are also considered synonymous. The terms “resin” and “polymer” are employed interchangeably. The term “polybenzoxazole precursor polymer” is defined as a polymer which upon curing, results in the formation of a polymer containing benzoxazole groups. The term “photoactive compound” as used herein includes both quinonediazide photoactive compounds (e.g. naphthoquinonediazides, diazonaphthoquinones) and photoacid generator compounds (PAGs).

In some embodiments, the photosensitive resin compositions include (a) at least one polybenzoxazole (PBO) precursor polymer and (b) at least one silicon-containing polymer containing a moiety of Structure (V),

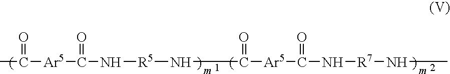

in which Ar⁵, R⁵, R⁷ m¹, and m² are defined in the Summary section above. The composition can further include a photoactive compound (e.g., a quinonediazide compound or a photoacid generator compound). For example, when the polybenzoxazole precursor polymer does not contain a photoactive moiety on the polymer, the composition further includes at least one photoactive compound. The composition can also include a solvent.

The silicon-containing polymers can be polymers without an endcap, such as a polymer of Structure (V). Alternatively, the silicon-containing polymers can be polymers with one or more endcaps, such as polymers of Structure (VI) or (VI*):

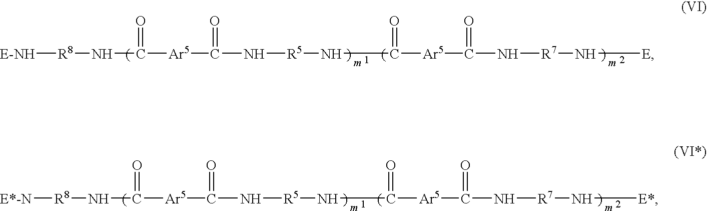

in which Ar⁵, R⁵, R⁷, E, E*, m¹, and m² are defined in the Summary section above.

The polybenzoxazole precursor polymer can be of Structure (I), (II), (III), (III*), (IV), or (IV*):

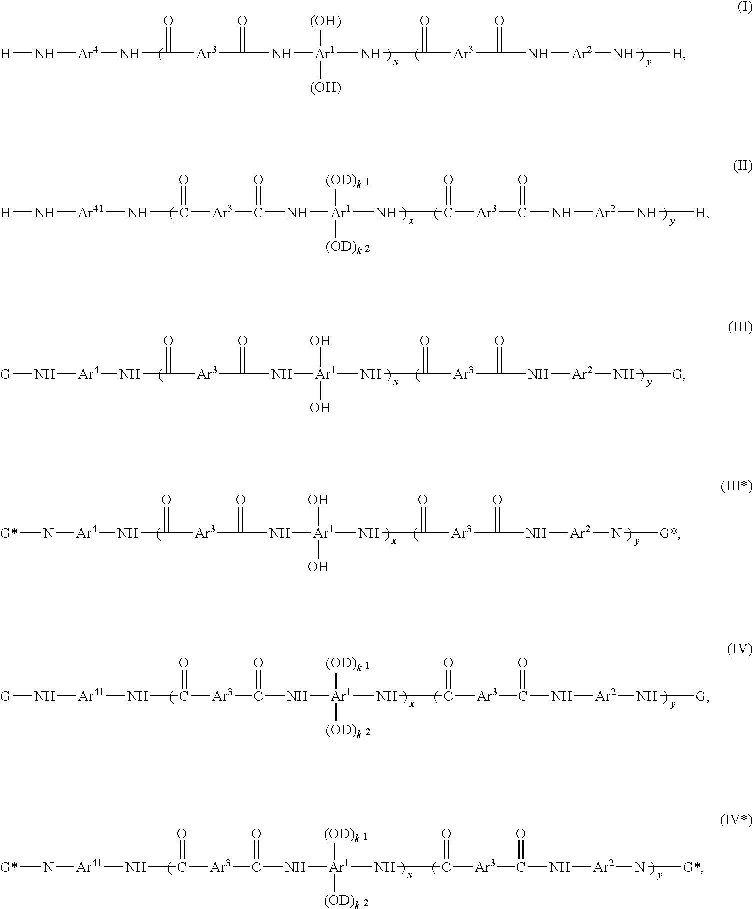

in which Ar¹, Ar², Ar³, Ar⁴, Ar⁴¹, x, y, D, k¹, k², G, and G* are defined in the Summary section above. In such embodiments, the composition can further include a solvent and/or a photoacid generator compound as a photoactive compound. For example, when the polybenzoxazole precursor polymer does not contain a photoactive moiety, the composition can also include at least one quinonediazide photoactive compound.

The polymers of Structure (I) can be prepared from monomers having Structures (X), (XI), and (XII). For example, monomers having Structures (X), (XI), and (XII) can be reacted in the presence of a base to synthesize polybenzoxazole precursor polymers of Structure (I).

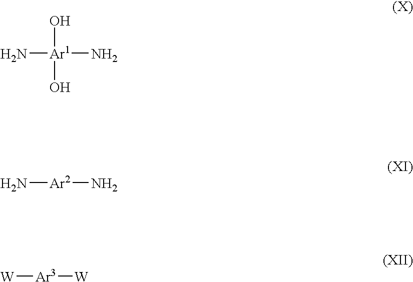

Ar¹, Ar², Ar³ can be those as previously defined, and W can be C(O)Cl, COOH or C(O)OR¹² in which R¹² can be a C₁-C₇ linear or branched alkyl group or a C₅-C₈ cycloalkyl group.

In Structures (I), (II), (III), (III*), (IV), (IV*), and (X), Ar¹ can be a tetravalent aromatic or a tetravalent heterocyclic group. Examples of Ar¹ include, but are not limited to:

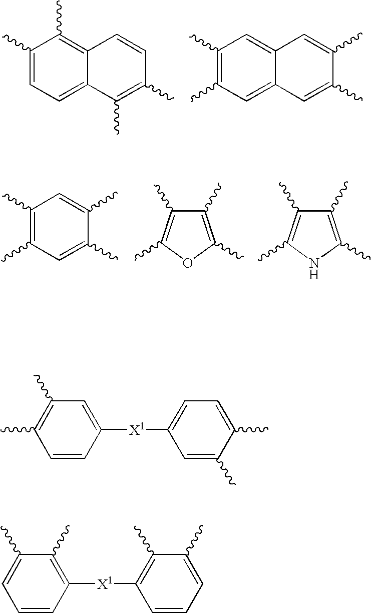

in which x¹ can be —O—, —S—, —C(CF₃)₂—, —C(CH₃)₂—, —CH₂—, —SO₂—, —NHCO—, or —SiR¹³₂— and each R¹³ independently can be a C₁-C₇ linear or branched alkyl or a C₅-C₈ cycloalkyl group. Examples of R¹³ include, but are not limited to, —CH₃, —C₂H₅, n-C₃H₇, i-C₃H₇, n-C₄H₉, t-C₄H₉, and cyclohexyl.

Examples of monomers having Structure (X) containing Ar¹ include, but are not limited to, 2,2-bis(3-amino-4-hydroxyphenyl)hexafluoropropane, 3,3′-dihydroxy-4,4′-diaminodiphenylether, 3,3′-dihydroxybenzidine, 4,6-diaminoresorcinol, and 2,2-bis(3-amino-4-hydroxyphenyl)propane. The substitution pattern of the two hydroxy and two amino groups in the monomer of Structure (X) can be any of the possible substitution patterns with the proviso that each amino group has an ortho relationship with a hydroxyl group in order to be able to form the benzoxazole ring. Furthermore, a polybenzoxazole precursor polymer may be synthesized using a mixture of two or more monomers described by generic Structure (X).

In Structures (I), (II), (III), (III*), (IV), (IV*), and (XI), Ar² can be a divalent aromatic, divalent heterocyclic, divalent alicyclic, or divalent aliphatic group that optionally contains silicon. Examples of Ar² include, but are not limited to:

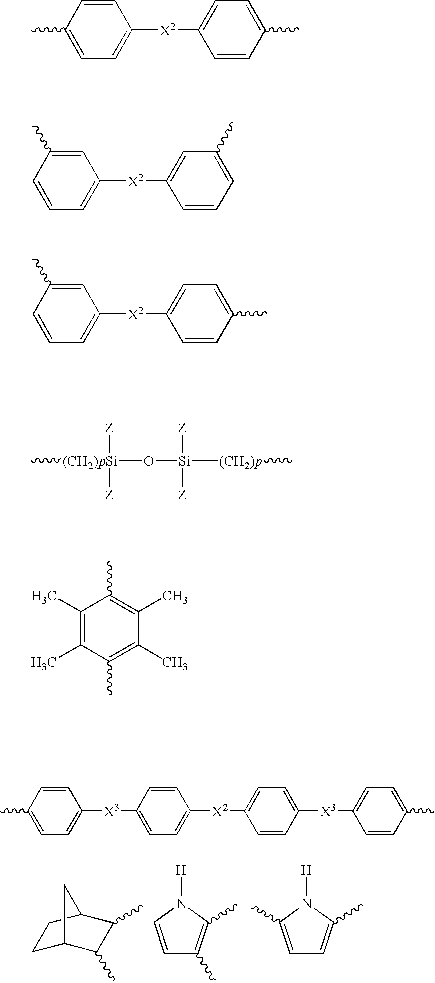

in which x² can be —O—, —S—, —C(CF₃)₂—, —C(CH₃)₂—, —CH₂—, —SO₂—, —NHCO—, or —SiR⁶₂— and each R⁶ independently can be a C₁-C₇ linear or branched alkyl or C₅-C₈ cycloalkyl group, X³ can be —O—, —S—, —C(CF₃)₂—, —C(CH₃)₂—, —CH₂—, —SO₂—, or —NHCO—, Z can be a hydrogen atom or a C₁-C₈ linear, branched or cyclic alkyl and p is an integer from 1 to 6. Examples of suitable Z groups include, but are not limited to, methyl, ethyl, propyl, isopropyl, n-butyl, sec-butyl, t-butyl, n-octyl, cyclopentyl, cyclohexyl, and cyclooctyl.

Examples of monomers having the Structure (XI) containing Ar² include, but are not limited to, 5(6)-diamino-1-(4-aminophenyl)-1,3,3-trimethylindane (DAPI), m-phenylenediamine, p-phenylenediamine, 2,2′-bis(trifluoromethyl)-4,4′-diamino-1,1′-biphenyl, 3,4′-diaminodiphenyl ether, 3,3′-diaminodiphenyl ether, 2,4-toluenediamine, 3,3′-diaminodiphenyl sulfone, 3,4′-diaminodiphenyl sulfone, 4,4′-diaminodiphenyl sulfone, 3,3′-diaminodiphenylmethane, 3,4′-diaminodiphenylmethane, 4,4′-diaminodiphenyl ketone, 3,3′-diaminodiphenyl ketone, 3,4′-diaminodiphenyl ketone, 1,3-bis(4-aminophenoxy)benzene, 1,3-bis(3-amino-phenoxy)benzene, 1,4-bis(gamma-aminopropyl)tetramethyl-disiloxane, 2,3,5,6-tetramethyl-p-phenylenediamine, m-xylylenediamine, p-xylylenediamine, methylenediamine, tetramethylenediamine, pentamethylenediamine, hexamethylenediamine, 2,5-dimethylhexamethylene-diamine, 3-methoxyhexamethylenediamine, heptamethylenediamine, 2,5-dimethylheptamethylenediamine, 3-methylheptamethylenediamine, 4,4-dimethylheptamethylenediamine, octamethylenediamine, nonamethylenediamine, 2,5-dimethylnonamethylenediamine, decamethylenediamine, ethylenediamine, propylenediamine, 2,2-dimethylpropylenediamine, 1,10-diamino-1,10-dimethyldecane, 2,11-diaminidodecane, 1,12-diaminooctadecane, 2,17-diaminoeicosane, 3,3′-dimethyl-4,4′-diaminodiphenylmethane, bis(4-aminocyclohexyl)methane, 3,3′-diaminodiphenylethane, 4,4′-diaminodiphenylethane, 4,4′-diaminodiphenyl sulfide, 2,6-diaminopyridine, 2,5-diaminopyridine, 2,6-diamino-4-trifluoromethylpyridine, 2,5-diamino-1,3,4-oxadiazole, 1,4-diaminocyclohexane, 4,4′-methylenedianiline, 4,4′-methylene-bis(o-choloroaniline), 4,4′-methylenebis(3-methylaniline), 4,4′-methylene-bis(2-ethylaniline), 4,4′-methylene-bis(2-methoxyaniline), 4,4′-oxy-dianiline, 4,4′-oxy-bis-(2-methoxyaniline), 4,4′-oxy-bis-(2-chloroaniline), 4,4′-thio-dianiline, 4,4′-thio-bis-(2-methylaniline), 4,4′-thio-bis(2-methyoxyaniline), 4,4′-thio-bis-(2-chloroaniline). Furthermore, a polybenzoxazole precursor polymer may be synthesized using a mixture of two or more monomers described by generic Structure (XI).

In Structures (I), (II), (III), (III*), (IV), (IV*), and (XII), Ar³ is a divalent aromatic, a divalent aliphatic, or a divalent heterocyclic group. Examples of Ar³ include, but are not limited to:

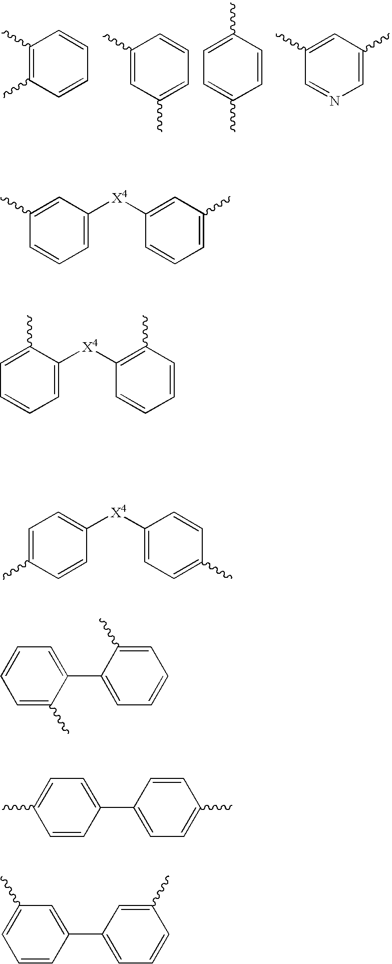

in which X⁴ can be —O—, —S—, —C(CF₃)₂—, —C(CH₃)₂—, —CH₂—, —SO₂—, or —NHCO—.

In Structure (XII), W can be C(O)Cl, COOH or C(O)OR¹² in which R¹² can be a C₁-C₇ linear or branched alkyl group or a C₅-C₈ cycloalkyl group. Examples of R¹² include, but are not limited to, —CH₃, —C₂H₅, n-C₃H₇, i-C₃H₇, n-C₄H₉, t-C₄H₉, and cyclohexyl.

Monomers having the Structure (XII) include diacids, diacid dichlorides and diesters. Examples of suitable dicarboxylic acids (W═COOH) include, but are not limited to, 4,4′-diphenyletherdicarboxylic acid, terephthalic acid, isophthalic acid and mixtures thereof. Examples of suitable diacid chlorides (W═COCl) include, but are not limited to, isophthaloyl dichloride, phthaloyl dichloride, terephthaloyl dichloride, 1,4-oxydibenzoyl chloride and mixtures thereof. Examples of suitable dicarboxylic esters (W═C(O)OR¹²) include, but are not limited to, dimethyl isophthalate, dimethyl phthalate, dimethyl terephthalate, diethyl isophthalate, diethyl phthalate, diethyl terephthalate and mixtures thereof.

Monomers having Structures (X), (XI), and (XII) can react to produce a polybenzoxazole precursor polymer of Structure (I). Any conventional method for reacting a dicarboxylic acid or its dichloride or diester with at least one aromatic and/or heterocyclic dihydroxydiamine, and optionally, with at least one diamine, may be used. Generally, the reaction for diacid dichlorides (W═C(O)Cl) can be carried out at about −10° C. to about 30° C. for about 6 to about 48 hours in the presence of an approximately stoichiometric amount of amine base. Examples of suitable amine bases include, but are not limited to, pyridine, triethylamine, 1,8-diazabicyclo[5.4.0]undec-7-ene (DBU), 1,5-diazabicyclo[4.3.0]non-5-ene (DBN), dimethylpyridine, and dimethylaniline. The polybenzoxazole precursor polymer of Structure (I) can be isolated by precipitation into water, recovered by filtration and dried. Descriptions of suitable syntheses employing diesters or diacids can be found in U.S. Pat. Nos. 4,395,482, 4,622,285, and 5,096,999, the entire contents of which are herein incorporated by reference.

The preferred reaction solvents are N-methyl-2-pyrrolidone (NMP), N-ethyl-2-pyrrolidone (NEP), gamma-butyrolactone (GBL), N,N-dimethylformamide (DMF), N,N-dimethylacetamide (DMAc), dimethyl-2-piperidone, dimethylsulfoxide (DMSO), sulfolane, and diglyme. The most preferred solvents are N-methyl-2-pyrrolidone (NMP) and gamma-butyrolactone (GBL).

Monomers having Structure (X), (XI), and (XII) are employed such that the ratio of [(X)+(XI)]/(XII) is generally from about 1 to about 1.2 Preferably, the ratio of [(X)+(XI)]/(XII) is generally from about 1 to about 1.1. The monomer having the Structure (X) is employed from about 50 to about 100 mole % of [(X)+(XI)] and the monomer having Structure (XI) is employed from about 0 to about 50 mole % of [(X)+(XI)]. Distribution of the polymeric units resulting from monomers having the Structures (X) and (XI) in the polybenzoxazole precursor base polymer may be random or in blocks.

In Structures (I), (II), (III), (III*), (IV) or (IV*), x can be an integer from about 4 to about 1000, y can be an integer from about 0 to about 500 and (x+y) can be less than about 1000. A preferred range for x is from about 6 to about 300 and a preferred range for y is from about 0 to about 50. A more preferred range for x is from about 10 to about 100 and a more preferred range for y is from about 0 to about 10. The most preferred range for x is from about 10 to about 50 and a most preferred range for y is from about 0 to about 5.

The amount of (x+y) can be calculated by dividing the numeric average molecular weight (Mn) of a polymer of Structure (I) by the average molecular weight of the repeat unit. The value of Mn can be determined by such standard methods as membrane osmometry or gel permeation chromatography as described, for example, in Jan Rabek, Experimental Methods in Polymer Chemistry, John Wiley & Sons, New York, 1983, the contents of which are incorporated herein by reference.

It should be noted that molecular weight and inherent viscosity of the polymers and therefore, x and y, at a constant stoichiometry, can have a wide range depending on the reaction conditions chosen and considerations such as the purity of the solvent, the humidity, presence or absence of a blanket of nitrogen or argon gas, reaction temperature, reaction time, and other variables.

Polybenzoxazole precursor polymer of Structure (II) can be synthesized by reaction of the polybenzoxazole precursor polymer of Structure (I) with about 0.5 mol % to about 25 mol % of a diazoquinone (based on the number of OH groups from the monomer of Structure (I)) in the presence of a base to yield the polybenzoxazole precursor of Structure (II) according to Reaction 1 below, in which Ar¹, Ar², Ar³, Ar⁴, Ar⁴¹, D, k¹, k², x and y can be those previously defined

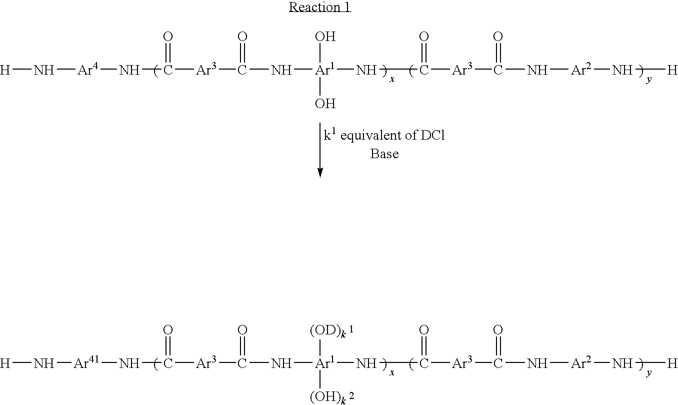

Examples of the diazoquinone compound (DCl) that can be reacted with the PBO polymer (I) include, but are not limited to, one of the following:

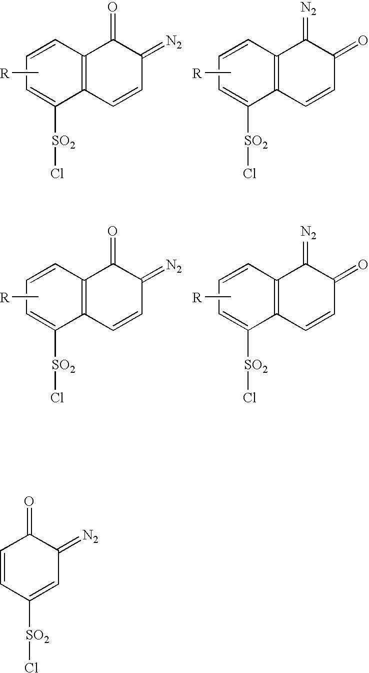

in which R can be a hydrogen atom, a halogen, a C₁-C₄ alkyl group, a C₁-C₄ alkoxy group, cyclopentyl or cyclohexyl. Examples of suitable R groups include, but are not limited to, methyl, ethyl, propyl, iso-propyl, n-butyl, sec-butyl, t-butyl, cyclopentyl or cyclohexyl.

Generally, the reaction can be carried out at about 0° C. to about 30° C. for about 3 to about 24 hours in a solvent in the presence of a base. Generally, a slight excess of base to DCl can be employed. Examples of bases include, but are not limited to, amine bases such as pyridine, trialkylamine, methylpyridine, lutidine, n-methylmorpholine, and the like. The most preferred base is triethylamine. The preferred reaction solvents are tetrahydrofuran, acetone, N-methyl-2-pyrrolidone (NMP), gamma-butyrolactone (GBL), N,N-dimethylformamide (DMF), N,N-dimethylacetamide (DMAc), dimethyl-2-piperidone, dimethylsulfoxide (DMSO), sulfolane, and diglyme. The most preferred reaction solvents are tetrahydrofuran and acetone. The reaction mixture should be protected from actinic rays.

The molar amount of DCl can range from about 0.5% to about 25% of the quantity of OH groups from monomers of Structure (X) to yield k¹ from 0.01 to about 0.5. A preferred amount of DCl is from about 0.5% to about 10% of the quantity of OH groups from monomers of Structure (X) to produce k¹ from about 0.01 to about 0.20. A more preferred amount of DCl is from about 0.5% to about 5% of the quantity of OH groups from monomers of Structure (X) to produce k¹ from about 0.01 to about 0.10. A most preferred amount of DCl is from about 0.5% to about 2.5% of the quantity of OH groups from monomers of Structure (X) to produce k¹ from about 0.01 to about 0.05.

Polybenzoxazole precursor polymers of Structure (III) can be synthesized by reaction of a polybenzoxazole precursor polymer of Structure (I) with G-M where G can be a monovalent organic group having a carbonyl, carbonyloxy or sulfonyl group and M can be a reactive leaving group. Examples of G include, but are not limited to, the following structures:

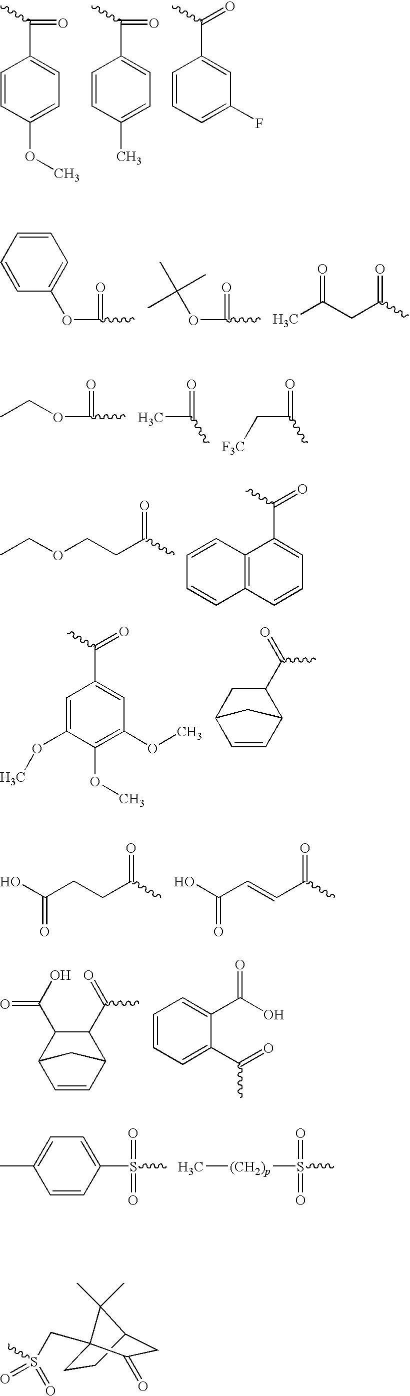

Examples of M groups include, but are not limited to, Cl, Br, mesylate, triflate, substituted carbonyloxy groups, and substituted carbonate groups.

Examples of suitable classes of G-M compounds include, but are not limited to, carbon and sulfonic acid chlorides, carbon and sulfonic acid bromides, linear and cyclic carbon and sulfonic acid anhydrides, and alkoxy or aryloxy substituted acid chlorides. Examples of suitable G-M compounds include maleic anhydride, succinic anhydride, acetic anhydride, propionic anhydride, norbornene anhydride, phthalic anhydride, camphor sulfonic acid anhydride, trifluoromethane sulfonic acid anhydride, methanesulfonic acid anhydride, p-toluenesulfonic acid anhydride, ethanesulfonic acid anhydride, butanesulfonic acid anhydride, perfluorobutanesulfonic acid anhydride, acetyl chloride, methanesulfonyl chloride, trifluoromethanesulfonyl chloride, benzoyl chloride, norbornene carboxylic acid chloride, di-t-butyl dicarbonate, dimethyl dicarbonate, diethyldicarbonate, dibutyldicarbonate, t-butyl chloroformate, ethyl chloroformate, n-butyl chloroformate, and methyl chloroformate. Further examples include compounds having the structures shown below.

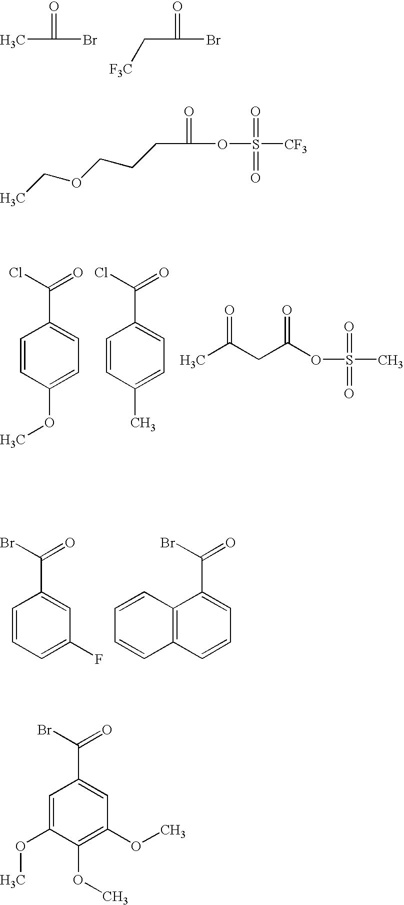

The reaction for synthesizing polybenzoxazole precursor polymers of Structure (III) can be carried out in a suitable solvent by addition of G-M to a dry solution of the polybenzoxazole precursor polymer of Structure (I) at a temperature from about −25° C. to about 40° C. The more preferred temperature is from about 0° C. to about 25° C. The most preferred temperature is from about 5° C. to about 10° C. The reaction time is from about 1 hour to about 24 hours. The molar amount of G-M employed is a slightly excess (3-6%) of the sum of the molar amounts of monomer of Structures (X) and (XI) less the molar amount of monomer of Structure (XII). Addition of organic or inorganic base may also be employed. Examples of suitable organic amine bases include, but are not limited to, pyridine, triethylamine, 1,8-diazabicyclo[5.4.0]undec-7-ene (DBU), 1,5-diazabicyclo[4.3.0]non-5-ene (DBN), dimethylpyridine, and dimethylaniline. Examples of other suitable bases include sodium hydroxide, sodium carbonate, and sodium silicate.

The preferred reaction solvents are propyleneglycol methyl ether acetate (PGMEA), N-methyl-2-pyrrolidone (NMP), N-ethyl-2-pyrrolidone (NEP), gamma-butyrolactone (GBL), N,N-dimethylformamide (DMF), N,N-dimethylacetamide (DMAc), dimethyl-2-piperidone, dimethylsulfoxide (DMSO), tetrahydrofuran (THF), acetone, sulfolane, and diglyme. The most preferred solvents are diglyme and PGMEA.

In some embodiments, the endcapping reaction with certain endcapping reagents, such as cyclic anhydrides, may not stop after the endcapping reaction. As shown below, a subsequent dehydration step can also occur to form a divalent endcap (e.g., G* in Structures (III*) and (IV*)). Examples of cyclic anhydrides which can undergo this additional reaction include, but are not limited to, maleic anhydride, succinic anhydride, norbornane anhydride, norbornene anhydride, and camphor anhydride.

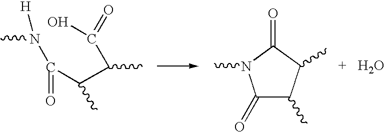

Polybenzoxazole precursor polymer of Structure (IV) can be synthesized by reaction of polybenzoxazole precursor polymer of Structure (III) with about 0.5 mol % to about 25 mol % of a diazoquinone compound (based on the number of OH groups from the monomer of Structure (X)) in the presence of a base to yield the polybenzoxazole precursor (IV) according to Reaction 2 below:

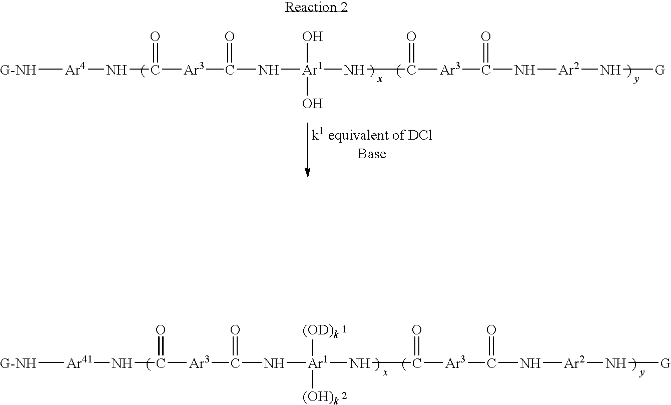

in which Ar¹, Ar², Ar³, Ar⁴, Ar⁴¹, D, k¹, k², x, y, and G can be those previously defined. Similarly, the polymer having Structure (IV*) can be synthesized from the polymer having Structure (III*).

The reaction conditions and ranges can be identical to that described previously for the synthesis of polybenzoxazole precursor polymer of Structure (II).

A polybenzoxazole precursor polymer of Structure (IV) or (IV*) can also be prepared by reaction of a polybenzoxazole precursor polymer of Structure (II) with G-M. The definition of G and M can be the same as those defined above and the reaction conditions can be the same as those described for the preparation of polybenzoxazole precursor polymer of Structure (III) or (III*).

Other polybenzoxazole precursor polymers are known in the art, such as those described in commonly owned co-pending U.S. Application Publication No. 20050181297, the entire contents of which are herein incorporated by reference.

The positive working photosensitive resin compositions of this disclosure can include at least one silicon-containing polymer containing a moiety of Structure (V), such as non-endcapped polymers of Structure (V), or endcapped polymers of Structure (VI) or (VI*):

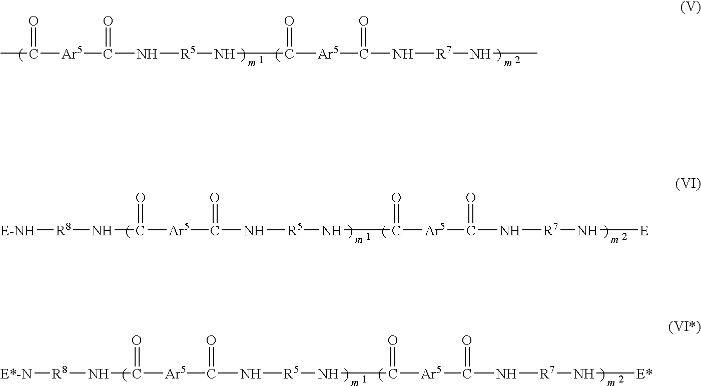

in which Ar⁵, R⁵, R⁷, m¹, m², E, and E* are defined in the Summary section above.

A non-endcapped polymer of Structure (V) can be prepared from monomers having Structures (VII), (VIII), and (IX). Monomers having Structures (VII), (VIII), and (IX) can be reacted in the presence of a base to synthesize polyamide of Structure (V).

H₂N—R⁵—NH₂ (VII)

W—Ar⁵—W (VIII)

H₂N—R⁷—NH₂ (IX)

R⁵, Ar⁵ and W can be those previously defined. R⁷ can be a non-silicon containing divalent aromatic group, a non-silicon containing divalent aliphatic group, a non-silicon containing divalent heterocyclic group, or mixtures thereof.

Examples of monomer (VII) include but are not limited to;

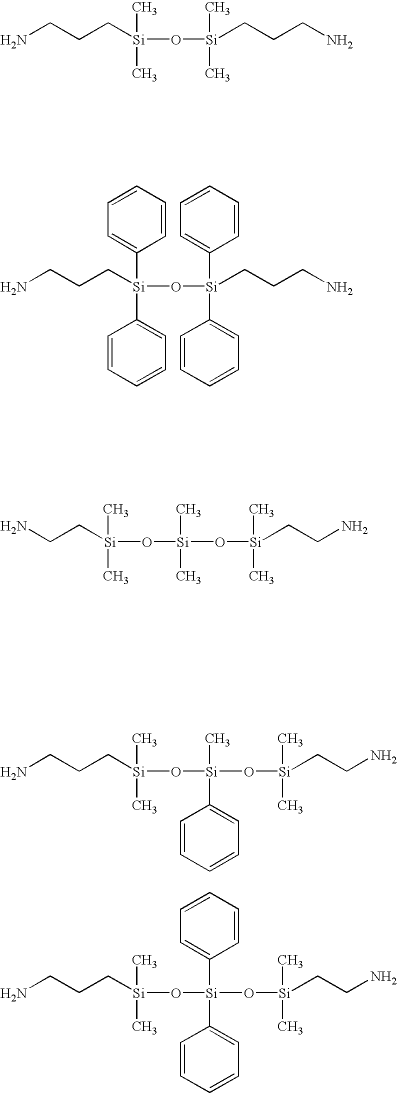

and can be purchased commercially or synthesized by common methods known to those skilled in the art.

Examples of Ar⁵ in Structures (V), (VI), (VI*), and (VIII) can be the same as the groups assigned to Ar² and Ar³ above and R⁷ below. In some embodiments, Ar⁵ is not a divalent aromatic group substituted with a carboxylic acid group.

Monomers having the Structure (VIII) can be diacids, diacid dichlorides and diesters. Examples of suitable dicarboxylic acids (W═COOH) include, but are not limited to, 4,4′-diphenyletherdicarboxylic acid, terephthalic acid, isophthalic acid and mixtures thereof. Examples of suitable diacid chlorides (W═COCl) include, but are not limited to, isophthaloyl dichloride, phthaloyl dichloride, terephthaloyl dichloride, 1,4-oxydibenzoyl chloride and mixtures thereof. Examples of suitable dicarboxylic esters (W═C(O)OR¹²) include, but are not limited to, dimethyl isophthalate, dimethyl phthalate, dimethyl terephthalate, diethyl isophthalate, diethyl phthalate, diethyl terephthalate and mixtures thereof.

Examples of R⁷ in Structures (V), (VI), (VI*), and (IX) include, but are not limited to:

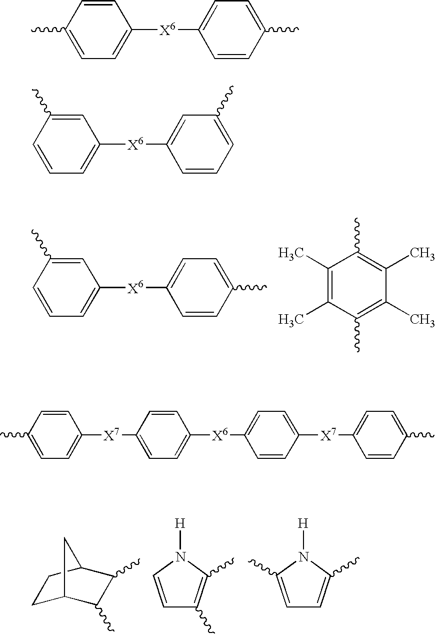

wherein X⁶ is —O—, —S—, —C(CF₃)₂—, —C(CH₃)₂—, —CH₂—, —SO₂—, or —NHCO—. and x⁷ is —O—, —S—, —C(CF₃)₂—, —C(CH₃)₂—, —CH₂—, —SO₂—, or —NHCO—.

Examples of monomers having the Structure (IX) containing R⁷ include, but are not limited to, 5(6)-diamino-1-(4-aminophenyl)-1,3,3-trimethylindane (DAPI), m-phenylenediamine, p-phenylenediamine, 2,2′-bis(trifluoromethyl)-4,4′-diamino-1,1′-biphenyl, 3,4′-diaminodiphenyl ether, 3,3′-diaminodiphenyl ether, 2,4-toluenediamine, 3,3′-diaminodiphenyl sulfone, 3,4′-diaminodiphenyl sulfone, 4,4′-diaminodiphenyl sulfone, 3,3′-diaminodiphenylmethane, 3,4′-diamino-diphenylmethane, 4,4′-diaminodiphenyl ketone, 3,3′-diaminodiphenyl ketone, 3,4′-diaminodiphenyl ketone, 1,3-bis(4-aminophenoxy)benzene, 1,3-bis(3-amino-phenoxy)benzene, 2,3,5,6-tetramethyl-p-phenylenediamine, m-xylylenediamine, p-xylylenediamine, methylenediamine, tetramethylenediamine, pentamethylenediamine, hexamethylenediamine, 2,5-dimethylhexamethylene-diamine, 3-methoxyhexamethylenediamine, heptamethylenediamine, 2,5-dimethylheptamethylenediamine, 3-methylheptamethylenediamine, 4,4-dimethylheptamethylenediamine, octamethylenediamine, nonamethylenediamine, 2,5-dimethylnonamethylenediamine, decamethylenediamine, ethylenediamine, propylenediamine, 2,2-dimethylpropylenediamine, 1,10-diamino-1,10-dimethyldecane, 2,11-diaminidodecane, 1,12-diaminooctadecane, 2,17-diaminoeicosane, 3,3′-dimethyl-4,4′-diaminodiphenylmethane, bis(4-aminocyclohexyl)methane, 3,3′-diaminodiphenylethane, 4,4′-diaminodiphenylethane, 4,4′-diaminodiphenyl sulfide, 2,6-diaminopyridine, 2,5-diaminopyridine, 2,6-diamino-4-trifluoromethylpyridine, 2,5-diamino-1,3,4-oxadiazole, 1,4-diaminocyclohexane, 4,4′-methylenedianiline, 4,4′-methylene-bis(o-choloroaniline), 4,4′-methylene-bis(3-methylaniline), 4,4′-methylene-bis(2-ethylaniline), 4,4′-methylene-bis(2-methoxyaniline), 4,4′-oxy-dianiline, 4,4′-oxy-bis-(2-methoxyaniline), 4,4′-oxy-bis-(2-chloroaniline), 4,4′-thio-dianiline, 4,4′-thio-bis-(2-methylaniline), 4,4′-thio-bis-(2-methyoxyaniline), 4,4′-thio-bis-(2-chloroaniline). Furthermore, a mixture of two or more monomers described by generic Structure IX may be employed.

Generally, the reaction conditions to synthesize polymers of Structure (V) can be the same as those described for the synthesis of polymers of Structure (I). The ratio of monomers [(VII)+(IX)] to monomer (VII) in the synthesis of polymers of Structure (V) is from 0.8/1 to 1/0.8. The preferred ratio of monomers [(VII)+(IX)] to monomer (VIII) is from about 0.9/1 to about 1/0.9.

The monomer having the Structure (VII) can be employed from about 5 to about 100 mole % of [(VII)+(IX)] and the monomer having Structure (IX) is employed from about 0 to about 95 mole % of [(VII)+(IX)]. A preferred range for (VII) is from about 25 to about 100 mole % of [(VIII)+(IX)] and for monomer having Structure (IX) is from about 0 to about 75 mole % of [(VII)+(IX)]. A more preferred range for (VII) is from about 50 to about 100 mole % of [(VII)+(IX)] and for monomer having Structure (IX) is from about 0 to about 50 mole % of [(VII)+(IX)]. The most preferred range for (VIII) is from about 60 to about 100 mole % of [(VII)+(IX)] and for monomer having Structure (IX) is from about 0 to about 40 mole % of [(VII)+(IX)]. Distribution of the polymeric units resulting from monomers having the Structures (X) and (XI) in the polybenzoxazole precursor base polymer may be random or in blocks.

In Structures (V), (VI), and (VI*), m¹ can be an integer from about 5 to about 1000, m² can be an integer from about 0 to about 500 and (m¹+m²) is less than about 1000. A preferred range for m¹ is from about 5 to about 200 and a preferred range for m² is from about 0 to about 200. A more preferred range for m¹ is from about 10 to about 150 and a more preferred range for m² is from about 0 to about 100. The most preferred range for m¹ is from about 10 to about 100 and a most preferred range for m² is from about 0 to about 50.

Polymers of Structure (V) can be prepared from equimolar amounts of (VII)/(IX) and (VIII) or an excess of (VII)/(IX) or an excess of (VIII). In the former situation, the chains will be terminated with amine groups. In the latter situation, the chain will be terminated with acid chloride groups. It is preferred to either hydrolyze the acid chloride groups to acid or react them with an alcohol to terminate the chain with an ester group. It is more preferred for the acid chloride groups to be reacted with alcohols.

Polyamides of Structure (VI) may be synthesized by reaction of a polymer of Structure (V) with E-M where E is a monovalent organic group and M is a reactive leaving group. Preferable monovalent organic group are those having a carbonyl, carbonyloxy or sulfonyl group. Examples of preferred E include the structures previously described for G. M can be those as described previously and examples of suitable classes of E-M compounds can be the same as those described previously for G-M. The reaction of polymers of Structure (V) with E-M can be carried out as described for G-M with polymers of Structure (I). As described previously for that reaction, in some cases, the endcapping reaction with certain endcapping reagents, such as cyclic anhydrides, may not stop after the endcapping reaction. A subsequent dehydration step may also occur to form a divalent endcap (E* in Structures (VI*)). Examples of cyclic anhydrides which may undergo this additional reaction include, but are not limited to, maleic anhydride, succinic anhydride, norbornane anhydride, norbornene anhydride, and camphor anhydride.

Suitable solvents of this photosensitive compositions described above can be polar organic solvents. Suitable examples of polar organic solvents include, but are not limited to, N-methyl-2-pyrrolidone (NMP), N-ethyl-2-pyrrolidone, gamma-butyrolactone (GBL), N,N-dimethylacetamide (DMAc), dimethyl-2-piperidone, N,N-dimethylformamide (DMF), and mixtures thereof. The preferred solvents are gamma-butyrolactone, N-ethyl-2-pyrrolidone and N-methyl-2-pyrrolidone. The most preferred solvent is gamma-butyrolactone.

The photoactive compound of the photosensitive resin composition, when employed can include one or more diazonaphthoquinone photoactive compounds, which can be the condensation products of compounds containing from about 2 to about 9 aromatic hydroxyl groups with one or more compounds having a moiety of structure D (described above). Preferred compounds having a moiety of structure D include a 5-naphthoquinone diazide sulfonyl compound and/or a 4-naphthoquinone diazide sulfonyl compound. Examples of photoactive compounds are illustrated in structures (XIII a-r) below.

The phenolic compounds (i.e., the backbone) typically employed in the preparation of a photoactive compound can be prepared by any suitable method. A common method of synthesis is by reaction of a suitable phenol derivative with a suitable aldehyde or ketone in the presence of a solvent such as methanol. The reaction can typically be catalyzed by a strong acid (e.g. sulfuric acid or p-toluene sulfonic acid). Generally, the reaction can be carried out at about 15° C. to about 80° C. for about 3 hours to about 48 hours.

The photoactive compounds (XIII) can be synthesized by reaction of the backbone with DCl. Generally, the reaction can be carried out at about 0° C. to about 30° C. for about 4 to about 36 hours in a solvent in the presence of a base. Generally, a slight excess of base to DCl can be employed. Examples of bases include, but are not limited to, amine bases such as pyridine, trialkylamine, methylpyridine, lutidine, n-methylmorpholine, and the like. The most preferred base is triethylamine. The preferred reaction solvents are tetrahydrofuran (THF), gamma-butyrolactone (GBL), N,N-dimethylformamide (DMF), acetone, N,N-dimethylacetamide (DMAc), dimethyl-2-piperidone, dimethylsulfoxide (DMSO), sulfolane, and diglyme. The most preferred solvents are tetrahydrofuran (THF), acetone and gamma-butyrolactone (GBL). The reaction mixture should be protected from actinic rays.

Examples of compounds XIII include, but are not limited to, one or more of the following compounds where each Q is independently a hydrogen atom or D with the proviso that at least one Q is D:

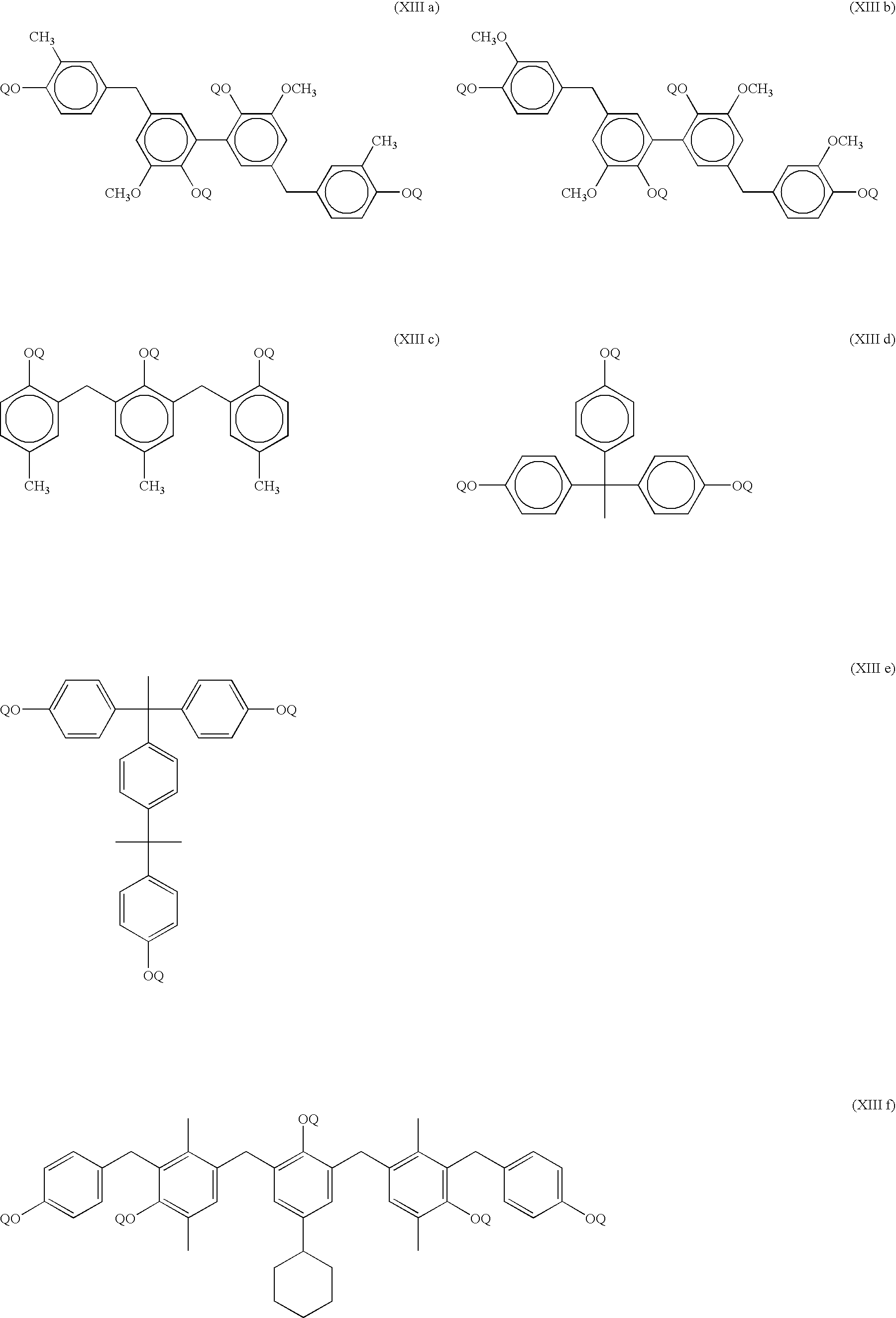

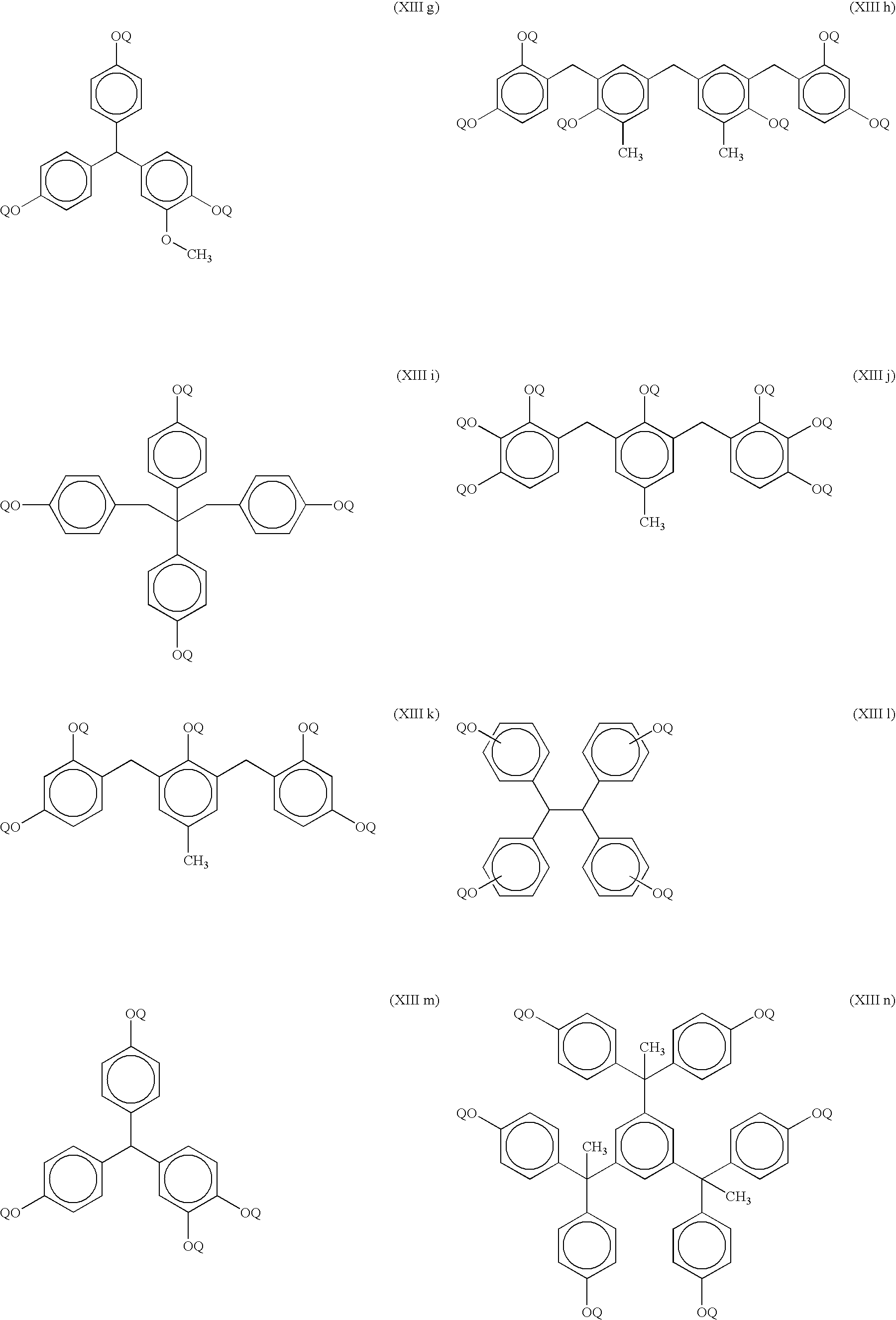

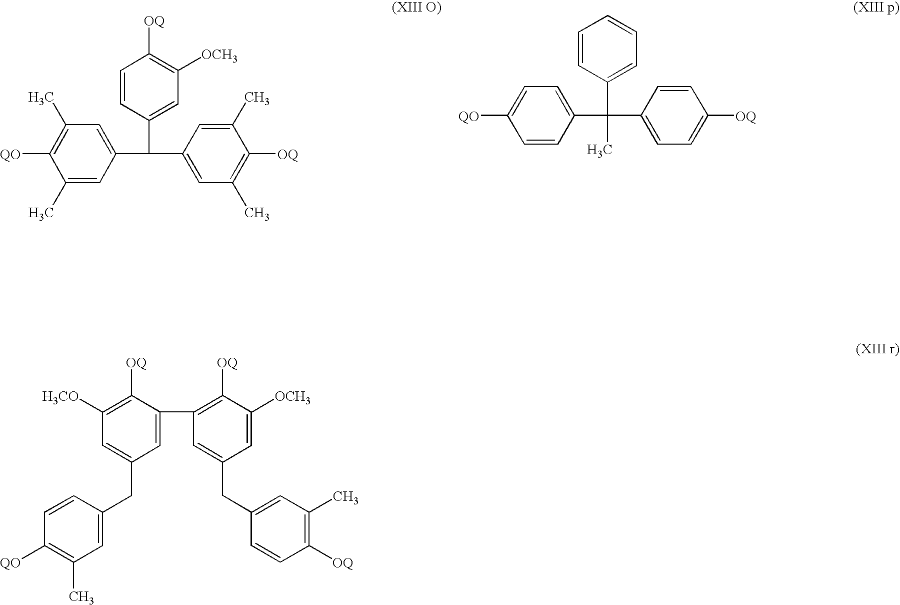

The amount of polybenzoxazole precursor polymer(s) of Structure (I), (II), (III), (III*), (IV), or (IV*) in the photosensitive composition can be from about 5 wt % to about 50 wt %. The more preferred amount of polybenzoxazole precursor polymer(s) of Structure (I), (II), (III), (III*), (IV), or (IV*) is from about 20 wt % to about 45 wt % and the most preferred amount of polybenzoxazole precursor polymer(s) of Structure (I), (II), (III), (III*), (IV), or (IV*) is from about 30 wt % to about 40 wt %. Polybenzoxazole precursor polymers of Structures (I), (II), (III), (III*), (IV), and (IV*) can be used singly or be combined in any ratio. Up to 25% of the amount of the polybenzoxazole precursor polymer of Structure (I), (II), (III), (III*), (IV), or (IV*) can be replaced by other organic solvent soluble, aqueous base soluble, aromatic or heterocyclic group polymers or copolymers. Examples of organic solvent soluble, aqueous base soluble, aromatic or heterocyclic group polymers or copolymers may include polyimides, polybenzoimidazoles, polybenzothiazoles, polytriazoles, polyquinazolones, polyquinazolindiones, polyquinacridones, polybenxazinones, polyanthrazolines, polyoxadiazoles, polyhydantoins, polyindophenazines, or polythiadiazoles.

The amount of a polymer having a moiety of Structure (V) (e.g., a polymer of Structure (VI), or (VI*)) used in the photosensitive composition can be from about 0.02 wt % to about 10 wt % of the total weight of the composition, preferably about 0.05 wt % to 5 wt %, and most preferably about 1 wt % to about 4 wt %.

The solvent can be about 40 wt % to about 80 wt % of the photosensitive composition. A preferred solvent weight range is from about 45 wt % to about 70 wt %. A more preferred solvent weight range is from about 50 wt % to about 65 wt %.

The amount of diazoquinone compound (XIII), if used in the photosensitive composition, can be from about 0 wt % to about 25 wt % of the total weight of the composition. The amount of diazoquinone compound (XIII) is preferably from about 2 wt % to about 12 wt %, and most preferably from about 3 wt % to about 6 wt %. The amount of diazoquinone compound can be reduced as more of a polymer of Structures (II), (IV), or (IV*) is used. In addition, in general, the larger k¹ becomes, the less diazoquinone compound is needed. In some embodiments, with a large k¹, there may be no need to use the diazoquinone compound (XIII) because the amount of the diazoquinone moiety in the polymer is sufficient to produce a positive tone photoactive composition.

The photosensitive compositions of the present disclosure can further include other additives. Suitable additives include, for example, plasticizers, leveling agents, dissolution inhibitors, and adhesion promoters.

The photosensitive PBO precursor compositions of the present disclosure can optionally include at least one plasticizer. The plasticizer should have a lower volatility than the solvent employed at the typical bake temperatures of about 100° C. to about 150° C., so that it remains in the film after the softbake. This typically means that the plasticizer of this disclosure has a higher boiling point than the solvent employed, unless interaction of the functional groups of the plasticizer with other components of the chemically amplified positive working photosensitive PBO precursor composition decreases its volatility sufficiently. It is preferred that this boiling point differential is at least about 10° C. A more preferred boiling point differential is at least about 15° C.

The amount of optional plasticizer used in the positive working photosensitive PBO precursor composition of this disclosure is from about 0.1 wt % to about 20 wt % of the total weight of the composition, preferably, from about 1 wt % to about 10 wt %, more preferably, from about 1.25 wt % to about 7.5 wt % and most preferably, from about 1.5 wt % to about 5 wt %. The plasticizers may be blended together in any suitable ratio.

In some embodiments, the optional plasticizer is at least one polyhydroxy compound with at least two OH groups and whose boiling point is higher than the boiling point of a chemically amplified positive working photosensitive PBO precursor composition solvent. Examples of polyhydroxy compounds with at least two OH groups are, but are not limited to, ethylene glycol, diethylene glycol, polyethylene glycol, propylene glycol, tripropylene glycol, polypropylene glycol, glycerol, butane diol, hexane diol, sorbitol, cyclohexanediol, 4,8-bis(hydroxymethyl)-tricyclo(5.2.1.0/2,6)decane and a 2-oxepanone co-polymer with 2-ethyl-2-(hydroxymethyl)-1,3-propanediol. Preferred polyhydroxy compound with at least two OH groups are diethylene glycol, tripropylene glycol, and a 2-oxepanone co-polymer with 2-ethyl-2-(hydroxymethyl)-1,3-propanediol. More preferred polyhydroxy compound with at least two OH groups are tripropylene glycol and a 2-oxepanone co-polymer with 2-ethyl-2-(hydroxymethyl)-1,3-propanediol.

In some embodiments, the optional plasticizer is at least one saturated glycol mono ether whose boiling point is higher than the boiling point of a chemically amplified positive working photosensitive PBO precursor composition solvent. Examples of suitable saturated glycol mono ethers include, but are not limited to, saturated mono ethers of tripropylene glycol, tetrapropylene glycol, triethylene glycol, tetraethylene glycol and pentaethylene glycol. Preferred saturated glycol mono ethers are saturated mono ethers of tripropylene glycol, triethylene glycol and tetraethylene glycol. More preferred saturated glycol mono ethers are tri(propylene glycol)methyl ether, tri(propylene glycol)propyl ether and tri(propylene glycol)butyl ether.

In some embodiments, the optional plasticizer is at least one carboxylic acid ester whose boiling point is higher than the boiling point of a chemically amplified positive working photosensitive PBO precursor composition solvent. Examples include, but are not limited to, ethyl cyclohexyl acetate, propyl benzoate, butyl benzoate, n-butyl cinnamate, ethyl-3,3′-diethoxypropionate, dimethyl succinate, diisopropyl succinate, dimethyl maleate, dimethyl malonate, diethyl adipate, diethyl acetamidomalonate, diethyl allylmalonate, and dimethyl cyclohexane-1,4-dicarboxylate, mixture of cis and trans isomers. Preferably the carboxylic acid ester is derived from a carboxylic acid containing at least two carboxylic acid groups. Examples include, but are not limited to, dimethyl succinate, diisopropyl succinate, dimethyl maleate, dimethyl malonate, diethyl adipate, diethyl acetamidomalonate, diethyl allylmalonate, and dimethyl cyclohexane-1,4-dicarboxylate, including mixture of cis and trans isomers thereof.

Preferred embodiments of the present disclosures are positive working photosensitive PBO precursor compositions including at least one plasticizer selected from the group consisting of polyhydroxy compounds with at least two OH groups and glycol ethers.

More preferred embodiments of the present disclosures are positive working photosensitive PBO precursor compositions including at least one plasticizer selected from the group consisting of polyhydroxy compounds with at least two OH groups.

An additional adhesion promoter, if included in the photosensitive composition, can range from about 0.1 wt % to about 2 wt % of the total weight of the composition. A preferred amount of adhesion promoter is from about 0.2 wt % to about 1.5 wt %. A more preferred amount of adhesion promoter is from about 0.3 wt % to about 1 wt %. Suitable adhesion promoters include, but are not limited to, amino silanes, and mixtures or derivatives thereof. Examples of suitable adhesion promoters which may be employed in the invention may be described by Structure (XIV):

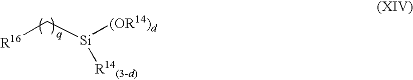

in which each R¹⁴ can be independently a C₁-C₄ alkyl group or a C₅-C₇ cycloalkyl group, each R¹⁵ can be independently a C₁-C₄ alkyl group, a C₁-C₄ alkoxy group, a C₅-C₇ cycloalkyl group or a C₅-C₇ cycloalkoxy group, d can be an integer from 0 to 3 and q can be an integer from 1 to about 6, R¹⁶ can be one of the following moieties:

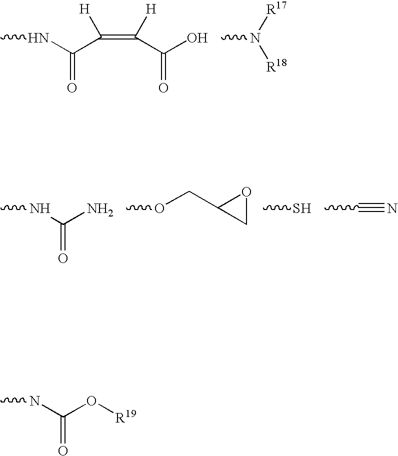

in which each R¹⁷ and R¹⁸ can be independently a C₁-C₄ alkyl group or a C₅-C₇ cycloalkyl group, and R¹⁹ can be a C₁-C₄ alkyl group or a C₅-C₇ cycloalkyl group. Preferred adhesion promoters are those wherein R¹⁶ can be selected from

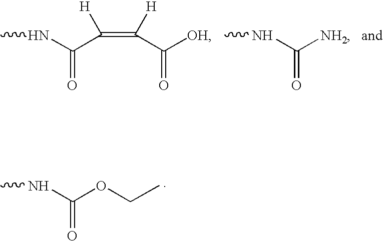

More preferred adhesion promoters are those wherein R¹⁶ is

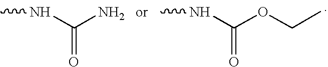

The most preferred adhesion promoters are

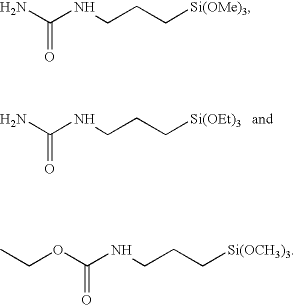

The photosensitive compositions of the present disclosure can further include other additives. Suitable additives include, for example, leveling agents, dissolution inhibitors and the like. Such additives may be included in the photosensitive compositions in about 0.03 to about 10 wt % of the total weight of composition.

Another embodiment of the present disclosure concerns a process for forming a relief image using the positive photosensitive compositions described above. The process includes the steps of:

(a) coating on a suitable substrate, a positive-working photosensitive composition including one or more polybenzoxazole precursor polymers having Structure (I), (II), (III), (III*), (IV), or (IV*) or mixtures thereof, at least one silicon-containing polymer having a moiety of Structure (V) (e.g., a polymer of Structure (V), (VI), or (VI*) or mixtures thereof) and optionally at least one solvent and optionally at least one photoactive compound (e.g., at least one naphthoquinonediazide photoactive compound), thereby forming a coated substrate.

(b) prebaking the coated substrate;

(c) exposing the prebaked coated substrate to actinic radiation;

(d) developing the exposed coated substrate with an aqueous developer, thereby forming an uncured relief image on the coated substrate; and

(e) baking the developed coated substrate at an elevated temperature, sufficient to cure the composition to produce a polybenzoxazole relief image.

The process can optionally include the step of pretreating a substrate with a solvent containing an adhesion promoter. Any suitable method of treatment of the substrate with adhesion promoter known to those skilled in the art may be employed. Examples include treatment of the substrate with adhesion promoter vapors, solutions or at 100% concentration. The time and temperature of treatment will depend on the particular substrate, adhesion promoter, and method, which can employ elevated temperatures. Any suitable external adhesion promoter can be employed. Classes of suitable external adhesion promoters include, but are not limited to, vinylalkoxysilanes, methacryloxyalkoxyysilanes, mercaptoalkoxysilanes, aminoalkoxysilanes, epoxyalkoxysilanes and glycidoxyalkoxysilanes. Aminosilanes and glycidoxysilanes are more preferred. Primary aminoalkoxysilanes are more preferred. Examples of suitable external adhesion promoters include, but are not limited to, gamma-aminopropyltrimethoxy-silane, gamma-glycidoxypropylmethyldimethoxysilane, gamma-glycidoxypropylmethyldiethoxysilane, gamma-mercaptopropylmethyldimethoxysilane, 3-methacryl-oxypropyldimethoxymethylsilane, and 3-methacryloxypropyltrimethoxysilane. gamma-aminopropyltrimethoxy-silane is more preferred. Additional suitable adhesion promoters are described in “Silane Coupling Agent” Edwin P. Plueddemann, 1982 Plenum Press, New York, the entire contents of which are herein incorporated by reference.

The positive acting photoactive composition of this invention is coated on a suitable substrate, which can be coated with various semiconductor coatings. The substrate may be, for example, coated with semiconductor materials such as silicon, silicon oxide, silicon nitride, aluminum, copper, silver, gold, chromium, tantalum, titanium, aluminum-copper alloys, or aluminum-copper-silicon alloys, compound semiconductors (III-V) or (II-VI), ceramic, glass or quartz. Said substrates may also contain films or structures used for electronic circuit fabrication such as organic or inorganic dielectrics, copper or other wiring metals.

Coating methods include, but are not limited to, spray coating, spin coating, offset printing, roller coating, screen printing, extrusion coating, meniscus coating, curtain coating, and immersion coating.

The resulting film is prebaked at an elevated temperature. The bake may be completed at one or more temperatures within the temperature of from about 70° C. to about 130° C. for several minutes to half an hour, depending on the method, to evaporate the remaining solvent. Alternatively, multiple bakes for shorter times and/or temperatures may be employed. Any suitable baking means may be employed. Examples of suitable baking means include, but are not limited to, hot plates and convection ovens. The resulting dry film has a thickness of from about 3 to about 50 micron or more preferably from about 4 to about 20 micron or most preferably from about 5 to about 15 micron.

After the bake step, the resulting dry film is exposed to actinic rays in a preferred pattern through a mask. X-rays, electron beam, ultraviolet rays, visible light, and the like can be used as actinic rays. The most preferred rays are those with wavelength of 436 nm (g-line) and 365 nm (i-line).

Following exposure to actinic radiation, in an optional step it can be advantageous to heat the exposed and coated substrate to a temperature between about 70° C. and about 130° C. The exposed and coated substrate can be heated in this temperature range for a short period of time, typically several seconds to several minutes and may be carried out using any suitable heating means. Preferred means include baking on a hot plate or in a convection oven. This process step is commonly referred to in the art as post-exposure baking.

Next, the film can be developed using an aqueous developer to form a relief pattern. The aqueous developer can contain aqueous base. Examples of suitable bases include, but are not limited to, inorganic alkalis (e.g., potassium hydroxide, sodium hydroxide, ammonia water), primary amines (e.g., ethylamine, n-propylamine), secondary amines (e.g. diethylamine, di-n-propylamine), tertiary amines (e.g., triethylamine), alcoholamines (e.g. triethanolamine), quaternary ammonium salts (e.g., tetramethylammonium hydroxide, tetraethylammonium hydroxide), and mixtures thereof. The concentration of base employed will vary depending on the base solubility of the polymer employed and the specific base employed. The most preferred developers are those containing tetramethylammonium hydroxide (TMAH). Suitable concentrations of TMAH range from about 1% to about 5%. In addition, an appropriate amount of a surfactant can be added to the developer. Development can be carried out by means of immersion, spray, puddle, or other similar developing methods at temperatures from about 10° C. to about 40° C. for about 30 seconds to about 5 minutes. After development, the relief pattern can be optionally rinsed using deionized water and dried by spinning, baking on a hot plate, in an oven, or other suitable means.

Following development, in an optional step it can be advantageous to heat the exposed, coated and developed substrate to a temperature between about 70° C. and about 130° C. The exposed, coated and developed substrate is heated in this temperature range for a short period of time, typically several seconds to several minutes and can be carried out using any suitable heating means. Preferred means include baking on a hot plate or in a convection oven. This process step is commonly referred to in the art as post-develop baking.

The benzoxazole ring can then be formed by curing of the uncured relief pattern to obtain the final high heat resistant pattern. Curing can be performed by baking the developed, uncured relief pattern at or above the glass transition temperature T_{g} of the photosensitive composition to obtain the benzoxazole ring that provides high heat resistance. Typically, temperatures above about 200° C. are used.

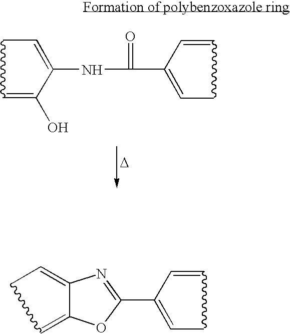

Preferably, temperatures from about 250° C. to about 400° C. are applied. The curing time is from about 15 minutes to about 24 hours depending on the particular heating method employed. A more preferred range for the curing time is from about 20 minutes to about 5 hours and the most preferred range of curing time is from about 30 minutes to about 3 hours. Curing can be done in air or preferably, under a blanket of nitrogen and may be carried by any suitable heating means. Preferred means include baking on a hot plate, a convection oven, tube furnace, vertical tube furnace, or rapid thermal processor. Alternatively, curing can be effected by the action of microwave or infrared radiation.

The photosensitive resin compositions can be used to prepare a buffer coat for use in various semiconductor devices. Exemplary semiconductor devices include semiconductor chips and interlayer dielectrics.

In some embodiments, the present disclosure relates to a chemically amplified positive tone photosensitive buffer coat composition including:

(a) at least one polybenzoxazole precursor polymer having Structure (XV), (XVI), or (XVI*) described in the Summary section above;

(b) at least one polymer having a moiety of Structure (V) (e.g., an un-endcaped polymer of Structure (V), or an endcapped polymer of Structure (VI) or (VI*)) described in the Summary section above,

(c) optionally at least one solvent; and

(d) optionally at least one photoacid generator (PAG) compound which releases acid upon irradiation.

Optionally, a chemically amplified photosensitive composition can contain other additives, such as photosensitizers, basic compounds, surfactants, dyes, adhesion promoters, plasticizers, and leveling agents.

Some of the hydroxyl groups in the PBO precursor polymers of Structures (I), (III), and (III*) can be reacted to yield the acid sensitive PBO precursor polymers of Structures (XV), (XVI), and (XVI*).

Examples of suitable acid sensitive groups R²⁷ that can be used in a polymer of Structure (XV), (XVI), and (XVI*) include, but are not limited to,

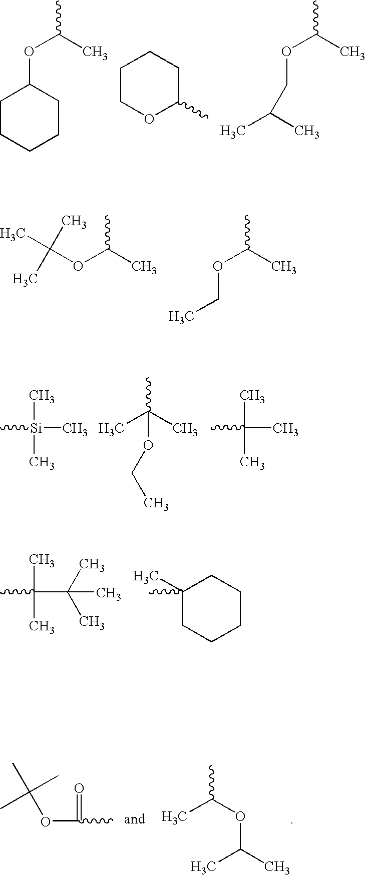

R²⁷ in combination with the O atom attached to the Ar¹ group can form groups such as acetal groups, ketal groups, ether groups, carbonate groups and silyl ethers groups. Mixtures of R²⁷ groups can also be employed.

Preferred R²⁷ groups are those groups which in combination with the O atom attached to Ar¹ form acetal groups. More preferred R²⁷ groups include, but are not limited to:

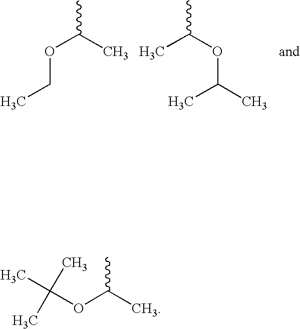

In A-O—R²⁸ in a polymer of Structure (XV), (XVI), and (XVI*), A can be any suitable divalent aromatic, aliphatic or heterocyclic group which is not acid labile and makes an -A-OH moiety an alkali solubilizing moiety. R²⁸ can be any acid labile group. Those skilled in the art will understand that after removal of R²⁸, the resultant -A-OH moiety should be solubilizing in an aqueous base. The preferred -A-OH are phenols or aromatic or aliphatic carboxylic acids. Examples of A groups include, but are not limited to, the following structures

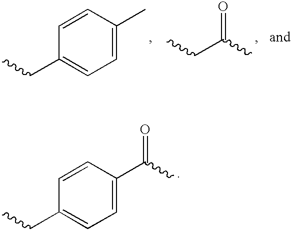

Specific examples of A-O—R²⁸ include, but are not limited to, the following structures:

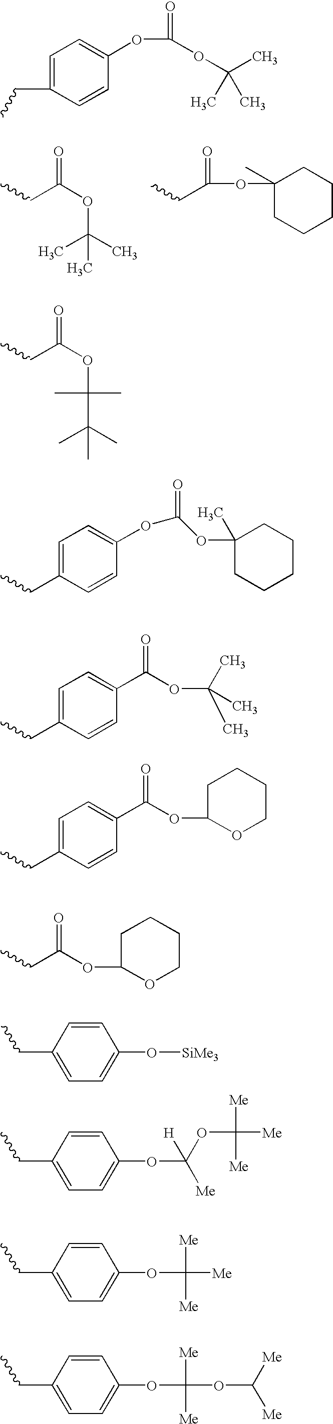

R²⁸, in combination with a portion of A, can form groups such as acetal groups, ketal groups, ether groups, silyl ethers groups, acid sensitive methylene ester groups (e.g. methylene t-butyl ester group), acid sensitive ester groups and carbonates. Mixtures of A and R²⁸ groups may be employed. When R²⁷ and R²⁸ are low activation energy groups (e.g. acetals), it is preferred that G not be derived from cyclic anhydrides, although G* may be.

Preferred A-O—R²⁸ groups are those containing acetals or acid sensitive esters. More preferred A-O—R²⁸ groups include, but are not limited to:

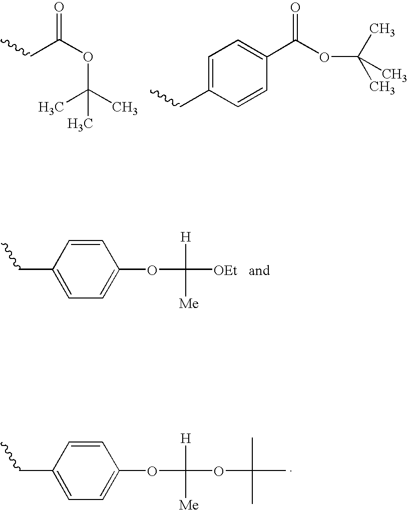

The reaction of the OH groups in monomeric units in the PBO precursor polymers of Structures (I), (III), and (III*) to generate acid sensitive groups B can be accomplished in different ways depending on which acid sensitive moiety is employed or if the spacer group J is employed. For example, the acid sensitive, end capped PBO precursor of Structure (XV) can be prepared by an acid catalyzed addition reaction of vinyl ethers with Structure (I) in a process similar to the one described in U.S. Pat. No. 6,143,467 and U.S. Pat. No. 7,132,205, the contents of which are herein incorporated by reference. Any suitable acid catalyst can be used for the reaction, for example, hydrochloric acid, p-toluene sulfonic acid and pyridinium-p-toluene sulfonate. The acid catalyst can be added in amounts ranging from 0.001 wt % to about 3.0 wt %. Several vinyl ethers with a range of activation energies towards acid induced deprotection can be used in this reaction. The examples of such vinyl ethers include but are not limited to ethyl vinyl ether, t-butyl vinyl ether, vinyl cyclohexyl ether, 2-ethylhexyl vinyl ether, dihydrofuran, 2-methoxy-1-propene, and dihydropyran. Polymers of Structure (III) and (III*) can be reacted similarly to produce polymers of Structures (XVI) and (XVI*), respectively.

PBO precursors polymers of Structures (XV), (XVI), and (XVI*) useful in this disclosure can also be prepared using a process consisting of the acid catalyzed reaction of a PBO precursor polymer of Structure (I), (III) or (III*), t-butyl vinyl ether and an alkyl-, alkylene-, cycloalkyl-, cycloalkylalkyl or arylalkyl alcohol as described for polymers derived from hydroxystyrene in U.S. Pat. No. 6,133,412, the contents of which are herein incorporated by reference.

A typical synthetic reaction mechanism for production of an acetal protected PBO precursor described by Structure (XVI) is shown below:

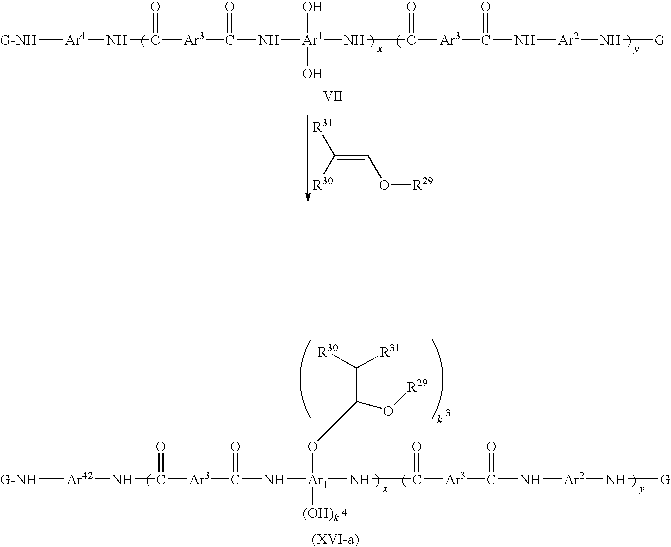

in which G, Ar¹, Ar², Ar³, Ar⁴², k³, k⁴, x and y are defined as before. Examples of R²⁹ include but are not limited to substituted or unsubstituted linear, branched or cyclic alkyl groups preferably having 1 to 18 carbon atoms, substituted or unsubstituted linear, branched or cyclic halogenated alkyl groups preferably having 1 to 18 carbon atoms, or arylalkyl groups. Examples of R³⁰ and R³¹ groups include, but are not limited to, hydrogen, linear, branched, or cyclic alkyl groups, linear or branched alkylene group bearing a cycloalkyl substituent, substituted cycloalkyl, aryl, and substituted aryl groups, preferably having 1 to 10 carbon atoms.

Another suitable method of deriving the PBO precursor polymers of Structures (XV), (XVI) and (XVI*) bearing acid labile functional groups, is from the reaction of the PBO precursor of Structure (I), (III), or (III*) with t-butyl (or other tertiary acid sensitive group) bromoacetate in the presence of base as described for polymers containing hydroxystyrene units in U.S. Pat. No. 5,612,170, the contents of which are herein incorporated by reference. Benzyl bromides bearing acid sensitive substituents (e.g. t-butyl esters, carbonates, or alpha alkoxy esters) may be reacted in a similar fashion. Silyl group protected PBO precursor polymers of Structures (XV), (XVI) and (XVI*) may be prepared similarly by reacting the polymer with silyl halides under basic conditions. Ether (e.g. t-butyl) protected PBO precursor polymers of Structures (XV), (XVI), and (XVI*) can be prepared using standard synthetic procedures for the conversion of alcohol groups to ether groups.

PBO precursor polymers of this disclosure have a k³ from about 0.1 to about 2. A preferred value for k³ is from about 0.1 to about 1.5. A more preferred value for k³ is from about 0.2 to about 1.2. The most preferred value for K³ is from about 0.3 to about 0.8. The corresponding values for k⁴ are 2-k³.

The chemically amplified positive-working composition of the present disclosure can include compounds which release acid upon exposure to radiation. Such materials are commonly called photoacid generators (PAGs). PAGs used in the present disclosure are preferably active to the radiation between about 300 nm to about 460 nm. They typically form a homogeneous solution in the photosensitive composition and produce strong acid upon irradiation. Examples of such acids include hydrogen halides or a sulfonic acid. The classes of such PAGs include, but are not limited to, oxime sulfonates, triazines, diazoquinone sulfonates, or sulfonium or iodonium salts of sulfonic acids. Examples of suitable PAGs include but are not limited to:

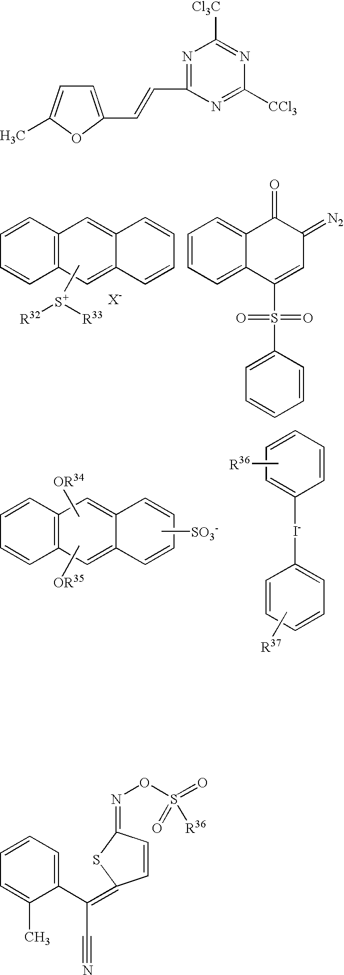

where R³² and R³³ are each independently linear, branched or cyclic alkyl or aryl group containing 1 to 20 carbon atoms and X⁻ is R³⁹SO₃⁻ (R³⁹ is a substituted or unsubstituted, linear, branched or cyclic C₁-C₂₅ alkyl or an single or multinuclear aryl group having a total of from 6 to 25 carbons); R³⁴, R³⁵, R³⁶ and R³⁷ are independently linear, branched or cyclic alkyl groups and R³⁸ is a linear or branched C₁-C₈ alkyl, C₅-C₈ cycloalkyl, camphoroyl or toluoyl.

Alternatively, an acid could be generated by a combination of PAG/sensitizer. In such systems, energy of radiation is absorbed by the sensitizer and transmitted in some manner to the PAG. The transmitted energy causes PAG decomposition and generation of photoacid. Any suitable photoacid generator compound can be used.

Suitable classes of photoacid generators generating sulfonic acids include, but are not limited to, sulfonium or iodonium salts, oximidosulfonates, bissulfonyldiazomethane compounds, and nitrobenzylsulfonate esters. Suitable photoacid generator compounds are disclosed, for example, in U.S. Pat. Nos. 5,558,978 and 5,468,589, the contents of which are incorporated herein by reference. Other suitable photoacid generators are perfluoroalkyl sulfonyl methides and perfluoroalkyl sulfonyl imides as disclosed in U.S. Pat. No. 5,554,664, the contents of which are incorporated herein by reference.

Suitable examples of photoacid generators also include phenacyl p-methylbenzenesulfonate, benzoin p-toluenesulfonate, α-(p-toluenesulfonyloxy)methylbenzoin, 3-(p-toluenesulfonyloxy)-2-hydroxy-2-phenyl-1-phenylpropyl ether, N-(p-dodecylbenzenesulfonyloxy)-1,8-naphthalimide and N-(phenyl-sulfonyloxy)-1,8-napthalimide.

Examples of suitable onium salts included but are not limited to, triphenyl sulfonium bromide, triphenyl sulfonium chloride, triphenyl sulfonium iodide, triphenyl sulfonium methane sulfonate, triphenyl sulfonium trifluoromethane-sulfonate, triphenyl sulfonium hexafluoropropanesulfonate, triphenyl sulfonium nonafluorobutanesulfonate, triphenyl sulfonium perfluorooctanesulfonate, triphenyl sulfonium phenyl sulfonate, triphenyl sulfonium 4-methyl phenyl sulfonate, triphenyl sulfonium 4-methoxyphenyl sulfonate, triphenyl sulfonium 4-chlorophenyl sulfonate, triphenyl sulfonium camphorsulfonate, 4-methylphenyl-diphenyl sulfonium trifluoromethanesulfonate, bis(4-methylphenyl)-phenyl sulfonium trifluoromethanesulfonate, tris-4-methylphenyl sulfonium trifluoromethanesulfonate, 4-tert-butylphenyl-diphenyl sulfonium trifluoromethanesulfonate, 4-methoxyphenyl-diphenyl sulfonium trifluoromethanesulfonate, mesityl-diphenyl sulfonium trifluoromethanesulfonate, 4-chlorophenyl-diphenyl sulfonium trifluoromethanesulfonate, bis(4-chlorophenyl)-phenyl sulfonium trifluoromethanesulfonate, tris(4-chlorophenyl) sulfonium trifluoromethanesulfonate, 4-methylphenyl-diphenyl sulfonium hexafluoropropanesulfonate, bis(4-methylphenyl)-phenyl sulfonium hexafluoropropanesulfonate, tris-4-methylphenyl sulfonium hexafluoropropanesulfonate, 4-tert-butylphenyl-diphenyl sulfonium hexafluoropropane sulfonate, 4-methoxyphenyl-diphenyl sulfonium hexafluoropropane sulfonate, mesityl-diphenyl sulfonium hexafluoropropane sulfonate, 4-chlorophenyl-diphenyl sulfonium hexafluoropropane sulfonate, bis(4-chlorophenyl)-phenyl sulfonium hexafluoropropane sulfonate, tris(4-chlorophenyl) sulfonium hexafluoropropane sulfonate, 4-methylphenyl-diphenyl sulfonium perfluorooctanesulfonate, bis(4-methylphenyl)-phenyl sulfonium perfluorooctanesulfonate, tris-4-methylphenyl sulfonium perfluoroocatanesulfonate, 4-tert-butylphenyl-diphenyl sulfonium perfluorooctane sulfonate, 4-methoxyphenyl-diphenyl sulfonium perfluorooctane sulfonate, mesityl-diphenyl sulfonium perfluorooctane sulfonate, 4-chlorophenyl-diphenyl sulfonium perfluorooctane sulfonate, bis(4-chlorophenyl)-phenyl sulfonium perfluorooctane sulfonate, tris(4-chlorophenyl) sulfonium perfluorooctane sulfonate, diphenyl iodonium hexafluoropropane sulfonate, diphenyl iodonium 4-methylphenyl sulfonate, bis(4-tert-butylphenyl)iodonium trifluoromethane sulfonate, bis(4-tert-butylphenyl)iodonium hexafluoromethane sulfonate, and bis(4-cyclohexylphenyl)iodonium trifluoromethane sulfonate.

Further examples of suitable photoacid generators for use in this disclosure are bis(p-toluenesulfonyl)diazomethane, methylsulfonyl p-toluenesulfonyldiazomethane, 1-cyclo-hexylsulfonyl-1-(1,1-dimethylethylsulfonyl diazomethane, bis(1,1-dimethylethylsulfonyl)diazomethane, bis(1-methylethyl-sulfonyl)diazomethane, bis(cyclohexylsulfonyl)diazomethane, 1-p-toluenesulfonyl-1-cyclohexylcarbonyldiazomethane, 2-methyl-2-(p-toluenesulfonyl)propiophenone, 2-methanesulfonyl-2-methyl-(4-methylthiopropiophenone, 2,4-methyl-2-(p-toluenesulfonyl)pent-3-one, 1-diazo-1-methylsulfonyl-4-phenyl-2-butanone, 2-(cyclohexylcarbonyl-2-(p-toluenesulfonyl)propane, 1-cyclohexylsulfonyl-1cyclohexylcarbonyldiazomethane, 1-diazo-1-cyclohexylsulfonyl-3,3-dimethyl-2-butanone, 1-diazo-1-(1,1-dimethylethylsulfonyl)-3,3-dimethyl-2-butanone, 1-acetyl-1-(1-methylethyl-sulfonyl)diazomethane, 1-diazo-1-(p-toluenesulfonyl)-3,3-dimethyl-2-butanone, 1-diazo-1-benzenesulfonyl-3,3-dimethyl-2-butanone, 1-diazo-1-(p-toluenesulfonyl)-3-methyl-2-butanone, cyclohexyl 2-diazo-2-(p-toluenesulfonyl)-acetate, tert-butyl 2-diazo-2-benzenesulfonylacetate, isopropyl-2-diazo-2-methanesulfonylacetate, cyclohexyl 2-diazo-2-benzenesulfonylacetate, tert-butyl 2 diazo-2-(p-toluenesulfonyl)acetate, 2-nitrobenzyl p-toluenesulfonate, 2,6-dinitrobenzyl p-toluenesulfonate, 2,4-dinitrobenzyl p-trifluoromethylbenzenesulfonate.

Examples of sensitizers include but are not limited to: 9-methylanthracene, anthracenemethanol, acenaththalene, thioxanthone, methyl-2-naphthyl ketone, 4-acetylbiphenyl, 1,2-benzofluorene, 9,10-dimethoxyanthracene, and 9,10-dibutoxyanthracene.

The chemically amplified positive acting photosensitive resin composition of this embodiment include at least one polymer having a moiety of Structure (V) (e.g., a polymer of Structure (V), (VI), or (VI*) or any mixtures thereof) as described above.

Suitable solvents of this photosensitive composition can be polar organic solvents. Suitable examples of polar organic solvents include, but are not limited to, N-methyl-2-pyrrolidone (NMP), N-ethyl-2-pyrrolidone, gamma-butyrolactone (GBL), N,N-dimethylacetamide (DMAc), dimethyl-2-piperidone, N,N-dimethylformamide (DMF), and mixtures thereof. The preferred solvents are gamma-butyrolactone, N-ethyl-2-pyrrolidone and N-methyl-2-pyrrolidone. The most preferred solvent is gamma-butyrolactone.

Examples of organic solvent soluble, aqueous base soluble, aromatic or heterocyclic group polymers or copolymers can include polyimides, polyamic esters, polybenzoimidazoles, polybenzothiazoles, polytriazoles, polyquinazolones, polyquinazolindiones, polyquinacridones, polybenxazinones, polyanthrazolines, polyoxadiazoles, polyhydantoins, polyindophenazines, or polythiadiazoles. Polyamic acids can also be employed as a co-resin, but preferably is employed only when a high-energy activation acid sensitive group (e.g. a tertiary ester) is employed on the polybenzoxazole precursor polymer of Structure (XV), (XVI) or (XVI*).

The chemically amplified positive working photosensitive polybenzoxazole precursor composition of the present disclosure can contain one or more polybenzoxazole precursors of Structure (XV), (XVI) or (XVI*) at about 10 wt. % to about 50 wt. % of the composition. Preferably, about 20 wt. % to about 45 wt. %, more preferably, about 25 wt. % to 42.5 wt. % and most preferably, about 30 wt. % to 40 wt. % of the polybenzoxazole precursor of Structure (XV), (XVI) or (XVI*) is present in the composition.

The amount of PAG can range from about 0.1 to about 7% (wt) of the photosensitive composition. A preferred amount of PAG is from about 0.5 to about 5% (wt) based on the amount of the composition. A more preferred amount of PAG is from about 0.7 to about 4% (wt) based on the amount of the composition. The amount of optional sensitizer can be from about 0.03 to about 2% (wt) based on the amount of the composition.

The chemically amplified positive working photosensitive polybenzoxazole precursor composition of the present disclosure can contain at least one polymer having a moiety of Structure (V) (e.g., a polymer of Structure (V), (VI), or (VI*)) at about 0.05 wt. % to about 10 wt. % of the composition. Preferably, about 0.1 wt. % to about 5 wt. %, more preferably, about 0.2 wt. % to 3 wt. % and most preferably, about 0.3 wt. % to 2 wt. % of at least one polymer having a moiety of Structure (V) is present in the composition.

The photosensitive compositions of this disclosure can optionally comprise a basic compound selected from the group consisting of tertiary amines, hindered secondary amines, non-aromatic cyclic amines and quaternary ammonium hydroxides.

Tertiary amines having alkyl and/or aromatic groups are defined by Structure (XVII) in which R⁴⁰, R⁴¹, and R⁴² are independently selected from the group consisting of a C₁-C₃₀ substituted or unsubstituted linear, branched, or cyclic alkyl, a C₃-C₃₀ tertiary aminoalkyl, a C₂-C₃₀ substituted or unsubstituted linear, branched, or cyclic hydroxyalkyl, a C₆-C₃₀ substituted or unsubstituted aryl, or a C₁-C₃₀ alkyl group containing at least one ether linkage, with the provisos that the sum of carbons contained in R⁴⁰, R⁴¹, and R⁴² is at least 6 and if one of R⁴⁰, R⁴¹, and R⁴² is a substituted or unsubstituted phenyl group, then the other two can not simultaneously be hydroxyalkyl groups.

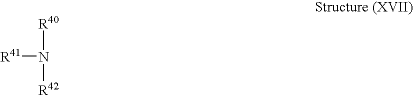

Examples of compounds of Structure (XVII) include, but are not limited to, the following compounds:

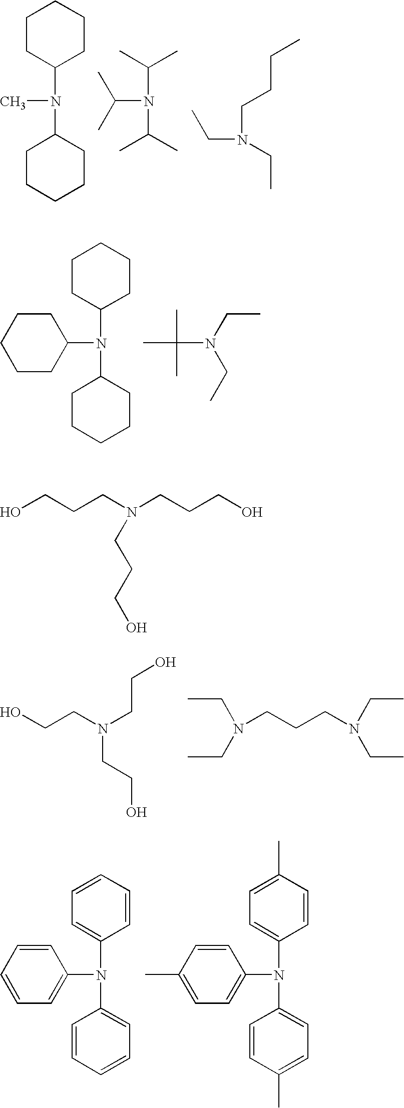

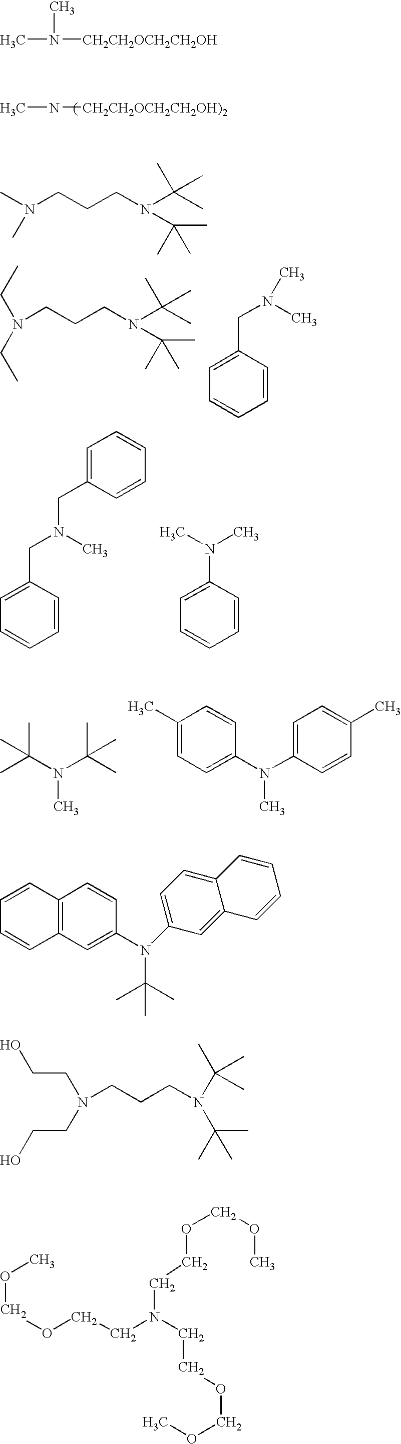

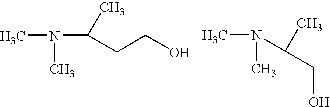

In one embodiment, preferred tertiary amines are those tertiary amines described by Structure (XVII) in which at least one of R⁴⁰, R⁴¹, and R⁴² is a C₁-C₃₀ alkyl group containing at least one ether linkage. In another embodiment, preferred tertiary amines are those tertiary amines described by Structure (XVII) in which R⁴⁰, R⁴¹, and R⁴² are independently selected from the group consisting of a C₃-C₃₀ substituted or unsubstituted linear, branched, or cyclic alkyl, a C₃-C₁₅ tertiary aminoalkyl, a C₃-C₃₀ substituted or unsubstituted linear, branched, or cyclic hydroxyalkyl, a C₆-C₃₀ substituted or unsubstituted aryl and which are “hindered”. Hindered tertiary amines are hereby defined as tertiary amines in which at least two of R⁴⁰, R⁴¹, and R⁴² have at least two substituents on the carbon bonded to the tertiary nitrogen as illustrated in Structure (XVIII), in which R⁴⁴, R⁴⁵, and R⁴⁶ are independently selected from the group consisting of hydrogen, a C₃-C₃₀ substituted or unsubstituted linear, branched, or cyclic alkyl, a C₃-C₁₅ tertiary aminoalkyl, a C₃-C₃₀ substituted or unsubstituted linear, branched, or cyclic hydroxyalkyl, a C₆-C₃₀ substituted or unsubstituted aryl and at least two of R⁴⁴, R⁴⁵, and R⁴⁶ are not hydrogen atoms. Two of R⁴⁴, R⁴⁵, and R⁴⁶ can be connected to form a ring.

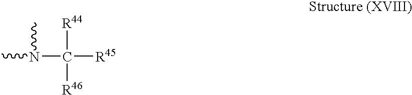

Examples of hindered tertiary amines include, but are not limited to, the following compounds:

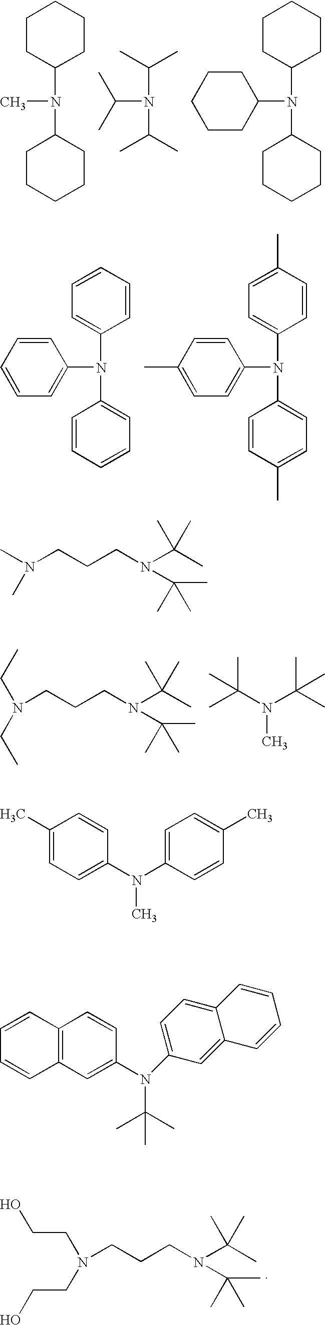

In one embodiment, the more preferred tertiary amines are those tertiary amines described by Structure (XVII) in which at least one of R⁴⁰, R⁴¹, and R⁴² is a C₃-C₁₅ alkyl group containing at least one ether linkage. In another embodiment, the more preferred tertiary amines are those hindered tertiary amines described by Structure (XVII) in which R⁴⁰, R⁴¹, and R⁴² are independently selected from the group consisting of a C₃-C₁₅ substituted or unsubstituted linear, branched, or cyclic alkyl, a C₃-C₁₀ tertiary aminoalkyl, a C₃-C₁₅ substituted or unsubstituted linear, branched, or cyclic hydroxyalkyl, a C₆-C₁₀ substituted or unsubstituted aryl.

In one embodiment, the most preferred tertiary amines are those tertiary amines described by Structure (XVII) wherein at least two of R⁴⁰, R⁴¹, and R⁴² are a C₃-C₁₅ alkyl groups containing at least one ether linkage. In another embodiment, the most preferred tertiary amines are those hindered tertiary amines described by Structure (XVII) in which R⁴⁰, R⁴¹, and R⁴² are independently selected from the group consisting of a C₃-C₁₀ substituted or unsubstituted linear, branched, or cyclic alkyl, a C₃-C₆ tertiary aminoalkyl, a C₃-C₁₀ substituted or unsubstituted linear, branched, or cyclic hydroxyalkyl, a substituted or unsubstituted phenyl group.

Hindered secondary amines are amines defined by Structure (XVII) in which R⁴⁰ is a hydrogen atom and R⁴¹ and R⁴² are independently selected from the group consisting of a C₃-C₃₀ substituted or unsubstituted linear, branched, or cyclic alkyl, a C₃-C₃₀ tertiary aminoalkyl, a C₃-C₃₀ substituted or unsubstituted linear, branched, or cyclic hydroxyalkyl, a C₆-C₃₀ substituted or unsubstituted aryl, and a C₃-C₃₀ alkyl group containing at least one ether linkage and in which R⁴¹ and R⁴² have at least two substituents on the carbon bonded to the nitrogen as illustrated in Structure (XVII). Examples of hindered secondary amines include, but are not limited to, diphenylamine, dicyclohexylamine, di-t-butylamine, t-butyl-phenylamine, t-butyl-cyclohexylamine, diisopropylamine, di-t-amylamine, phenyl-cyclohexylamine, phenyl-napthylamine, dinaphthylamine, dianthracenylamine, and compounds represented by the following structures:

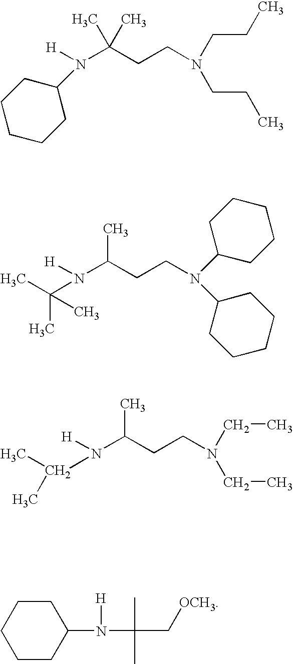

Preferred hindered secondary amines are amines defined by Structure (XVII) in which R⁴⁰ is a hydrogen atom and R⁴¹ and R⁴² are independently selected from the group consisting of a C₃-C₁₅ substituted or unsubstituted linear, branched, or cyclic alkyl, a C₃-C₁₅ tertiary aminoalkyl, a C₃-C₁₅ substituted or unsubstituted linear, branched, or cyclic hydroxyalkyl, a C₆-C₁₀ substituted or unsubstituted aryl, and a C₃-C₁₅ alkyl group containing at least one ether linkage and in which R⁴¹ and R⁴² have at least two substituents on the carbon bonded to the nitrogen as illustrated in Structure (XVIII).

More preferred hindered secondary amines are amines defined by Structure (XVII) in which R⁴⁰ is a hydrogen atom and R⁴¹ and R⁴² are independently selected from the group consisting of a C₃-C₁₀ substituted or unsubstituted linear, branched, or cyclic alkyl, a C₃-C₁₀ tertiary aminoalkyl, a C₃-C₁₀ substituted or unsubstituted linear, branched, or cyclic hydroxyalkyl, a substituted or unsubstituted phenyl group and a C₃-C₁₅ alkyl group containing at least one ether linkage and in which R⁴¹ and R⁴² have at least two substituents on the carbon bonded to the nitrogen as illustrated in Structure (XVII).

Most preferred hindered secondary amines are amines defined by Structure (XVII) in which R⁴⁰ is a hydrogen atom and R⁴¹ and R⁴² are independently selected from the group consisting of a C₃-C₁₀ substituted or unsubstituted linear, branched, or cyclic alkyl, a C₃-C₁₀ substituted or unsubstituted linear, branched, or cyclic hydroxyalkyl, a substituted or unsubstituted phenyl group and a C₃-C₁₅ alkyl group containing at least one ether linkage and in which R⁴¹ and R⁴² have at least two substituents on the carbon bonded to the nitrogen as illustrated in Structure (XVII) and at least one of R⁴¹ and R⁴² is selected from a substituted or unsubstituted cyclohexyl group, a substituted or unsubstituted phenyl group, and a group having three substituents on the carbon bonded to the nitrogen (i.e., none of R⁴⁴, R⁴⁵, and R⁴⁶ shown in Structure (XVII) are hydrogen atoms).

Non-aromatic cyclic amines are amines in which the amine nitrogen is incorporated into a primarily carbocyclic ring structure which may contain additional heteroatoms such as oxygen, sulfur, or another nitrogen. The ring structure may be monocyclic, bicyclic, or tricyclic, and may contain double bonds. Examples of classes of non-aromatic cyclic amines include, but are not limited to, amines described by Structures (XIX), (XX), and tertiary alicyclic amines.

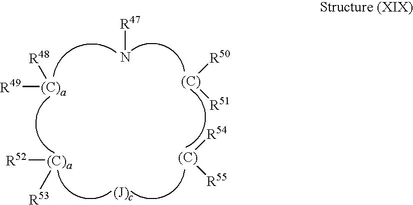

In Structure (XIX), R⁴⁷ is a hydrogen atom, a C₁-C₆ substituted or unsubstituted linear, branched, or cyclic alkyl, or a substituted or unsubstituted C₆-C₁₀ aryl; R⁴⁸, R⁴⁹, R⁵⁰, R⁵¹. R⁵², R⁵³, R⁵⁴, and R⁵⁵ are independently a hydrogen atom, a C₁-C₆ substituted or unsubstituted linear, branched, or cyclic alkyl, or a substituted or unsubstituted C₆-C₁₀ aryl; J is an oxygen atom, a sulfur atom, or a NR⁵⁶ group where R⁵⁶ is a hydrogen atom, a C₁-C₆ substituted or unsubstituted linear, branched, or cyclic alkyl, or a substituted or unsubstituted C₆-C₁₀ aryl; a and b are independently 1, 2, or 3 and c is 0 or 1.

Examples of suitable non-aromatic cyclic amines of Structure (XIX) include, but are not limited to, morpholine, N-methylmorpholine, 2,6-dimethylmorpholine, 2,2,6,6-tetramethylmorpholine, N-hydroxyethyl morpholine, N-ethyl morpholine, thiomorpholine, N-methylthiomorpholine, 2,6-dimethylthiomorpholine, 2,2,6,6-tetramethylthiomorpholine, piperidine, N-hydroxyethylpiperidine, 2,6-dimethyl piperidine, 2,2,6,6-tetramethylpiperidine, pyrrolidine, N-methylpyrrolidine, N-ethyl pyrrolidine, 2,5-dimethylpyrrolidine 2,2,5,5-tetramethylpyrrolidine, piperazine, N,N′-dimethylpiperazine, and N,N′-diethylpiperazine.

Preferred non-aromatic cyclic amines of Structure (XIX) are those in which R⁴⁷ is a C₁-C₆ substituted or unsubstituted linear, branched, or cyclic alkyl, or a substituted or unsubstituted C₆-C₁₀ aryl and where R⁴⁷ is a hydrogen atom and at least two of R⁴⁸, R⁴⁹, R⁵⁰, and R⁵¹ are independently a C₁-C₆ substituted or unsubstituted linear, branched, or cyclic alkyl. Preferred examples of non-aromatic cyclic amines include, but are not limited to, N-methylmorpholine, 2,6-dimethylmorpholine, 2,2,6,6-tetramethylmorpholine, N-hydroxyethyl morpholine, N-ethyl morpholine, N-hydroxyethylpiperidine, 2,6-dimethyl piperidine, 2,2,6,6-tetramethylpiperidine, N-methylpyrrolidine, N-ethyl pyrrolidine, 2,5-dimethylpyrrolidine 2,2,5,5-tetramethylpyrrolidine, N,N′-dimethylpiperazine, and N,N′-diethylpiperazine.

More preferred non-aromatic cyclic amines of Structure (XIX) are those in which R⁴⁷ is a C₁-C₆ substituted or unsubstituted linear, branched, or cyclic alkyl, or a substituted or unsubstituted C₆-C₁₀ aryl and where R⁴⁷ is a hydrogen atom and R⁴⁸, R⁴⁹, R⁵⁰, and R⁵¹ are each independently a C₁-C₆ substituted or unsubstituted linear, branched, or cyclic alkyl More preferred examples of non-aromatic cyclic amines include, but are not limited to, N-methylmorpholine, 2,2,6,6-tetramethylmorpholine, N-hydroxyethyl morpholine, N-ethyl morpholine, N-hydroxyethylpiperidine, 2,2,6,6-tetramethylpiperidine, N-methylpyrrolidine, N-ethyl pyrrolidine, 2,2,5,5-tetramethylpyrrolidine, N,N′-dimethylpiperazine, and N,N′-diethylpiperazine.

Most preferred non-aromatic cyclic amines of Structure (XIX) are those in which R⁴⁷ is a C₁-C₆ substituted or unsubstituted linear, branched, or cyclic alkyl. Most preferred examples of non-aromatic cyclic amines of Structure XIX include, but are not limited to, N-methylmorpholine, N-hydroxyethyl morpholine, N-ethyl morpholine, N-hydroxyethylpiperidine, N-methylpyrrolidine, N-ethyl pyrrolidine, N,N′-dimethylpiperazine, and N,N′-diethylpiperazine.

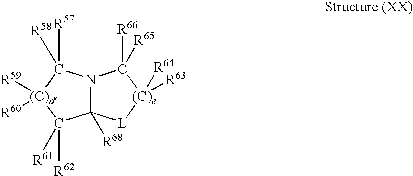

In Structure (XX) shown above, L is an oxygen atom, a sulfur atom, NR⁶⁷ or CR⁶⁹R⁷⁰; R⁶⁷ is a hydrogen atom, a C₁-C₆ substituted or unsubstituted linear, branched, or cyclic alkyl, or a substituted or unsubstituted C₆-C₁₀ aryl; R⁶⁹ and R⁷⁰ are independently selected from a hydrogen atom, a C₁-C₆ substituted or unsubstituted linear, branched, or cyclic alkyl, or a substituted or unsubstituted C₆-C₁₀ aryl; R⁵⁷-R⁶⁶ are independently selected from a hydrogen atom, a C₁-C₆ substituted or unsubstituted linear, branched, or cyclic alkyl, or a substituted or unsubstituted C₆-C₁₀ aryl; d′ is 1, 2, or 3; e is 1, 2, or 3; R⁶⁸ is a hydrogen atom or in conjunction with R⁶⁷ forms a second bond between L and the carbon to which R⁶⁸ is attached. Preferred non-aromatic cyclic amines of Structure XVII are include, but are not limited to, 1,5-diazabicyclo[4.3.0]non-5-ene, and 1,8-diazabicyclo[5.4.0]undec-7-ene.

Examples of alicyclic amines include, but are not limited to, the following compounds where R⁷² is a C₁-C₆ substituted or unsubstituted linear, branched, or cyclic alkyl, or a substituted or unsubstituted C₆-C₁₀ aryl.

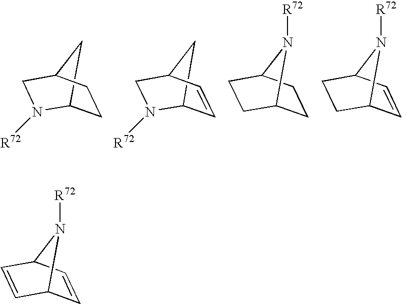

Quaternary ammonium hydroxides are ammonium hydroxides in which each of the four groups has a carbon atom attached to the positively charged nitrogen. The groups may be substituted or unsubstituted. Preferred quaternary ammonium hydroxides are described by Structure (XXI) shown below, in which R⁷¹, R⁷², R⁷³, and R⁷⁴ are independently substituted or unsubstituted linear, branched, or cyclic alkyl, substituted or unsubstituted linear, branched or cyclic hydroxyalkyl, or substituted or unsubstituted phenyl.

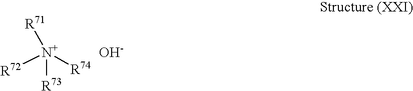

Examples of quaternary ammonium hydroxides of Structure (XXI) include, but are not limited to, the following compounds:

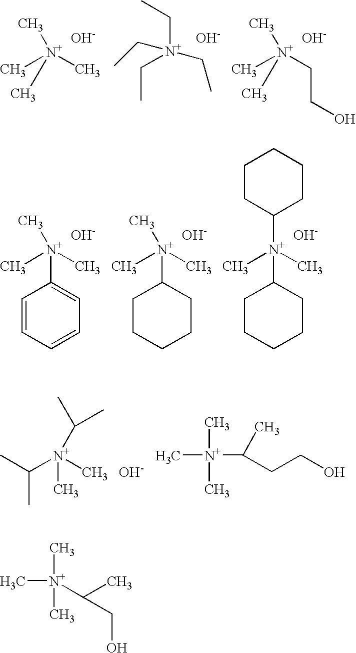

More preferred quaternary ammonium hydroxides are those of Structure (XXI) in which R⁷¹, R⁷², R⁷³, and R⁷⁴ are independently substituted or unsubstituted linear, branched, or cyclic alkyl, or substituted or unsubstituted linear, branched or cyclic hydroxyalkyl. Most preferred quaternary ammonium hydroxides are those of Structure (XXI) in which R⁷¹, R⁷², R⁷³, and R⁷⁴ are independently C₁-C₄ linear, branched, or cyclic substituted or unsubstituted alkyl, or C₂-C₄ substituted or unsubstituted, linear, branched or cyclic hydroxyalkyl.

According to one embodiment of the present disclosure, a mixture of at least two basic compounds having different structures selected from the basic compounds described above, can be used as the basic compound of component (C). Specifically, for example, two basic compounds having different structures, three basic compounds having different structures or four or more basic compounds having different structures may be used. In case of using at least two basic compounds having different structures, it is preferred that an amount of the basic compound that is used in the smallest amount is not less than 10% by weight based on the total amount of the basic compounds used.

The amount of basic compound ranges from about 0.001 wt % to about 3 wt % of the total photosensitive composition. A preferred amount of basic compound is from about 0.01 wt % to about 1.5 wt % of the total photosensitive composition. A more preferred amount of basic compound is from about 0.02 wt % to about 1 wt % of the total photosensitive composition. The most preferred amount of basic compound is from about 0.03 wt % to about 0.5 wt % of the total photosensitive composition.

The chemically amplified positive working photosensitive PBO precursor compositions of the present disclosure can optionally include at least one plasticizer. Examples of suitable plasticizers are the same as described above.

The amount of optional plasticizer used in the chemically amplified positive working photosensitive PBO precursor composition of this disclosure is from about 0.1 wt % to about 20 wt % of the total weight of the composition, preferably, from about 1 wt % to about 10 wt %, more preferably, from about 1.25 wt % to about 7.5 wt % and most preferably, from about 1.5 wt % to about 5 wt %. The plasticizers may be blended together in any suitable ratio.

The positive chemically amplified resist formulation of the present disclosure can also contain other additives, such as, but not limited to, surfactants, dyes, profile enhancing additives, and adhesion promoters.

If employed, the amount of adhesion promoter can range from about 0.1 wt % to about 5 wt % based on the amount of polybenzoxazole precursor polymer. A preferred amount of adhesion promoter is from about 0.5 wt % to about 5 wt % based on the amount of polybenzoxazole precursor polymer. A more preferred amount of adhesion promoter is from about 1 wt % to about 4 wt % based on the amount of polybenzoxazole precursor polymer. Suitable adhesion promoters include, for example, alkoxysilanes, and mixtures or derivatives thereof. Examples of suitable adhesion promoters are the same as described earlier.

In some embodiments, the present disclosure includes a process for forming a relief pattern. The process can include the steps of: (a) providing a substrate, (b) coating on said substrate, a chemically amplified positive-working photosensitive composition including (1) at least one polybenzoxazole precursor polymer having Structure (XV), (XVI), or (XVI*) described above; (2) at least one compound which releases acid upon irradiation (PAG); (3) at least one polymer having a moiety of Structure (V) (e.g., a polymer of Structure (V), (VI), or (VI*) described above, or mixtures thereof); and (4) at least one solvent, thereby forming a coated substrate; (c) exposing the coated substrate to actinic radiation; (d) post exposure baking the coated substrate at an elevated temperature of about 70° C. to about 150° C.; (e) developing the coated substrate with an aqueous base developer, thereby forming a developed relief pattern; and (f) baking the substrate at an elevated temperature sufficient to cure the composition to produce a polybenzoxazole relief image. The curing temperature can range from about 250° C. to about 400° C.

The positive working photosensitive PBO precursor compositions of this disclosure can be coated on a suitable substrate. The coating can have a thickness of at least about 5 μm (e.g., at least about 8 μm or at least about 10 μm) and/or at most about 50 μm (e.g., at most about 20 μm or at most about 15 μm). The substrate can be, for example, semiconductor materials such as a silicon wafer, compound semiconductor (Groups III-V) or (Groups II-VI) wafer, a ceramic, glass or quartz substrate. The substrates may also contain films or structures used for electronic circuit fabrication such as organic or inorganic dielectrics, copper or other wiring metals.

To ensure proper adhesion of the photosensitive composition to the substrate the substrate can optionally be treated before coating with an (external) adhesion promoter before the first coating step or the photosensitive composition may employ an internal adhesion promoter. Any suitable method of treatment of the substrate with adhesion promoter known to those skilled in the art may be employed. Examples include treatment of the substrate with adhesion promoter vapors, solutions or at 100% concentration. The time and temperature of treatment will depend on the particular substrate, adhesion promoter, and method, which may employ elevated temperatures. Any suitable external adhesion promoter may be employed. Classes of suitable external adhesion promoters include but are not limited to vinylalkoxysilanes, methacryloxalkoxysilanes, mercaptoalkoxysilanes, aminoalkoxysilanes, epoxyalkoxysilanes and glycidoxyalkoxysilanes. Aminosilanes and glycidoxysilanes are more preferred. Primary aminoalkoxysilanes are more preferred. Examples of suitable external adhesion promoters include, but are not limited to, gamma-aminopropyltrimethoxysilane, gamma-glycidoxypropylmethyldimethoxysilane, gamma-glycidoxypropylmethyldiethoxysilane, gamma-mercaptopropylmethyldimethoxysilane, 3-methacryl-oxypropyldimethoxymethylsilane, and 3-methacryloxypropyltrimethoxysilane. gamma-Aminopropyltrimethoxysilane is more preferred. Additional suitable adhesion promoters are described in “Silane Coupling Agent” Edwin P. Plueddemann, 1982 Plenum Press, New York, the contents of which are herein incorporated by reference.

Coating methods include, but are not limited to, spray coating, spin coating, offset printing, roller coating, screen printing, extrusion coating, meniscus coating, curtain coating, and immersion coating. The resulting film is prebaked at an elevated temperature.

The baking may be carried out at one or more temperatures within the temperature range of about 70° C. to about 150° C. Preferably the temperature range is about 80° C. to about 130° C., more preferably the temperature range is about 90° C. to about 120° C. and most preferably the coatings are baked from about 100° C. to about 120° C.

The duration of the baking can be for several minutes to half an hour, depending on the method to evaporate the remaining solvent. Any suitable baking means may be employed. Examples of suitable baking means include, but are not limited to, hot plates and convection ovens. The resulting dry film can have a thickness of from about 3 to about 50 microns or more preferably from about 4 to about 20 microns or most preferably from about 5 to about 15 microns.

After the baking step, the resulting dry film can be exposed to actinic rays in a preferred pattern through a mask. X-rays, electron beam, ultraviolet rays, visible light, and the like can be used as actinic rays. The most preferred rays are those with wavelength of 436 nm (g-line) and 365 nm (1-line).

Following exposure to actinic radiation, it can be advantageous to heat the exposed and chemically amplified positive working photosensitive PBO precursor composition coated substrate to a temperature between about 70° C. to about 150° C. Preferably the temperature range is about 80° C. to about 140° C. More preferably the temperature range is about 90° C. to about 130° C. Most preferably the temperature range is about 100° C. to about 130° C.

The exposed and coated substrate can be heated in this temperature range for a short period of time, typically several seconds to several minutes and can be carried out using any suitable heating means. Preferred means include baking on a hot plate or in a convection oven. This process step is commonly referred to in the art as post-exposure baking.

Next, the film can be developed using an aqueous developer to form a relief pattern. The aqueous developer can contain aqueous base. Examples of suitable bases include, but are not limited to, inorganic alkalis (e.g., potassium hydroxide, sodium hydroxide, ammonia water), primary amines (e.g., ethylamine, n-propylamine), secondary amines (e.g. diethylamine, di-n-propylamine), tertiary amines (e.g., triethylamine), alcoholamines (e.g. triethanolamine), quaternary ammonium salts (e.g., tetramethylammonium hydroxide, tetraethylammonium hydroxide), and mixtures thereof. The concentration of base employed will vary depending on the base solubility of the polymer employed and the specific base employed. The most preferred developers are those containing tetramethylammonium hydroxide (TMAH). Suitable concentrations of TMAH range from about 1% to about 5%. In addition, an appropriate amount of a surfactant can be added to the developer. Development can be carried out by means of immersion, spray, puddle, or other similar developing methods at temperatures from about 10° C. to about 40° C. for about 30 seconds to about 5 minutes. After development, the relief pattern may be optionally rinsed using deionized water and dried by spinning, baking on a hot plate, in an oven, or other suitable means.

Following development, in an optional step it can be advantageous to heat the exposed, coated and developed substrate to a temperature between about 70° C. to about 220° C. Preferably the temperature range is about 80° C. to about 210° C. More preferably the temperature range is about 80° C. to about 200° C. The most preferred temperature range is about 90° C. to about 180° C. The exposed, coated and developed substrate is heated in this temperature range for a short period of time, typically several seconds to several minutes and may be carried out using any suitable heating means. Preferred means include baking on a hot plate or in a convection oven. This process step is commonly referred to in the art as post-develop baking.

The benzoxazole ring can then be formed by curing of the uncured relief pattern to obtain the final high heat resistant pattern. Curing can be performed by baking the developed, uncured relief pattern at or above the glass transition temperature T_{g} of the positive working photosensitive PBO precursor composition to obtain the benzoxazole ring that provides high heat resistance. Typically, temperatures above about 200° C. are used. Preferably, temperatures from about 250° C. to about 400° C. are applied. The curing time can be from about 15 minutes to about 24 hours depending on the particular heating method employed. A more preferred range for the curing time is from about 20 minutes to about 5 hours and the most preferred range of curing time is from about 30 minutes to about 3 hours. Curing can be done in air or preferably, under a blanket of nitrogen and may be carried by any suitable heating means. Preferred means include baking on a hot plate, a convection oven, tube furnace, vertical tube furnace, or rapid thermal processor. Alternatively, curing may be effected by the action of microwave or infrared radiation.

The application of current silicon-containing polymers having a moiety of Structure (V) (e.g., polymers of Structure (V), (VI), or (VI*)) can be extended to non-photosensitive compositions. For example, another aspect of this invention relates to a non-photosensitive composition include:

(a) one or more polyamic acid

(b) at least one polymer having a moiety of Structure (V) described in the Summary section above, or mixtures thereof, and

(c) optionally at least one solvent.

Polyamic acids may be prepared by reacting one or more dianhydride with one or more diamines. Examples of suitable dianhydrides include, but are not limited to the to 3,3′,4,4′-biphenyltetracarboxylic acid dianhydride, 3,3′,4,4′diphenylsulfidetetracarboxylic acid dianhydride, 3,3′4,4′-diphenylsulfon-tetracarboxylic acid dianhydride, 3,3′,4,4′-benzophenone tetracarboxylic acid dianhydride, 3,3′,4,4′-diphenylmethanetetracarboxylic acid dianhydride, 2,2′,3,3′-diphenylmethanetetracarboxylic acid dianhydride, 2,3,3′,4′-biphenyltetra-carboxylic acid dianhydride, 2,3,3′,4′-benzophenonetetracarboxylic acid dianhydride, dianhydrides of oxydiphthalic acids, particularly 3,3′,4,4′-diphenyloxidetetracarboxylic acid dianhydride (4,4′-oxydiphthalic acid dianhydride), 2,3,6,7-naphthalenetetracarboxylic acid dianhydride, 1,4,5,7-naphtnalenetetracarboxylic acid dianhydride, 2,2-bis(3,4-dicarboxyphenyl)-propane dianhydride, 2,2-bis(2,3-dicarboxyphenyl)propane dianhydride, 2,2-bis(3,4-dicarboxyphenyl)hexafluoropropane dianhydride, 1,3-diphenyl-hexafluoropropane-3,3,4,4-tetracarboxylic acid dianhydride, 1,4,5,6-naphthalenetetracarboxylic dianhydride, 2,2′,3,3′-diphenyltetracarboxylic acid dianhydride, 3,4,9,10-perylenetetracarboxylic acid dianhydride, 1,2,4,5 naphthalenetetracarboxylic acid dianhydride, 1,4,5,8-naphthalenetetracarboxylic acid dianhydride, 1,8,9,10-phenanthrenetetracarboxylic acid dianhydride, 1,1-bis(2,3-dicarboxyphenyl)ethane dianhydride, 1,1-bis(3,4-dicarboxyphenyl)ethane dianhydride, 1,2,3,4-benzenetetracarboxylic acid dianhydride and 1,2,4,5-benzenetetracarboxylic acid dianhydride (pyromellitic dianhydride, PMDA).

Examples of diamine monomers include but are not limited to 5(6)-amino-1-(4-aminophenyl)-1,3,3-trimethylindane (DAPI), m-phenylenediamine, p-phenylenediamine, 2,2′-bis(trifluoromethyl)-4,4′-diamino-1,1′-biphenyl, 3,4′-diaminodiphenyl ether, 4,4′-diaminodiphenyl ether, 3,3′-diaminodiphenyl ether, 2,4-tolylenediamine, 3,3′-diaminodiphenyl sulfone, 3,4′-diaminodiphenyl sulfone, 4,4′-diaminodiphenyl sulfone, 3,3′-diaminodiphenylmethane, 4,4′-diamino-diphenylmethane, 3,3′-diaminodiphenylmethane, 3,4′-diaminodiphenylmethane, 4,4′-diaminodiphenyl ketone, 3,3′-diaminodiphenyl ketone, 3,4′-diaminodiphenyl ketone, 1,3-bis(4-aminophenoxy)benzene, 1,3-bis(3-amino-phenoxy)benzene, 1,4-bis(γ-aminopropyl)tetramethyldisiloxane, 2,3,5,6-tetramethyl-p-phenylenediamine, m-xylylenediamine, p-xylylenediamine, methylenediamine, tetramethylenediamine, pentamethylenediamine, hexamethylenediamine, 2,5-dimethylhexamethylenediamine, 3-methoxyhexamethylenediamine, heptamethylenediamine, 2,5-dimethylheptamethylenediamine, 3-methylheptamethylenediamine, 4,4-dimethylheptamethylenediamine, octamethylenediamine, nonamethylenediamine, 2,5-dimethylnonamethylenediamine, decamethylenediamine, ethylenediamine, propylenediamine, 2,2-dimethylpropylenediamine, 1,10-diamino-1,10-dimethyldecane, 2,11-diaminidodecane, 1,12-diaminooctadecane, 2,17-diaminoeicosane, 3,3′-dimethyl-4,4′-diaminodiphenylmethane, bis(4-aminocyclohexyl)methane, bis(3-aminonorbornyl)methane, 3,3′-diaminodiphenylethne, 4,4′-diaminodiphenylethne, and 4,4′-diaminodiphenyl sulfide, 2,6-diaminopyridine, 2,5-diaminopyridine, 2,6-diamino-4-trifluoromethylpyridine, 2,5-diamino-1,3,4-oxadiazole, 1,4-diaminocyclohexane, piperazine, 4,4′-methylenedianiline, 4,4′-methylene-bis(o-choloroaniline), 4,4′-methylene-bis(3-methylaniline), 4,4′-methylene-bis(2-ethylaniline), 4,4′-methylene-bis(2-methoxyaniline), 4,4′-oxy-dianiline, 4,4′-oxy-bis-(2-methoxyaniline), 4,4′-oxy-bis-(2-chloroaniline), 4,4′-thio-dianiline, 4,4′-thio-bis-(2-methylaniline), 4,4′-thio-bis-(2-methyoxyaniline), 4,4′-thio-bis-(2-chloroaniline), 3,3′sulfonyl-dianiline, and 3,3′sulfonyl-dianiline. Synthesis of polyamic acid is described in U.S. Pat. No. 7,018,776 which is incorporated by reference.

Another embodiment of the present disclosure concerns a process for forming a relief image using the non-photosensitive compositions described above. The process can include the steps of:

(a) providing a substrate;

(b) in a first coating step, coating the substrate with a composition containing a polyamic acid, a silicon-containing of polymer having a moiety of Structure (V), and gamma-butyrolactone to form a layer containing the polyamic acid having a thickness of at least about 0.5 μm;

(c) baking the layer of polyamic acid at a temperature or temperatures below 140° C.;

(d) in a second coating step, coating a layer of a photoresist over the layer of polyamic acid to form a bilayer coating;

(e) exposing the bilayer coating to actinic radiation;

(f) developing the bilayer coating with one or more aqueous developers;

(g) removing the remaining photoresist layer; and

(h) curing the polyamic acid layer at a temperature at least about 200° C. to produce a polyimide structure.

The present disclosure also features novel polymers of Structure (VI) or (VI*) described in the Summary section above.

The disclosure is illustrated by, but not limited to, the following examples in which the parts and percentages are by weight (wt %) unless otherwise specified.

### SYNTHESIS EXAMPLE 1

### Synthesis of a Polybenzoxazole Precursor Polymer of Structure (I)

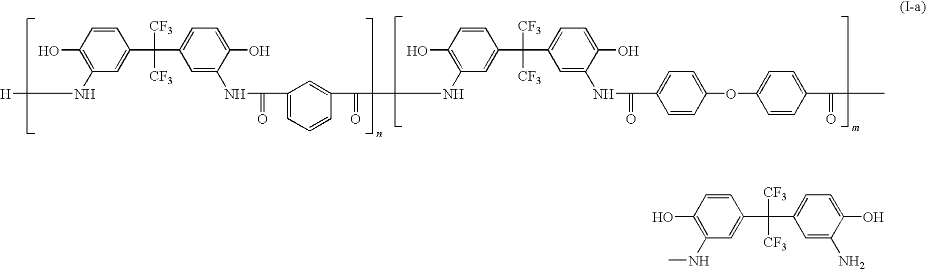

To a 2 liter, three-necked, round bottom flask equipped with a mechanical stirrer, nitrogen inlet and addition funnel, 155.9 g (426.0 mmol) of hexafluoro-2,2-bis(3-amino-4-hydroxyphenyl)propane, 64.3 g (794.9 mmol) of pyridine, and 637.5 g of N-methylpyrrolidone (NMP) were added. The solution was stirred at room temperature until all solids dissolved, then cooled in an ice water bath at 0-5° C. To this solution, 39.3 g (194 mmol) of isophthaloyl chloride, and 56.9 g (194 mmol) of 1,4-oxydibenzoyl chloride dissolved in 427.5 g of NMP, were added drop-wise. After the addition was completed, the resulting mixture was stirred at room temperature for 18 hours. The viscous solution was precipitated in 10 liters of vigorously stirred deionized water. The polymer was collected by filtration and washed with deionized water and a water/methanol (50/50) mixture. The polymer was dried under vacuum conditions at 105° C. for 24 hours.

The yield was almost quantitative and the inherent viscosity (iv) of the polymer was 0.20 dl/g measured in NMP at a concentration of 0.5 g/dl at 25° C.

### SYNTHESIS EXAMPLE 2

### Synthesis of a Polybenzoxazole Precursor Polymer of Structure (II)

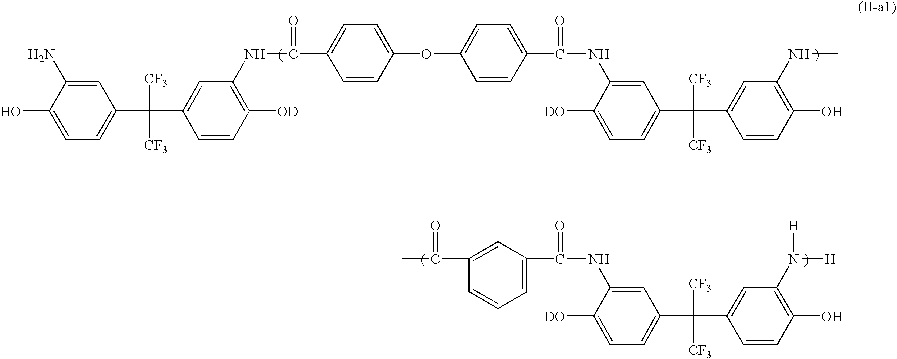

To a 1 liter three-necked round bottom flask equipped with a mechanical stirrer, 54.2 g (100 mmol) of the polymer obtained in Synthesis Example 1 and 500 ml of tetrahydrofuran (THF) were added. The mixture was stirred for ten minutes and the solid was fully dissolved. 0.81 g (3 mmole) of 5-naphthoquinone diazide sulfonyl chloride was then added and the mixture was stirred for another 10 minutes. Triethylamine, 0.3 g (3 mmol), was added gradually within 15 minutes and then the reaction mixture was stirred for 5 hours. The reaction mixture was then added gradually to 5000 ml of vigorously stirred deionized water. The precipitated product was separated by filtration and washed with 2 liters of deionized water. To the product was added another 6 liters deionized water and the mixture vigorously stirred for 30 minutes. After filtration the product was washed with 1 liter deionized water. The isolated product was dried at 40° C. overnight. The inherent viscosity of the polymer was 0.21 dl/g measured in NMP at the concentration of 0.5 g/dl at 25° C.

### SYNTHESIS EXAMPLE 3

### Synthesis of a Photoactive Compound (XIII p)

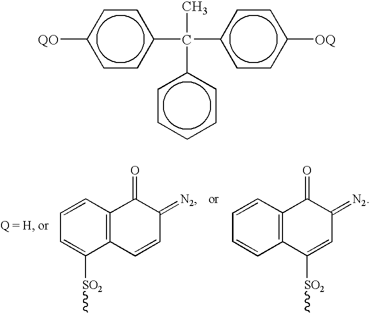

To a 500 ml, 3-neck flask equipped with mechanical stirrer, dropping funnel, pH probe, thermometer and nitrogen purge system were added 225 ml of THF and 30 g of (4,4′-(1-phenylethylidene)bisphenol) (Bisphenol AP). The mixture was stirred until Bisphenol AP was fully dissolved. To this was added 27.75 g of 4-naphthoquinone diazide sulfonyl chloride (S214-Cl) and 25 ml of THF. The reaction mixture was stirred until the solid was fully dissolved. 10.48 g of triethylamine dissolved in 50 ml THF was added to the reaction mixture gradually while the pH was kept below 8 during this process. The temperature during this exothermic reaction was kept below 30° C. Upon completion of addition, the reaction mixture was stirred for 48 hours. To this was added 27.75 g of 5-naphthoquinone diazide sulfonyl chloride (S215-Cl) and 25 ml of THF and the reaction mixture was stirred for 30 minutes. 10.48 g triethylamine dissolved in 50 ml THF was added to the reaction mixture gradually while the pH was kept below 8 during this process. Again, during this exothermic reaction, the temperature was kept below 30° C. Upon completion of the addition, the reaction mixture was stirred for 20 hours. The reaction mixture was then added gradually to a mixture of 6 liters of deionized water and 10 g of HCl. The product was filtered and washed with 2 liters of deionized water. The product was then reslurried by using 3 liters of deionized water, filtered and washed with 1 liter of deionized water. The product was then dried inside a vacuum oven at 40° C. until the amount of water dropped below 2%. HPLC analysis revealed that the product was a mixture of several esters as shown in Table 1.

TABLE 1

| | DNQ | Example |
|---|---|---|
| Structure | moiety | 3 |
| 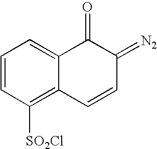 | S214 | 0.61% |
| 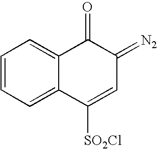 | S215 | 0.53% |
| 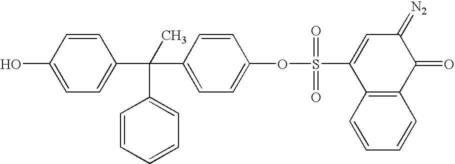 | S214mono-ester | 1.72% |
| 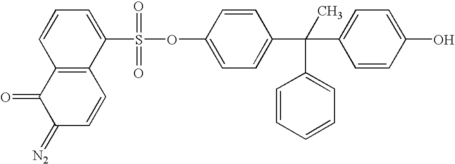 | S215mono-ester | 1.4% |
| 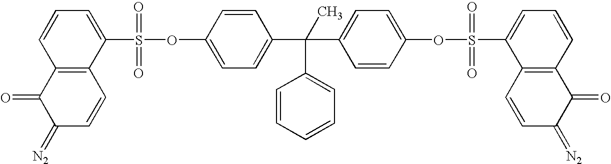 | S215diester | 18.9% |
| 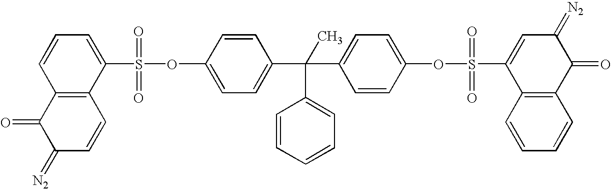 | MixedEsterPAC | 46.7% |
| 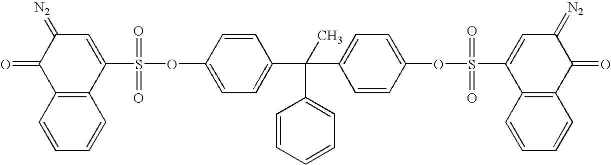 | S214diester | 29% |

### SYNTHESIS EXAMPLE 4

### Synthesis of a Polybenzoxazole Precursor Polymer of Structure (I)

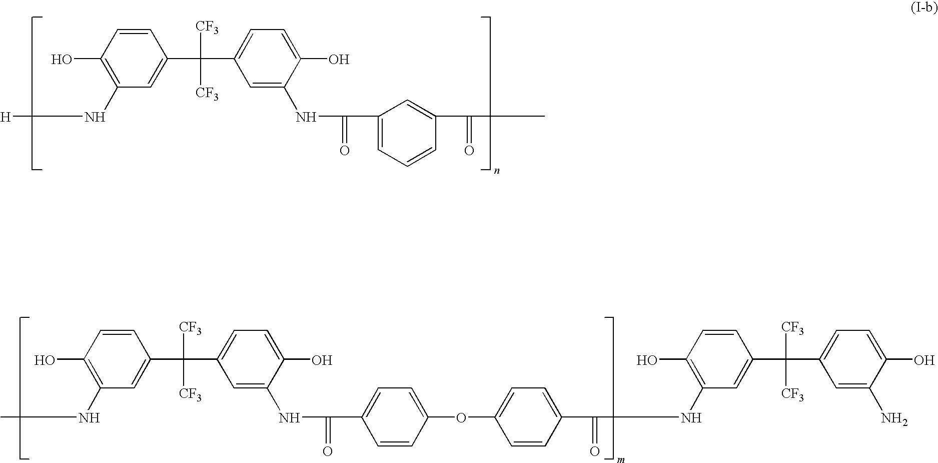

The synthesis of Polymer (1-b) was similar to Polymer (1-a) in Synthesis Example 1 except the ratio of 1,4-oxydibenzoyl chloride to isophthaloyl chloride was changed from 1/1 to 4/1.

### SYNTHESIS EXAMPLE 5

### Synthesis of a Polybenzoxazole Precursor Polymer of Structure (II)

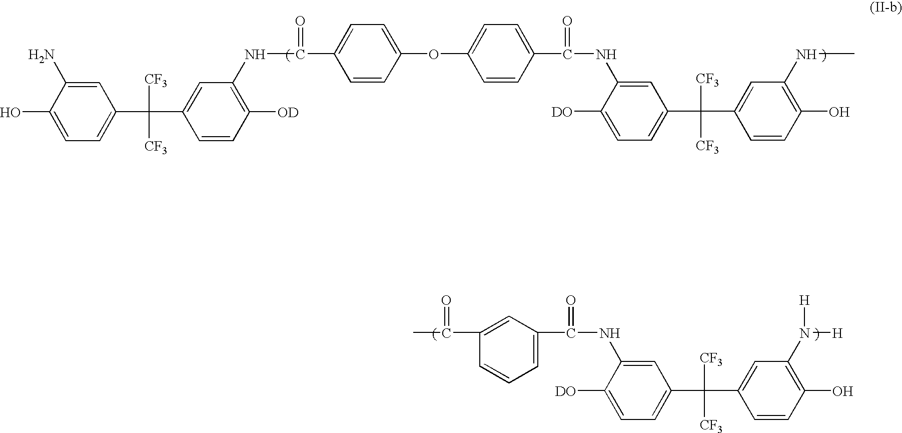

The synthesis of Polymer (II-b) was similar to Polymer (II-a) in Synthesis Example 2, except Polymer 1-b was used instead of Polymer (I-a) and the ratio of 5-naphthoquinone diazide sulfonyl chloride to OH groups was changed from 1.5% to 1%.

### SYNTHESIS EXAMPLE 6

### Synthesis of a Polybenzoxazole Precursor Polymer of Structure (IV*)

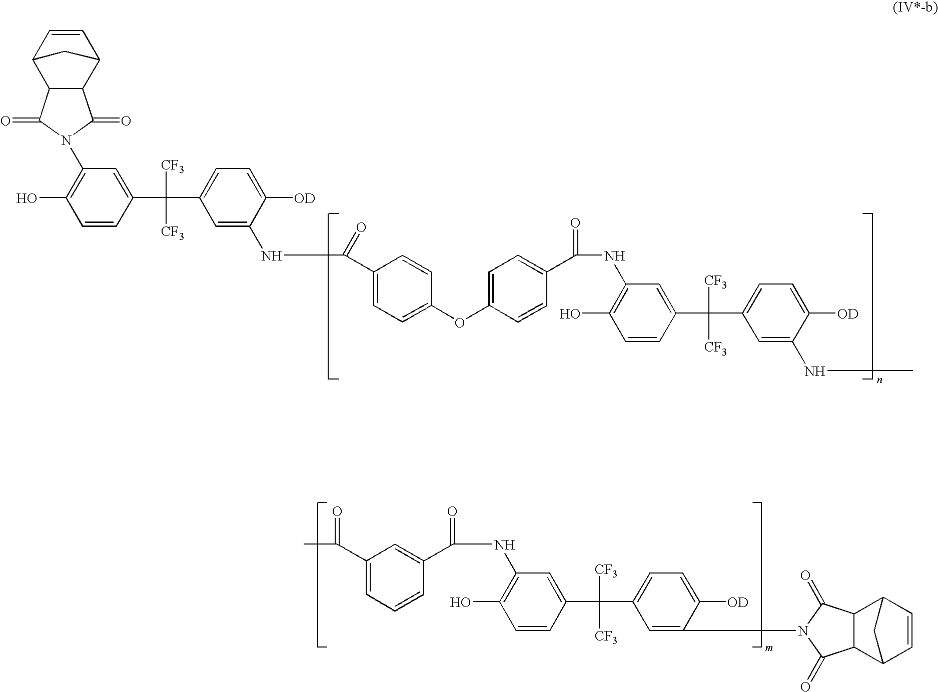

A PBO precursor polymer prepared in the same way as in Synthesis Example 5 (200 g) was dissolved in a mixture of 600 g of diglyme and 300 g of propylene glycol methyl ether acetate (PGMEA). Residual water was removed as an azeotrope with PGMEA and diglyme using a rotary evaporator at 65° C. (10-12 torr). About 550 g of solvents was removed during the azeotropic distillation. The reaction solution was placed under a N₂ blanket and equipped with a magnetic stirrer. Nadic anhydride (7 g) was added followed by 10 g of pyridine. The reaction was stirred overnight at 50° C. Then the reaction mixture was diluted with 500 g of tetrahydrofuran (THF) and precipitated into 8 liters of a 50:50 methanol:water mixture. The polymer was collected by filtration and vacuum dried at 40° C. The yield was almost quantitative.

### SYNTHESIS EXAMPLE 7

### Synthesis of a Polybenzoxazole Precursor Polymer of Structure (II)

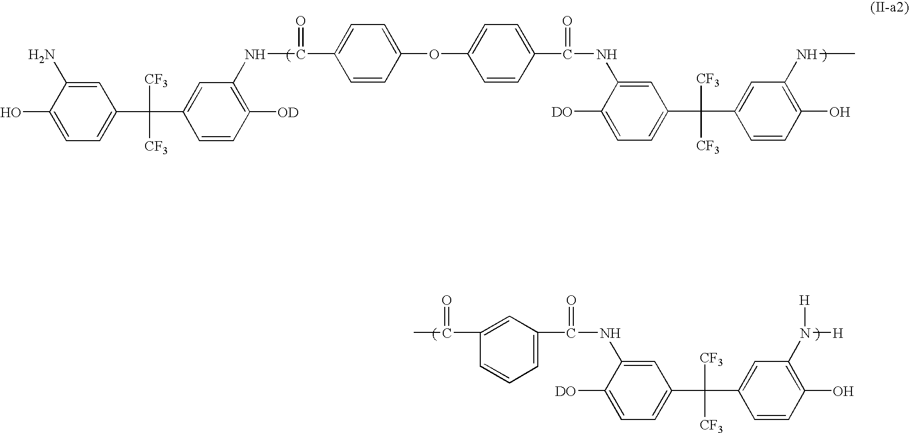

Synthesis Example 2 was repeated except 2.7 g (10 mmole) of 5-naphthoquinone diazide sulfonyl chloride was used. The yield was quantitative and the inherent viscosity of the polymer was 0.21 dl/g measured in NMP at the concentration of 0.5 g/dl at 25° C.

### SYNTHESIS EXAMPLE 8

### Preparation of a Polybenzoxazole Precursor Polymer of Structure (III-a)

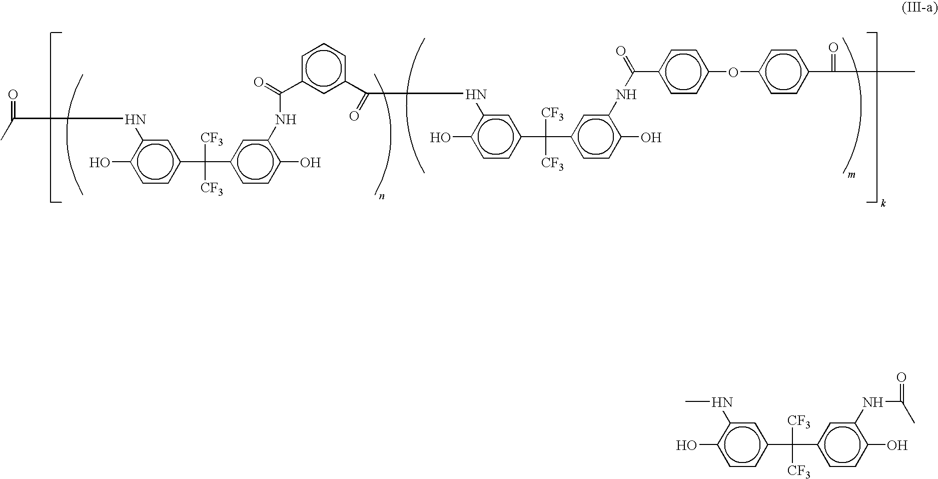

100 g of the PBO precursor polymer obtained following the procedure from Synthesis Example 1 was dissolved in 1000 g of diglyme. Residual water was removed as an azeotrope with diglyme using a rotary evaporator at 65° C. (10-12 torr). About 500 g of solvents were removed during the azeotropic distillation. The reaction solution was placed under a N₂ blanket, equipped with a magnetic stirrer and cooled using an ice bath down to ˜5° C. 3.6 g acetyl chloride was added via syringe. The reaction was held on the ice bath for about 10 minutes. Then the ice bath was removed and the reaction was allowed to warm up over the period of 1 hour. Then, the mixture was again cooled to 5° C. on the ice bath. 3.6 g pyridine was added via syringe over the period of 1 hour. The reaction was kept on the ice bath for ˜10 minutes following the pyridine addition, and then was allowed to warm up over the period of 1 hour.

The reaction mixture was precipitated into 6 liters of water with stirring. The precipitated polymer was collected by filtration and air dried overnight. Then, the polymer was dissolved in 500-600 g of acetone and precipitated into 6 liters of water/methanol (70/30). The polymer was again collected by filtration and air-dried for several hours. The still damp polymer cake was dissolved in a mixture of 700 g of THF and 70 ml of water. An ion exchange resin UP604 (40 g), available from Rohm and Haas, was added and the solution was rolled for 1 hour. The final product was precipitated in 7 liters of water, filtered, air-dried overnight followed by 24 hours drying in a vacuum oven at 90° C.

The yield was 100% and the inherent viscosity (iv) of the polymer was 0.205 dl/g measured in NMP at a concentration of 0.5 g/dl at 25° C.

### SYNTHESIS EXAMPLE 9

### Synthesis of a Polyamide Polymer of Structure (V)

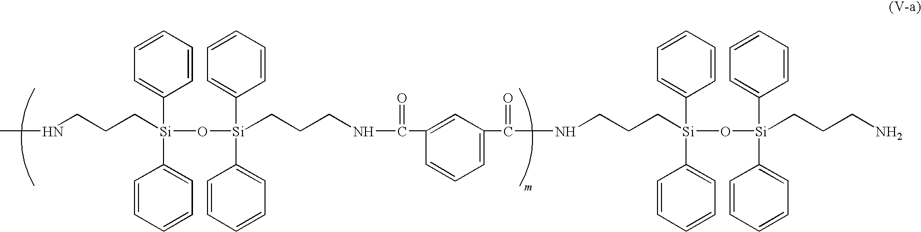

To a 1 liter, three-necked, round bottom flask equipped with a mechanical stirrer, nitrogen inlet and addition funnel, 79.6 g (160.0 mmol) of 1,3-bis(3-aminopropyl)tetraphenyldisiloxane, 64.7 g (639 mmol) of triethylamine, and 480 g of N-methylpyrrolidone (NMP) are added. The solution is stirred at room temperature until all solids dissolves, then cools in an ice water bath at 0-5° C. To this solution 29.44 g (145 mmol) of isophthaloyl chloride dissolved in 180 g of NMP, are added drop-wise. After the addition is completed, the resulting mixture is stirred at room temperature for 18 hours. The viscous solution is precipitated in 5 liters of vigorously stirred deionized water containing 0.2% acetic acid. The polymer is collected by filtration and washed with deionized water. The polymer is dried under vacuum conditions at 45° C. for 24 hours.

### SYNTHESIS EXAMPLE 10

### Synthesis of a Polyamide Polymer of Structure (VI)

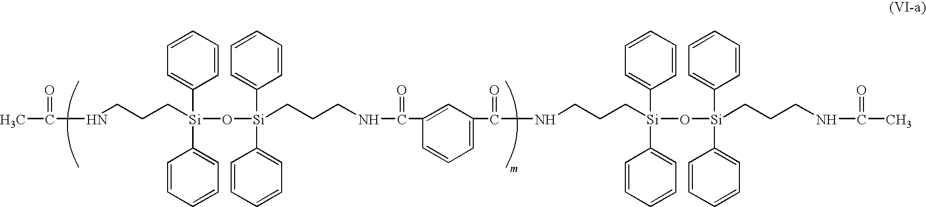

50 g of the polyamide polymer obtained following the procedure from Synthesis Example 9 is dissolved in 500 g of diglyme. Residual water is removed as an azeotrope with diglyme using a rotary evaporator at 65° C. (10-12 torr). About 250 g of solvents are removed during the azeotropic distillation. The reaction solution is placed under a N₂ blanket, equipped with a magnetic stirrer and cooled using an ice bath down to ˜5° C. 1.8 g acetyl chloride is added via syringe. The reaction is held on the ice bath for about 10 minutes. Then the ice bath was removed and the reaction is allowed to warm up over the period of 1 hour. Then, the mixture is again cooled to 5° C. on the ice bath. 1.8 g pyridine is added via syringe over the period of 1 hour. The reaction is kept on the ice bath for ˜10 minutes following the pyridine addition, and then is allowed to warm up over the period of 1 hour.

The reaction mixture is precipitated into 3 liters of water with stirring. The precipitated polymer is collected by filtration and air dried overnight. Then, the polymer is dissolved in 250-300 g of acetone and precipitated into 6 liters of water/methanol (70/30). The polymer is again collected by filtration and air-dried for several hours. The still damp polymer cake is dissolved in a mixture of 350 g of THF and 35 g of deionized water. An ion exchange resin UP604 (20 g), available from Rohm and Haas, is added and the solution was rolled for 1 hour. The final product is precipitated in 3.5 liters of water, filtered, air-dried overnight followed by 24 hours drying in a vacuum oven at 90° C.

### SYNTHESIS EXAMPLE 11

### Synthesis of a Polyamide Polymer of Structure (V)

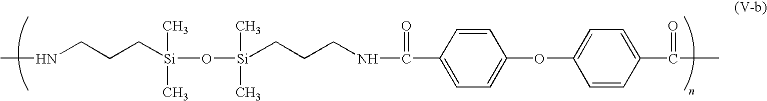

To a 1 liter, three-necked, round bottom flask equipped with a mechanical stirrer, nitrogen inlet and addition funnel, 39.7 g (160.0 mmol) of 1,3-bis(3-aminopropyl)tetramethyldisiloxane, 64.7 g (639 mmol) of triethylamine, and 240 g of N-methylpyrrolidone (NMP) were added. The solution was stirred at room temperature until all solids dissolved. The solution was then cooled in an ice water bath at 0-5° C. To this solution 42.56 g (145 mmol) of 1,4-oxydibenzoyl chloride dissolved in 288 g of NMP, were added drop-wise. After the addition was completed, the resulting mixture was stirred at room temperature for 18 hours. The viscous solution was precipitated in 5 liters of vigorously stirred deionized water containing 0.2% acetic acid. The polymer was collected by filtration and washed with deionized water. The polymer was dried under vacuum conditions at 45° C. for 24 hours.

The yield was 64 g and the inherent viscosity (iv) of the polymer was 0.176 dl/g measured in NMP at a concentration of 0.5 g/dl at 25° C.

### SYNTHESIS EXAMPLE 12

### Synthesis of a Polyamide Polymer of Structure (V)

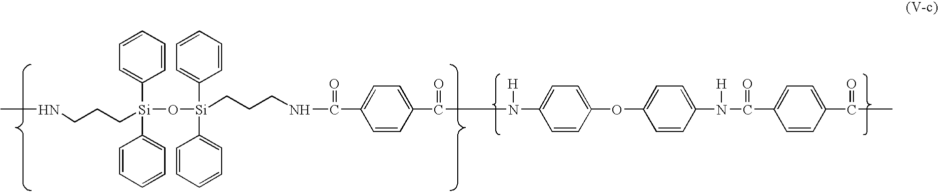

To a 1 liter, three-necked, round bottom flask equipped with a mechanical stirrer, nitrogen inlet and addition funnel, 59.7 g (120.0 mmol) of 1,3-bis(3-aminopropyl)tetraphenyldisiloxane, 8.0 (40 mmol) of 4,4-oxydianiline, 64.7 g (639 mmol) of triethylamine, and 480 g of N-methylpyrrolidone (NMP) are added. The solution is stirred at room temperature until all solids dissolves, then cools in an ice water bath at 0-5° C. To this solution 29.44 g (145 mmol) of terephthaloyl chloride dissolved in 180 g of NMP, are added drop-wise. After the addition is completed, the resulting mixture is stirred at room temperature for 18 hours. The viscous solution is precipitated in 5 liters of vigorously stirred deionized water containing 0.2% acetic acid. The polymer is collected by filtration and washed with deionized water. The polymer is dried under vacuum conditions at 45° C. for 24 hours.

hexafluoro-2,2-bis(3-amino-4-hydroxyphenyl)propane, 64.3 g (794.9 mmol) of pyridine, and 637.5 g of N-methylpyrrolidone (NMP) were added. The solution was stirred at room temperature until all solids dissolved, and then cooled in an ice water bath at 0-5° C. To this solution, 38.7.3 g (191 mmol) of isophthaloyl chloride, and 56.0 g (191 mmol) of 1,4-oxydibenzoyl chloride dissolved in 427.5 g of NMP, were added drop-wise. After the addition was completed, the resulting mixture was stirred at room temperature for 18 hours. Nadic anhydride (37 g) was added to the solution and followed by the addition of 52.8 g of pyridine. The reaction was stirred overnight at 50° C. The viscous solution was precipitated in 10 liters of vigorously stirred deionized water. The polymer was collected by filtration and washed with deionized water and a water/methanol (50/50) mixture. The polymer was dried under vacuum conditions at 40° C. for 24 hours.

The yield was almost quantitative and the inherent viscosity (iv) of the polymer was 0.20 dl/g measured in NMP at a concentration of 0.5 g/dl at 25° C.

### SYNTHESIS EXAMPLE 16

### Preparation of a PBO Precursor Blocked with Ethyl Vinyl Ether

### An Example of (XV1*-a)

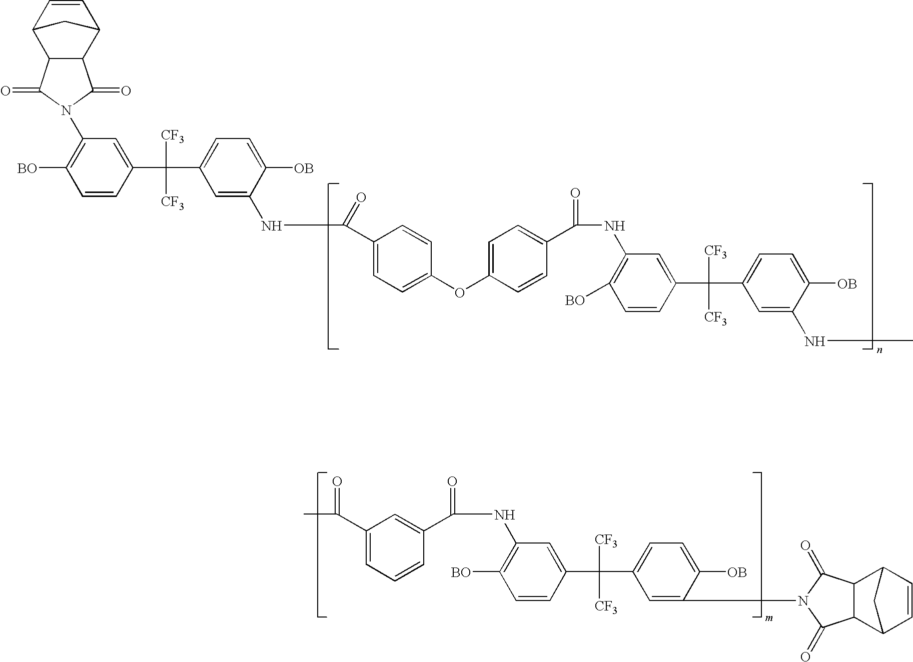

### SYNTHESIS EXAMPLE 13

### Synthesis of a Polybenzoxazole Precursor Polymer of Structure (I)

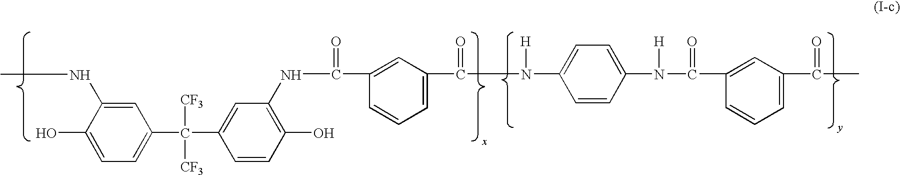

To a 2 liter, three-necked, round bottom flask equipped with a mechanical stirrer, nitrogen inlet and addition funnel, 140.3 g (383.4 mmol) of hexafluoro-2,2-bis(3-amino-4-hydroxyphenyl)propane, 4.61 g (42.6 mmol) of 1,4-diaminophenyl, 64.3 g (794.9 mmol) of pyridine, and 637.5 g of N-methylpyrrolidone (NMP) are added. The solution is stirred at room temperature until all solids dissolved. The solution is then cooled in an ice water bath at 0-5° C. To this solution, 78.6 g (388 mmol) of isophthaloyl chloride dissolved in 427.5 g of NMP, are added drop-wise. After the addition is completed, the resulting mixture is stirred at room temperature for 18 hours. The viscous solution is precipitated in 10 liters of vigorously stirred deionized water. The polymer is collected by filtration and washed with deionized water and a water/methanol (50/50) mixture. The polymer is dried under vacuum conditions at 105° C. for 24 hours. The yield is almost quantitative.

### SYNTHESIS EXAMPLE 14

### Synthesis of a Polyamide Polymer of Structure (V-d)

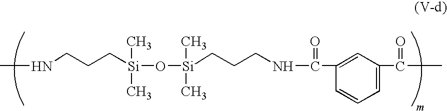

To a 1 liter, three-necked, round bottom flask equipped with a mechanical stirrer, nitrogen inlet and addition funnel, 39.7 g (160.0 mmol) of 1,3-bis(3-aminopropyl)tetramethyldisiloxane, 64.7 g (639 mmol) of triethylamine, and 240 g of N-methylpyrrolidone (NMP) were added. The solution was stirred at room temperature until all solids dissolved. The solution was then cooled in an ice water bath at 0-5° C. To this solution 29.28 g (145 mmol) of isophthaloyl chloride dissolved in 288 g of NMP, were added drop-wise. After the addition was completed, the resulting mixture was stirred at room temperature for 18 hours. The viscous solution was precipitated in 5 liters of vigorously stirred deionized water containing 0.4% acetic acid. The polymer was collected by filtration and washed with deionized water. The polymer was dried under vacuum conditions at 45° C. for 24 hours.

The yield was 48.5 g and the inherent viscosity (iv) of the polymer was 0.099 dl/g measured in NMP at a concentration of 0.5 g/dL at 25° C.

### SYNTHESIS EXAMPLE 15

### An Example of Structure (III*))(III*-a1)

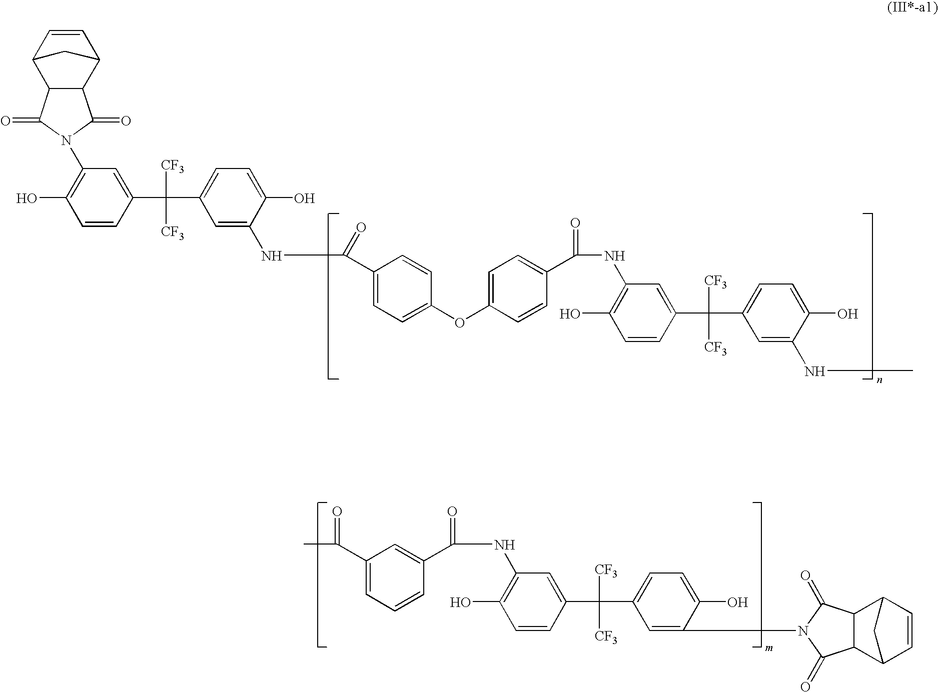

To a 2 liter, three-necked, round bottom flask equipped with a mechanical stirrer, nitrogen inlet and addition funnel, 155.9 g (426.0 mmol) of

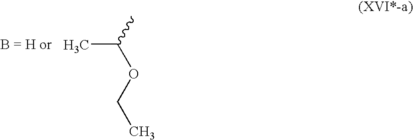

A polymer prepared in the same way as in Synthesis Example 2 (or alternatively Synthesis Example 3) (95.76 g) was dissolved in 543 g of propylene glycol methyl ether acetate (PGMEA). Residual water was removed as an azeotrope with propylene glycol methyl ether acetate (PGMEA) using a rotary evaporator at 65° C. (10-12 torr). About 262.5 g of solvent was removed during the azeotropic distillation. The reaction solution was placed under a N₂ blanket and equipped with a magnetic stirrer. Ethyl vinyl ether (7.46 g) was added via syringe. 5.41 g of 2 wt % solution of p-toluene sulfonic acid in PGMEA was then added. The reaction mixture was stirred for 2 hrs at 25° C. NMR analysis indicated that 16% of the OH groups were blocked. Additional ethyl vinyl ether (2.98 g) was added. The reaction mixture was stirred for another two hours and NMR analysis showed that 28.3% of OH groups were blocked. Triethylamine (8.64 g of 2% solution in PGMEA) was added. 146.8 g acetone, 78.5 g hexane and 116.9 g deionized water were then added consecutively. The solution was stirred for a few minutes. Then, by using a separatory funnel, the organic phase was separated from the aqueous phase. To the organic phase was added 78.6 g of acetone and 63.0 g of deionized water and the mixture was shaken for a few minutes. The organic phase was again separated from the aqueous phase. This process was repeated two more times each with 78.6 g of acetone and 63.0 g of deionized water. The resulting solution was then concentrated to 50% solids by using a rotary evaporator at 65° C. (10-12 torr).

### SYNTHETIC EXAMPLE 17

### Preparation of 4,4′-oxydiphthalic Anhydride (ODPA)/Oxydianiline (ODA) Polyamic Acid

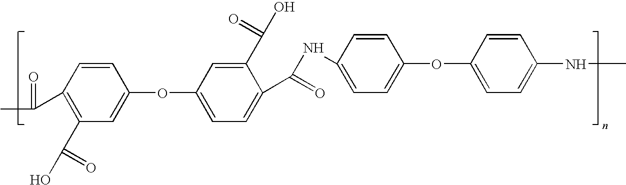

A 500 mL, three neck, round bottom flask was equipped with a mechanical stirrer, temperature controller and nitrogen inlet. 270 g of gamma-butyrolactone was added to this reaction flask followed by addition of 38.48 g (124.05 mmole) of 4,4′-oxydiphthalic anhydride (ODPA). The ODPA charging funnel was rinsed with 15 g of gamma-butyrolactone. The reaction mixture was stirred at room temperature for 15 minutes and then at 73-75° C. until 4,4′-oxydiphthalic anhydride was fully dissolved. The clear, pale yellow reaction solution was cooled to 15° C. The 4,4′-oxydiphthalic anhydride was partially precipitated. 24.34 g (121.57 mmol) of oxydianiline was added portion wise within an hour. 13.3 g gamma-butyrolactone was added to rinse the oxydianiline container. The reaction temperature was kept at 15° C. for another 15 minutes and then slowly increased to 40° C. The reaction mixture was allowed to stir at this temperature for 24 hours. The reaction was complete as evidenced by the absence of anhydride peak (1800 cm⁻¹) from IR spectrum of the solution. The kinematic viscosity of the final product was 3451 cSt.

### SYNTHETIC EXAMPLE 18

### Preparation of Pyromellitic Dianhydride (PMDA)/Oxydianiline (ODA) Polyamic Acid

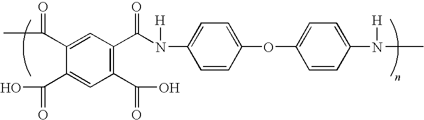

A 500 mL, three neck, round bottom flask was equipped with a mechanical stirrer, temperature controller and nitrogen inlet. 300 g of N-methyl pyrollidone (NMP) was added to this reaction flask followed by addition of 39.2 g (179.72 mmol) of pyromellitic dianhydride (PMDA). The PMDA charging funnel was rinsed with 34 g of N-methyl pyrollidone. The reaction mixture was stirred at room temperature until pyromellitic dianhydride was fully dissolved. The reaction solution was cooled to 15° C. 36.03 g (179.96 mmol) of oxydianiline was added portion wise within an hour. 34 g methylpyrrolidone was added to rinse the oxydianiline container. The reaction temperature was kept at 15° C. for another 15 minutes and then slowly increased to 40° C. The reaction mixture was allowed to stir at this temperature for 24 hours. The reaction was complete as evidenced by the absence of anhydride peak (1800 cm⁻¹) from IR spectrum of the solution. The kinematic viscosity of the final product was 16,973 cSt.

### SYNTHESIS EXAMPLE 19

### Synthesis of a Polyamide Polymer of Structure (VI*)

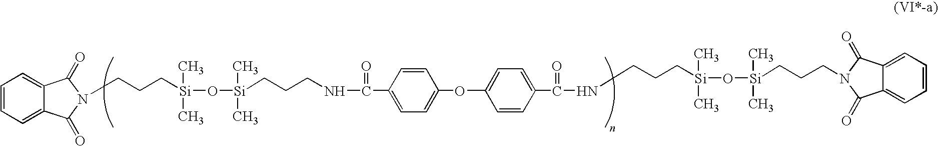

A polyamide polymer prepared in the same way as in Synthesis Example 11 (100 g) is dissolved in a mixture of 300 g of diglyme and 150 g of propylene glycol methyl ether acetate (PGMEA). Residual water is removed as an azeotrope with PGMEA and diglyme using a rotary evaporator at 55° C. (8-10 torr). About 3,280 g of solvents are removed during the azeotropic distillation. The reaction solution is placed under a N₂ blanket and equipped with a magnetic stirrer. Nadic anhydride (4 g) is added followed by 6 g of pyridine. The reaction is stirred overnight at 55° C. Then the reaction mixture is diluted with 250 g of tetrahydrofuran (THF) and precipitated into 4 liters of a 50:50 methanol:water mixture. The polymer is collected by filtration and vacuum dried at 40° C. The yield is almost quantitative.

### SYNTHESIS EXAMPLE 20

### Preparation of a PBO Precursor Polymer of Structure Type III with a p-Toluene Sulfonic Endcap (III)

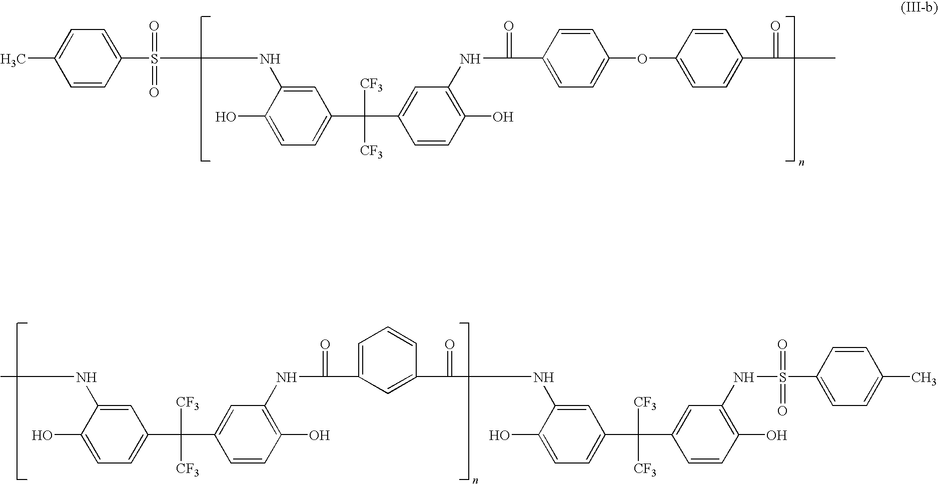

The PBO precursor polymer obtained in Synthesis Example 1 (100 g) was dissolved in a mixture of 500 g of diglyme and 300 g of propylene glycol methyl ether acetate (PGMEA). Residual water was removed as an azeotrope with PGMEA and diglyme using vacuum distillation at 65° C. (10-12 torr). About 400 g of solvents was removed during the azeotropic distillation. The reaction solution was placed under a N₂ blanket. The reaction mixture was cooled on an ice bath down to 5° C. and 3.2 g of pyridine was added at once followed by 8.5 g of p-toluene sulfonic acid chloride. The reaction mixture was allowed to warmed up to room temperature and stirred overnight.

The reaction mixture was precipitated into 6 liters of water while stirring. The precipitated polymer was collected by filtration and air dried overnight. Then the polymer was dissolved in 500-600 g of acetone and precipitated into 6 liters of a water/methanol (70/30) mixture. The polymer was again collected by filtration and air-dried for several hours. The still damp polymer cake was dissolved in a mixture of 700 g of THF and 70 ml of water. An ion exchange resin UP604 (40 g), available from Rohm and Haas, was added and the solution was rolled for 1 hour. The final product was precipitated in 7 liters of water, filtered, air-dried overnight followed by 24 hour drying in vacuum oven at 90° C.

¹H NMR analysis showed the absence of any amine peaks at ˜4.5 ppm as well as the absence of aromatic peaks due to the uncapped BisAPAF unit at 6.4-6.7 ppm. This indicates that end capping was complete. The yield was 77 g.

### SYNTHESIS EXAMPLE 21

### Preparation of PBO Precursor Polymer of Structure Type III Endcapped with p-Toluene Sulfonyl and Blocked with Ethyl Vinyl Ether (XVI-a)

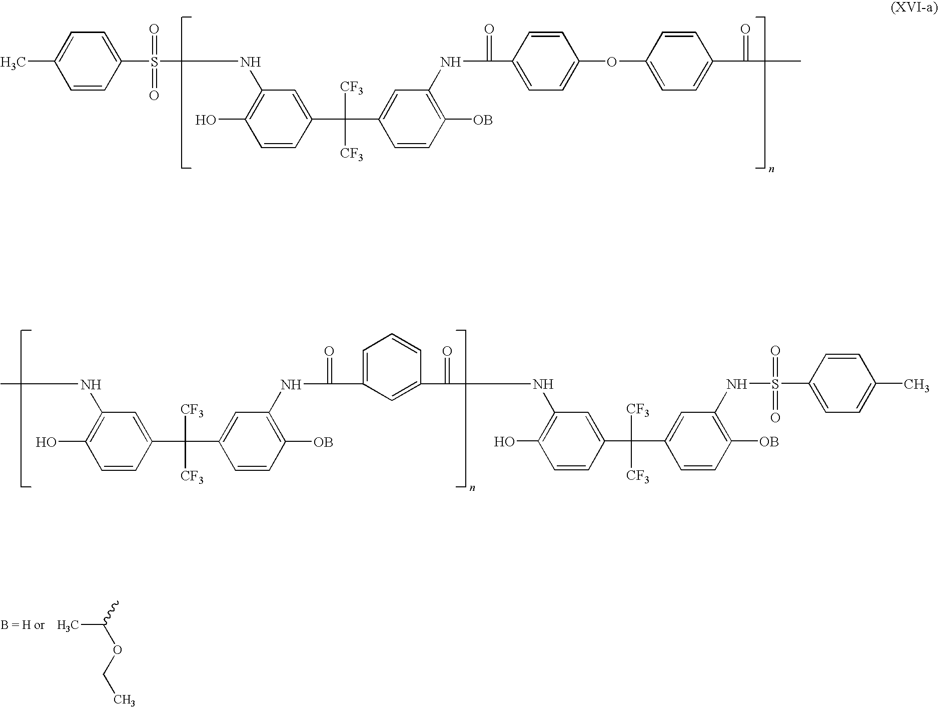

A polymer prepared with the procedure from Synthesis Example 20 (30 g) was dissolved in 150 g of diglyme. Residual water was removed as an azeotrope with diglyme using vacuum distillation at 65° C. (10-12 torr). About 50 g of solvents was removed during the azeotrope distillation. Water content in reaction mixture ranged from 60-150 ppm. The reaction solution was placed under a N₂ blanket and equipped with a magnetic stirrer and cooled down to 25° C. Ethyl vinyl ether (15 ml) was added via syringe, followed by 1 ml of a 4 wt % solution of p-toluene sulfonic acid in PGMEA. The reaction mixture was stirred for 2 hours at 25° C. and triethyl amine (1 ml) was added.

The reaction mixture was precipitated into 2 liters of a water/methanol mixture (50/50) mixture. The polymer was separated by filtration, air dried for 2 hours and dissolved in 200 ml of THF. The polymer was precipitated two more times into 2 liters of a water/methanol mixture (50/50), filtered and air-dried. Then the polymer was vacuum-dried at 45° C. overnight.

¹H NMR showed that about 93-97 mol % of OH groups in the PBO precursor polymer was blocked with ethyl vinyl ether. This was concluded based on the integration of the acetal peak at 5.6 ppm and the phenol peak at 10.4 ppm.

### SYNTHESIS EXAMPLE 22

### Preparation of PBO Precursor of Structure Type XVI with Acetyl Endcap, Blocked with Ethyl Vinyl Ether (XVI-b)

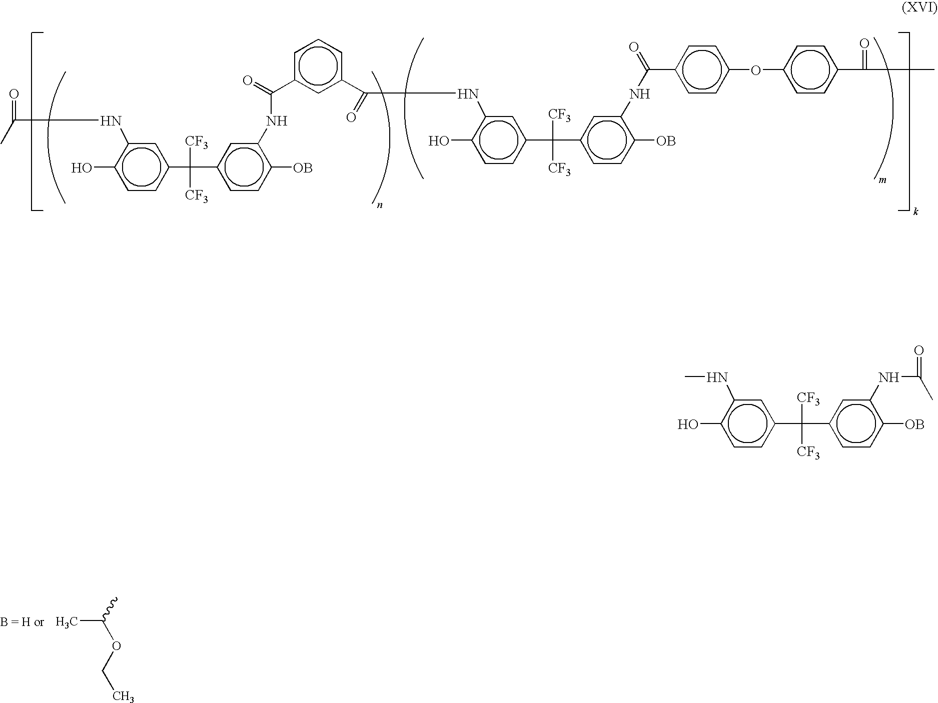

Synthesis of this polymer is similar to polymer in Synthesis Example 16, except a polymer prepared by the method of Synthesis Example 8 is used as starting material.

### SYNTHESIS EXAMPLE 23

### Preparation of PBO Precursor of Structure Type XVI* Blocked with t-Butoxy Carbonyl Methyl (XVI*a BCM)

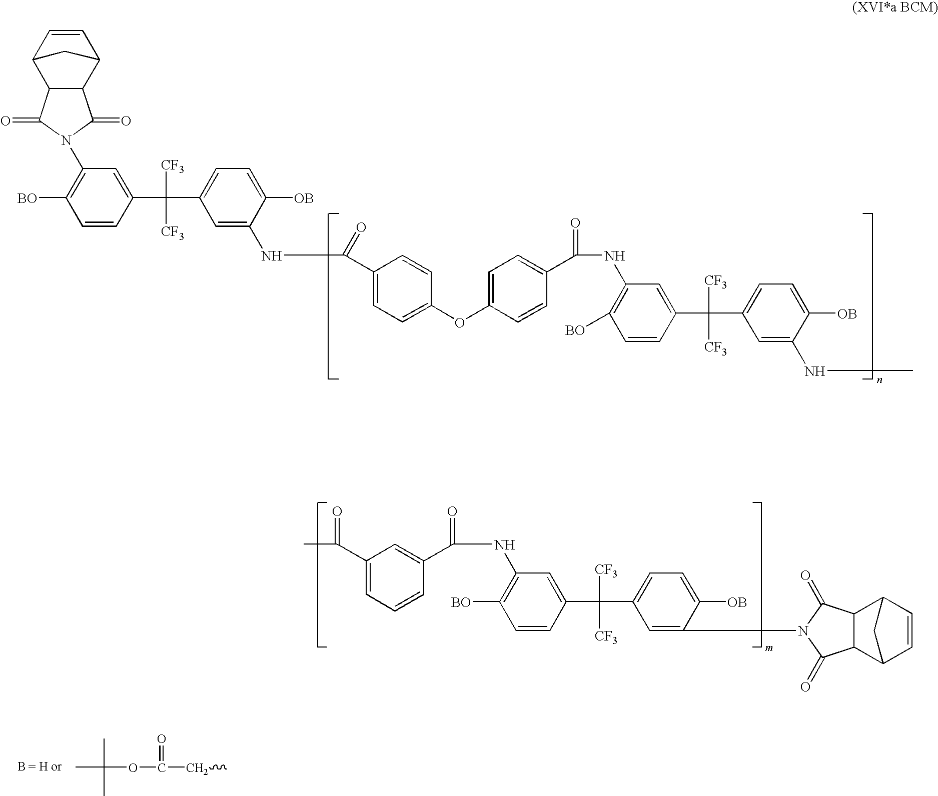

A polymer prepared in the same way as in Synthesis Example 6 (100 g) is dissolved in 1,000 g of diglyme. Residual water is removed as an azeotrope with diglyme using a rotary evaporator at 65° C. (10-12 torr). About 500 g of solvent is removed during the azeotrope distillation. The reaction solution is placed under a N₂ blanket and equipped with a magnetic stirrer. t-butyl bromoacetate, (21.2 g, 107 mmol) is added, followed by 9.3 g, 117.6 mmol of pyridine. The reaction mixture is stirred for 5 hours at 40° C. The resulting mixture is added dropwise to 10 liters of water, yielding a white precipitate. The precipitate is washed 5 times with water, filtered, and dried in vacuum below 40° C. to give 101 g of t-butoxycarbonylmethyloxy-bearing polymer. The product is analyzed by proton-NMR. From a peak of phenyl at 6 to 7 ppm and peaks of t-butyl and methylene at 1 to 2 ppm, the t-butoxycarbonylmethyloxy introduction rate is calculated to be 30 mole % of available OH groups.

### SYNTHESIS EXAMPLE 24

### Preparation of PBO Precursor of Structure Type XV Blocked with t-Butoxy Carbonyl Methyl (XVa BCM)

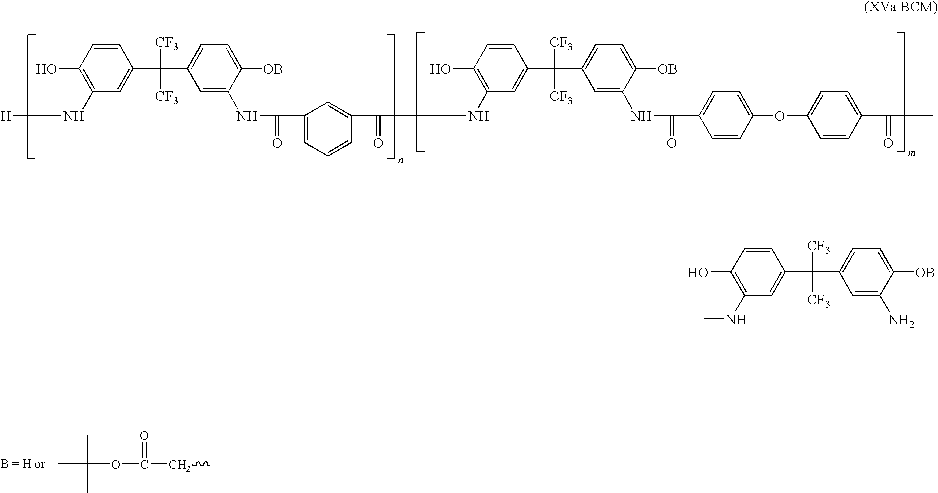

This polymer is prepared according to the procedure described in Synthesis Example 23 except 100 g of polymer described in Synthesis Example 1 is used.

### EXAMPLE 1

100 parts of the polymer obtained in Synthesis Example 2, 8 part of polymer obtained in Synthetic Example 11, 5 parts of gamma-ureidopropyltrimethoxysilane, 6.25 parts of diphenylsilanediol, 13.5 parts of PAC synthesized in Synthesis Example 3 were dissolved in 131 parts GBL and 44 parts N-methylpyrrolidone (NMP) and filtered to provide a photosensitive polybenzoxazole precursor composition.

A silicon nitride-coated wafer was coated with the photosensitive polybenzoxazole precursor composition above at a spin speed of 3,000 rpm for 55 seconds. The film was then softbaked twice on a hotplate at 135° C. for 45 seconds for each bake, resulting in a film thickness of 7.34 μm. The film was then exposed using a contact print broadband exposure with a patterned exposure gradient, including 30, 35, 40, 45, 50, 55, 60, 65, 80 & 100% transmittance. 100% transmittance exposure was equivalent to 400 mJ/cm². The film was then developed by immersion for 50 seconds in a 2.38% aqueous TMAH solution, rinsed three times with deionized water by immersion dip and dried by using nitrogen to provide a relief pattern. The exposure energy required to clear all the material from an exposed area (E₀) was 373 mJ/cm². The unexposed film thickness after development was 5.95 μm. The film was then cured for one hour at 350° C. in a vacuum oven with nitrogen purge, resulting in a film thickness of the unexposed area of 4.72 μm. The film was then exposed to a 50:1 HF solution for 10 seconds, inspected via optical microscope for any adhesion failure defects, and no failure was observed. The film was exposed again to the HF solution mentioned for one minute, re-inspected for adhesion failure defects and no failure was observed. Finally, a tape pull test using 3M-898 tape was conducted as described in ASTM-3359 and then the wafer was re-inspected for adhesion failure defects. No adhesion failure (i.e., less than about 0.1% of adhesion loss) was observed.

### COMPARATIVE EXAMPLE 1

100 parts of the polymer obtained in Synthesis Example 2, 5 parts of gamma-ureidopropyltrimethoxysilane, 6.25 parts of diphenylsilanediol, 13.5 parts of PAC synthesized in Synthesis Example 3 were dissolved in 175 parts GBL and filtered to provide a photosensitive polybenzoxazole precursor composition.

A silicon nitride-coated wafer was coated with the photosensitive polybenzoxazole precursor composition at a spin speed of 3,000 rpm for 55 seconds. The film was then softbaked twice on a hotplate at 135° C. for 45 seconds for each bake, resulting in a film thickness of 7.91 μm. The film was then exposed using a contact print broadband exposure with a patterned exposure gradient, including 30, 35, 40, 45, 50, 55, 60, 65, 80 & 100% transmittance. 100% transmittance exposure was equivalent to 400 mJ/cm². The film was then developed by immersion for 50 seconds in a 2.38% aqueous TMAH solution, rinsed three times with deionized water by immersion dip and dried by using nitrogen to provide a relief pattern. The exposure energy required to clear all the material from an exposed area (E₀) was 160 mJ/cm². The unexposed film thickness after development was 4.41 μm. The film was then cured for one hour at 350° C. in a vacuum oven with nitrogen purge, resulting in a film thickness of the unexposed area of 3.57 μm. The film was then exposed to a 50:1 HF solution for 10 seconds, inspected via optical microscope and adhesion failure was observed.

Comparison of Example 1 and Comparative Example 1 proved that presence of 8 parts of polymer (Va) in the photosensitive polybenzoxazole precursor composition greatly improved the HF resistance of the cured film. It also improved the film thickness retention after development.

### EXAMPLE 2

100 parts of the polymer obtained in Synthesis Example 6, 5 parts of the polymer obtained in Synthesis Example 9 and 12 parts of PAC shown in structure XIII O (see below) are dissolved in 175 parts GBL and filtered to provide a photosensitive polybenzoxazole precursor composition.

A silicon wafer is then coated with the photosensitive polybenzoxazole precursor composition and hotplate baked for 4 minutes at 120° C., resulting in a film thickness of 10.0 μm. The film is then exposed at 500 mJ/cm2 utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. No adhesion loss is observed.

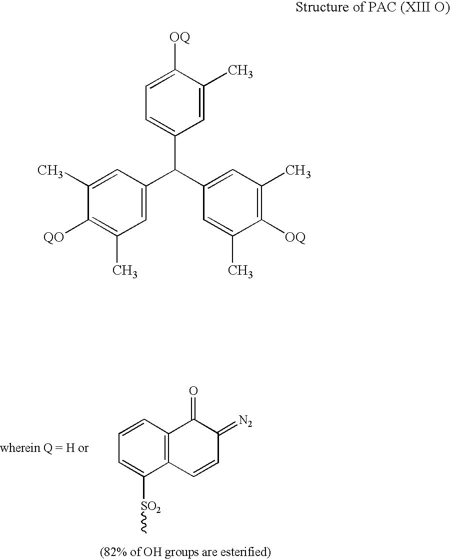

### COMPARATIVE EXAMPLE 2

100 parts of the polymer obtained in Synthesis Example 6 and 12 parts of PAC shown in structure (XIII O) are dissolved in 175 parts GBL and filtered to provide a photosensitive polybenzoxazole precursor composition.

A silicon wafer is then coated with the photosensitive polybenzoxazole precursor composition and hotplate baked for 4 minutes at 120° C., resulting in a film thickness of 10.0 μm. The film is then exposed at 500 mJ/cm² utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. Complete adhesion loss is observed.

Comparison of Example 2 and Comparative Example 2 shows that the polymer obtained from Synthesis Example 9 is surprisingly an effective adhesion promoter.

### EXAMPLE 3

100 parts of the polymer obtained in Synthesis Example 1, 10 parts of the polymer obtained in Synthesis Example 10, and 12 parts of PAC (XIII r) (see below) are dissolved in 175 parts GBL and filtered to provide a photosensitive polybenzoxazole precursor composition.

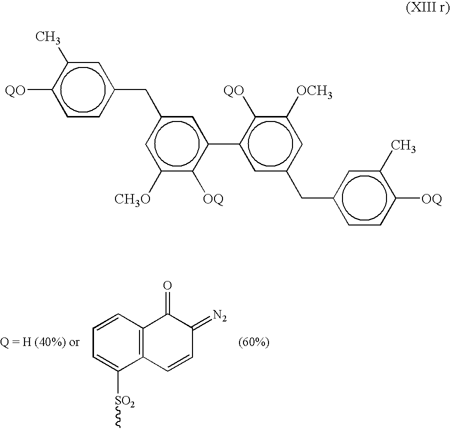

A silicon wafer is then coated with the photosensitive polybenzoxazole precursor composition and hotplate baked for 4 minutes at 120° C., resulting in a film thickness of 10.0 μm. The film is then exposed at 500 mJ/cm² utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. No adhesion loss is observed.

### COMPARATIVE EXAMPLE 3

100 parts of the polymer obtained in Synthesis Example 1 and 12 parts of PAC (XIII q) are dissolved in 175 parts GBL and filtered to provide a photosensitive polybenzoxazole precursor composition.

A silicon wafer is then coated with the photosensitive polybenzoxazole precursor and hotplate baked for 4 minutes at 120° C., resulting in a film thickness of 10.0 μm. The film is then exposed at 500 mJ/cm² utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. Complete adhesion loss is observed.

Comparison of Example 3 and Comparative Example 3 shows that the polymer obtained from Synthesis Example 9 is surprisingly an effective adhesion promoter.

### EXAMPLE 4

A positive acting photosensitive composition is prepared from 100 parts of a polymer prepared by the method described in Synthesis Example 8, 7.5 parts of polymer prepared by the method described in Synthesis Example 9, 9 parts of PAC shown in structure (XIII O), 13 parts of PAC synthesized in Example 3, 125 parts propylene glycol methyl ether acetate (PGMEA) and 50 parts GBL and filtered to provide a photosensitive polybenzoxazole precursor composition.

A silicon wafer is then coated with the photosensitive polybenzoxazole precursor composition and hotplate baked for 4 minutes at 120° C., resulting in a film thickness of 10.0 μm. The film is then exposed at 500 mJ/cm² utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. No adhesion loss is observed.

### COMPARATIVE EXAMPLE 4

A positive acting photosensitive composition is prepared from 100 parts of a polymer prepared by the method described in Synthesis Example 8, 9 parts of PAC shown in structure (XIII O) (see above), 13 parts of PAC synthesized in Example 3, 125 parts propylene glycol methyl ether acetate (PGMEA) and 50 parts GBL and filtered to provide a photosensitive polybenzoxazole precursor composition.

A silicon wafer is then coated with the photosensitive polybenzoxazole precursor composition and hotplate baked for 4 minutes at 120° C., resulting in a film thickness of 10.0 μm. The film is then exposed at 500 mJ/cm² utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. Complete adhesion loss is observed.

### EXAMPLE 5

A positive acting photosensitive composition is prepared from 100 parts of a polymer prepared by the method described in Synthesis Example 7, 8 parts of polymer prepared by the method described in Synthesis Example 10, 125 parts GBL and 50 parts N-methyl-2-pyrrolidone (NMP) and filtered to provide a photosensitive polybenzoxazole precursor composition.

A silicon wafer is then coated with the photosensitive polybenzoxazole precursor composition and hotplate baked for 4 minutes at 120° C., resulting in a film thickness of 10.0 μm. The film is then exposed at 500 mJ/cm2 utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. No adhesion loss is observed.

### COMPARATIVE EXAMPLE 5

A positive acting photosensitive composition is prepared from 100 parts of a polymer prepared by the method described in Synthesis Example 7, 125 parts GBL and 50 parts N-methyl-2-pyrrolidone (NMP) and filtered to provide a photosensitive polybenzoxazole precursor composition.

A silicon wafer is then coated with the photosensitive polybenzoxazole precursor composition and hotplate baked for 4 minutes at 120° C., resulting in a film thickness of 10.0 μm. The film is then exposed at 500 mJ/cm2 utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. Complete adhesion loss is observed.

### EXAMPLE 6

100 parts of the polymer obtained in Synthesis Example 13, 10 parts of the polymer obtained in Synthesis Example 12, and 25 parts of PAC obtained in Synthesis Example 3 are dissolved in 175 parts GBL and filtered to provide a photosensitive polybenzoxazole precursor composition.

A silicon wafer is then coated with the photosensitive polybenzoxazole precursor composition and hotplate baked for 4 minutes at 120° C., resulting in a film thickness of 10.0 μm. The film is then exposed at 500 mJ/cm² utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. No adhesion loss is observed.

### COMPARATIVE EXAMPLE 6

100 parts of the polymer obtained in Synthesis Example 13, 10 parts of the polymer obtained in Synthesis Example 12, and 25 parts of PAC obtained in Synthesis Example 3 are dissolved in 175 parts GBL and filtered to provide a photosensitive polybenzoxazole precursor composition.

A silicon wafer is then coated with the photosensitive polybenzoxazole precursor composition and hotplate baked for 4 minutes at 120° C., resulting in a film thickness of 10.0 μm. The film is then exposed at 500 mJ/cm2 utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. Complete adhesion loss is observed.

Comparison of Example 6 and Comparative Example 6 shows that the polymer obtained from Synthesis Example 9 is surprisingly an effective adhesion promoter.

### EXAMPLE 7

100 parts by weight of the polymer obtained in Synthesis Example 4, 5 parts of polymer obtained in Synthetic Example 14, 5 parts of Bisphenol AF, 20 parts of PAC of structure (XIII f) were dissolved in 173 parts N-ethyl pyrrolidone (NEP) and filtered to provide a photosensitive polybenzoxazole precursor composition.

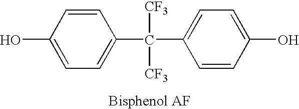

A silicon nitride-coated wafer was coated with the photosensitive polybenzoxazole precursor composition above at a spin speed of 3000 rpm for 55 seconds. The film was then softbaked twice on a hotplate at 135° C. for 45 seconds for each bake, resulting in a film thickness of 7.85 μm. The film was then exposed using a contact print broadband exposure with a patterned exposure gradient, including 30, 35, 40, 45, 50, 55, 60, 65, 80 & 100% transmittance. 100% transmittance exposure was equivalent to 400 mJ/cm². The film was then developed by immersion for 50 seconds in a 2.38% aqueous TMAH solution, rinsed three times with deionized water by immersion dip and dried by using nitrogen to provide a relief pattern. The exposure energy required to clear all the material from an exposed area (E₀) was 293 mJ/cm². The unexposed film thickness after development was 5.84 μm. The film was then cured for one hour at 300° C. in a vacuum oven with nitrogen purge, resulting in a film thickness of the unexposed area of 4.65 μm. The film was then exposed to a 50:1 HF solution for 10 seconds, inspected via optical microscope for any adhesion failure defects no failure was observed. The film was exposed again to the HF solution mentioned for one minute, re-inspected for adhesion failure defects and no failure was observed. Finally, a tape pull test using 3M-898 tape was conducted as described in ASTM-3359 and then the wafer was re-inspected for adhesion failure defects. No adhesion failure (i.e., less than about 0.1% of adhesion loss) was observed.

### EXAMPLE 8

A positive acting photosensitive composition was prepared by mixing 200 parts of a polymer solution prepared by the method described in Synthesis Example 16, 5 parts of a polymer prepared by the method described in Synthesis Example 11, 0.17 parts of 1,8-diazabicyclo[5.4.0]undec-7-ene (DBU), 5 parts of the phenolic speed enhancer shown below 5 parts of (5-propylsulfonyloxyimino-5H-thiophen-2-ylidene)-Z-methylphenyl-acetonitrile, 10 parts tripropylene glycol, 20 parts of additional PGMEA, and 30 parts GBL and filtered through a 0.2 μm Teflon filter.

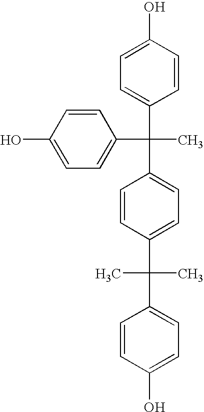

A silicon wafer was then coated with the photosensitive polybenzoxazole precursor composition and hotplate baked for 4 minutes at 120° C., resulting in a film thickness of 10.0 μm. The film was then exposed at 200 mJ/cm² utilizing a broadband exposure with a 10×10 pattern array of 2 mm squares and a 10×10 pattern array of 1 mm squares. The film was then developed using two 30 second puddle development steps with a 2.38% aqueous TMAH solution, rinsed with deionized water and dried to provide a relief pattern.

The resulting wafer pattern was then cured at 350° C. for one hour using a vacuum oven with nitrogen purge. The resulting cured relief pattern was then placed in a pressure cooker test apparatus at 2 atmosphere pressure and 121° C. for 1190 hours. The film was then subjected to a tape peel test using 3M-681 tape according to the procedure described in ASTM-3359. No adhesion loss was observed.

### EXAMPLE 9

Example 8 was repeated except this time 3M-898 tape was used. No adhesion lost was observed.

### EXAMPLE 10

A positive acting photosensitive composition was prepared by mixing 200 parts of a polymer solution prepared by the method described in Synthesis Example 16, 3 parts of a polymer prepared by the method described in Synthesis Example 11, 0.17 parts of 1,8-diazabicyclo[5.4.0]undec-7-ene (DBU), 5 parts of the phenolic speed enhancer shown below 5 parts of (5-propylsulfonyloxyimino-5H-thiophen-2-ylidene)-2-methylphenyl-acetonitrile, 10 parts tripropylene glycol, 20 parts of additional PGMEA, and 30 parts GBL and filtered through a 0.2 μm Teflon filter.

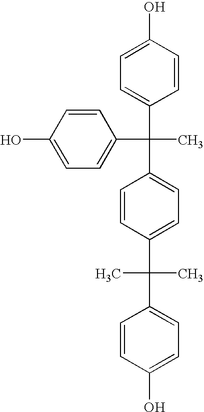

A silicon wafer was then coated with the photosensitive polybenzoxazole precursor composition and hotplate baked for 4 minutes at 120° C., resulting in a film thickness of 10.0 μm. The film was then exposed at 200 mJ/cm² utilizing a broadband exposure with a 10×10 pattern array of 2 mm squares and a 10×10 pattern array of 1 mm squares. The film was then developed using two 30 second puddle development steps with a 2.38% aqueous TMAH solution, rinsed with deionized water and dried to provide a relief pattern.

The resulting wafer pattern was then cured at 350° C. for one hour using a vacuum oven with nitrogen purge. The resulting cured relief pattern was then placed in a pressure cooker test apparatus at 2 atmosphere pressure and 121° C. for 607 hours. The film was then subjected to a tape peel test using 3M-681 tape according to the procedure described in ASTM-3359. No adhesion loss was observed.

### EXAMPLE 11

Example 10 was repeated except this time 3M-898 tape was used and total test time was 1190 hours. No adhesion lost was observed.

### COMPARATIVE EXAMPLE 7

A positive acting photosensitive composition was prepared by mixing 200 parts of a polymer solution prepared by the method described in Synthesis Example 15, 0.17 parts of 1,8-diazabicyclo[5.4.0]undec-7-ene (DBU), 5 parts of the phenolic speed enhancer shown below 5 parts of (5-propylsulfonyloxyimino-5H-thiophen-2-ylidene)-2-methylphenyl-acetonitrile, 10 parts tripropylene glycol, 20 parts of additional PGMEA, and 30 parts GBL and filtered through a 0.2 μm Teflon filter.

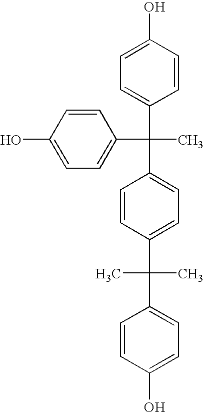

A silicon wafer was then coated with the photosensitive polybenzoxazole precursor composition and hotplate baked for 4 minutes at 120° C., resulting in a film thickness of 10.0 μm. The film was then exposed at 200 mJ/cm² utilizing a broadband exposure with a 10×10 pattern array of 2 mm squares and a 10×10 pattern array of 1 mm squares. The film was then developed using two 30 second puddle development steps with a 2.38% aqueous TMAH solution, rinsed with deionized water and dried to provide a relief pattern.

The resulting wafer pattern was then cured at 350° C. for one hour using a vacuum oven with nitrogen purge. The resulting cured relief pattern was then placed in a pressure cooker test apparatus at 2 atmosphere pressure and 121° C. for 321 hours. The film was then subjected to a tape peel test using 3M-581 tape according to the procedure described in ASTM-681. Complete adhesion loss was observed.

### COMPARATIVE EXAMPLE 8

Comparative Example 7 was repeated except this time 3M-898 tape was used. Complete adhesion loss was observed.

### EXAMPLE 12

A composition was obtained by mixing 100 parts of the polymer solution obtained in Synthesis Example 17 and 19.5 parts of a 10% solution of polymer obtained in Synthetic Example 11 in NMP and filtered to provide a non-photosensitive polyimide precursor composition.

The resin solution was spin coated onto silicon wafers and then dried on a hot plate for 3 minutes at 90° C. followed by a hotplate for 3 minutes at 120° C. In this way, 9 mm thick polymer layers of uniform thickness were obtained on the wafers. I-line photoresist OIR 907-17 obtained from Fujifilm Electronic materials was then spin coated onto the resin and then dried on a hotplate for 3 minutes at 90° C. The wafers were then exposed to broadband radiation illumination using a Karl Suss MA 56 contact exposure tool at 400 mJ/cm². After exposure, the image was developed by forming a puddle of 0.238 normal TMAH and water solution for 30 seconds two times. The wafers were then rinsed with DI Water for 30 seconds at 600 rpm. The wafers were then spun until they were dried. The photoresist was then removed by spinning the wafer at 1,500 rpm and spraying PGMEA for 60 seconds. The wafers were then spun dry. The wafers were then placed in a vacuum oven with nitrogen purge at 100° C. The oven was then ramped to 350° C. at 5° C./minute and held at that temperature for 1 hour. The oven was then cooled back to 100° C. The wafers were then removed form the oven.

The resulting image provided four 10×10 grids of pads of resin for adhesion tape testing. An adhesion test at time=0 was performed by taking Scotch 898, with a pull strength of 82N/100 mm width (75 oz./inch) was placed on one of the grids. The bubbles in the tape were then rubbed out with a pencil eraser. Then the tape was pulled off at a steady rate and at a 90° C. angle to the wafer. No adhesion failure was observed, by the fact that no pads lost adhesion. The wafers were then placed in a pressure cooker at 121° C. and 2 atmospheres of live steam for 1,045 hours. The adhesion test was then repeated on one of the other grids which had not been tested at time=0. No adhesion failure was observed, by the fact that no pads lost adhesion.

### EXAMPLE 13

The test described in Example 12 was repeated for a non-photosensitive composition obtained by mixing 100 parts of the polymer solution obtained in Synthesis Example 1 and 14.4 parts of a 10% solution of polymer obtained in Synthetic Example 11 in NMP. No adhesion lost was observed after the wafers were placed in a pressure cooker at 121° C. and 2 atmospheres of live steam for 1,045 hours.

### EXAMPLE 14

The test described in Example 12 was repeated for a non-photosensitive composition obtained by mixing 100 parts of the polymer solution obtained in Synthesis Example 1 and 9.0 parts of a 10% solution of polymer obtained in Synthetic Example 11 in NMP. No adhesion lost was observed after the wafers were placed in a pressure cooker at 121° C. and 2 atmospheres of live steam for 1045 hours.

### EXAMPLE 15

The test described in Example 12 was repeated for a non-photosensitive composition obtained by mixing 100 parts of the polymer solution obtained in Synthesis Example 17 and 5.4 parts of a 10% solution of polymer obtained in Synthetic Example 11 in NMP. No adhesion lost was observed after the wafers were placed in a pressure cooker at 121° C. and 2 atmospheres of live steam for 1045 hours.

### COMPARATIVE EXAMPLE 9

The test described in Example 12 was repeated for a non-photosensitive composition using only polymer solution obtained in Synthesis Example 17. After the wafers were placed in a pressure cooker at 121° C. and 2 atmospheres of live steam for only 140 hours 100% adhesion failure was observed.

### EXAMPLE 16

The test described in Example 12 was repeated for a non-photosensitive composition obtained by mixing 100 parts of the polymer solution obtained in Synthesis Example 18 and 12 parts of a 10% solution of polymer obtained in Synthetic Example 11 in NMP. No adhesion lost was observed after the wafers were placed in a pressure cooker at 121° C. and 2 atmospheres of live steam for 583 hours.

### EXAMPLE 17

The test described in Example 12 was repeated for a non-photosensitive composition obtained by mixing 100 parts of the polymer solution obtained in Synthesis Example 18 and 8 parts of a 10% solution of polymer obtained in Synthetic Example 11 in NMP. No adhesion lost was observed after the wafers were placed in a pressure cooker at 121° C. and 2 atmospheres of live steam for 583 hours.

### EXAMPLE 18

The test described in Example 12 was repeated for a non-photosensitive composition obtained by mixing 100 parts of the polymer solution obtained in Synthesis Example 18 and 4 parts of a 10% solution of polymer obtained in Synthetic Example 11 in NMP. No adhesion lost was observed after the wafers were placed in a pressure cooker at 121° C. and 2 atmospheres of live steam for 583 hours.

### COMPARATIVE EXAMPLE 10

The test described in Example 12 was repeated for a non-photosensitive composition using only polymer solution obtained in Synthesis Example 18. After the wafers were placed in a pressure cooker at 121° C. and 2 atmospheres of live steam for only 298 hours 94% adhesion failure was observed.

### EXAMPLE 19

100 parts of the polymer obtained in Synthesis Example 2, 8 part of polymer obtained in Synthetic Example 19, 4 parts of (3-glycidoxypropyl)-triethoxysilane, 7.5 parts of diphenylsilanediol, 11.5 parts of PAC synthesized in Synthesis Example 3 are dissolved in 100 parts GBL and 75 parts N-ethylpyrrolidone (NEP) and filtered to provide a photosensitive polybenzoxazole precursor composition.

A silicon wafer is then coated with the photosensitive polybenzoxazole precursor composition and hotplate baked for 4 minutes at 120° C., resulting in a film thickness of 10.0 μm. The film is then exposed at 500 mJ/cm² utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. No adhesion loss is observed.

### COMPARATIVE EXAMPLE 11

100 parts of the polymer obtained in Synthesis Example 2, 4 parts of (3-glycidoxypropyl)triethoxysilane, 7.5 parts of diphenylsilanediol, 11.5 parts of PAC synthesized in Synthesis Example 3 are dissolved in 100 parts GBL and 75 parts N-ethylpyrrolidone (NEP) and filtered to provide a photosensitive polybenzoxazole precursor composition.

A silicon wafer is then coated with the photosensitive polybenzoxazole precursor composition and hotplate baked for 4 minutes at 120° C., resulting in a film thickness of 10.0 μm. The film is then exposed at 500 mJ/cm² utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. Complete adhesion loss is observed.

Comparison of Example 19 and Comparative Example 11 shows that presence of 8 parts of polymer (VI*-a) in the photosensitive polybenzoxazole precursor composition greatly improves the HF resistance of the cured film. It also improves the film thickness retention after development.

### EXAMPLE 20

A positive acting photosensitive composition is prepared by mixing 100 parts of a polymer prepared by the method described in Synthesis Example 21, 4 parts of a polymer prepared by the method described in Synthesis Example 19, 0.12 parts of triethylamine, 5 parts of the photoacid generator shown below, 10 parts propylene carbonate, 75 parts of PGMEA, and 75 parts GBL and filters through a 0.2 μm Teflon filter.

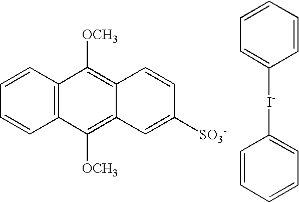

A silicon wafer is then coated with the photosensitive polybenzoxazole precursor composition and hotplate baked for 4 minutes at 120° C., resulting in a film thickness of 9.5 μm. The film is then exposed at 200 mJ/cm² utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 1000 hours. The film is then subjected to a tape peel test using 3M-681 tape according to the procedure described in ASTM-3359. No adhesion loss is observed.

### EXAMPLE 21

A positive acting photosensitive composition is prepared by mixing 200 parts of a polymer solution prepared by the method described in Synthesis Example 22, 6 parts of a polymer prepared by the method described in Synthesis Example 10, 0.2 parts of N-hydroxyethyl morpholine, 4 parts of the photoacid generator shown below, 9 parts tripropylene glycol mono methyl ether, 30 parts of PGMEA, and 25 parts GBL and filters through a 0.2 μm Teflon filter.

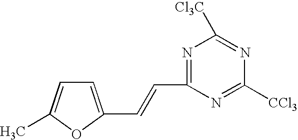

A silicon wafer is then coated with the photosensitive polybenzoxazole precursor composition and hotplate baked for 4 minutes at 120° C., resulting in a film thickness of 10.0 μm. The film is then exposed at 500 mJ/cm² utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. No adhesion loss is observed.

### EXAMPLE 22

A positive acting photosensitive composition is prepared by mixing 200 parts of a polymer solution prepared by the method described in Synthesis Example 23, 7.5 parts of a polymer prepared by the method described in Synthesis Example 12, 0.22 parts of di-t-butylamine, 3 parts of the photoacid generator shown below, 9 parts tripropylene glycol mono methyl ether, 30 parts of PGMEA, and 25 parts GBL and filters through a 0.2 μm Teflon filter.

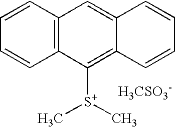

A silicon wafer is then coated with the photosensitive polybenzoxazole precursor composition and hotplate baked for 4 minutes at 120° C., resulting in a film thickness of 10.0 μm. The film is then exposed at 500 mJ/cm² utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. No adhesion loss is observed.

### EXAMPLE 23

A positive acting photosensitive composition is prepared by mixing 200 parts of a polymer solution prepared by the method described in Synthesis Example 24, 6.5 parts of a polymer prepared by the method described in Synthesis Example 10, 3 parts of the photoacid generator shown below, 12 parts tripropylene glycol, 28 parts of PGMEA, and 32 parts GBL and filters through a 0.2 μm Teflon filter.

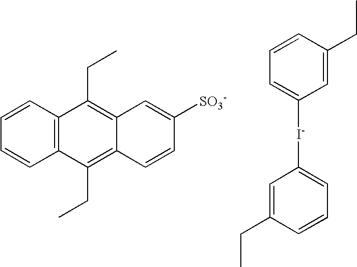

A silicon wafer is then coated with the photosensitive polybenzoxazole precursor composition and hotplate baked for 4 minutes at 120° C., resulting in a film thickness of 10.0 μm. The film is then exposed at 500 mJ/cm² utilizing a broadband exposure with a 10×10 pattern array of 2 mm squares and a 10×10 pattern array of 1 mm squares. The film is then developed using two 30 second puddle development steps with a 2.38% aqueous TMAH solution, rinsed with deionized water and dried to provide a relief pattern.

The resulting wafer pattern is then cured at 350° C. for one hour using a vacuum oven with nitrogen purge. The resulting cured relief pattern is then placed in a pressure cooker test apparatus at 2 atmosphere pressure and 121° C. for 250 hours. The film is then subjected to a tape peel test using 3M-581 tape according to the procedure described in ASTM-3359. No adhesion loss is observed.

We claim:

1. A composition, comprising:
(a) at least one polybenzoxazole precursor polymer; and
(b) at least one silicon-containing polymer comprising a moiety of Structure (V): 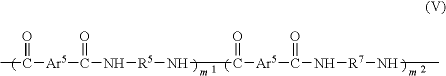
wherein
each R⁵ independently is 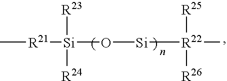
in which each R²¹ and each R²² independently are a divalent aliphatic or aromatic group, each R²³, each R²⁴, each R²⁵ and each R²⁶ independently are a monovalent aliphatic or aromatic group, and n is an integer of 1-100;
each R⁷ is a non-silicon containing divalent aromatic group, a non-silicon containing divalent aliphatic group, a non-silicon containing divalent heterocyclic group, or mixtures thereof;
each Ar⁵ is a divalent aromatic group, a divalent aliphatic group, a divalent heterocyclic group, or mixtures thereof, provided that Ar⁵ is not a divalent aromatic group substituted with a carboxylic acid group;
m¹ is an integer of 5-1000; and
m² is an integer of 0-500.

2. The composition of claim 1, wherein the silicon-containing polymer is of Structure (VI) or (VI*): 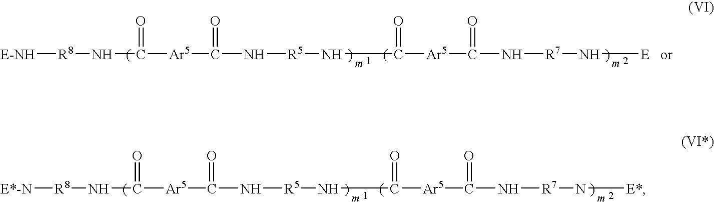
in which R⁸ is R⁵ or R⁷, E is a monovalent organic group, and E* is a divalent organic group.

3. The composition of claim 1, wherein the polybenzoxazole precursor polymer is of Structure (I), (II), (III), (III*), (IV), or (IV*): 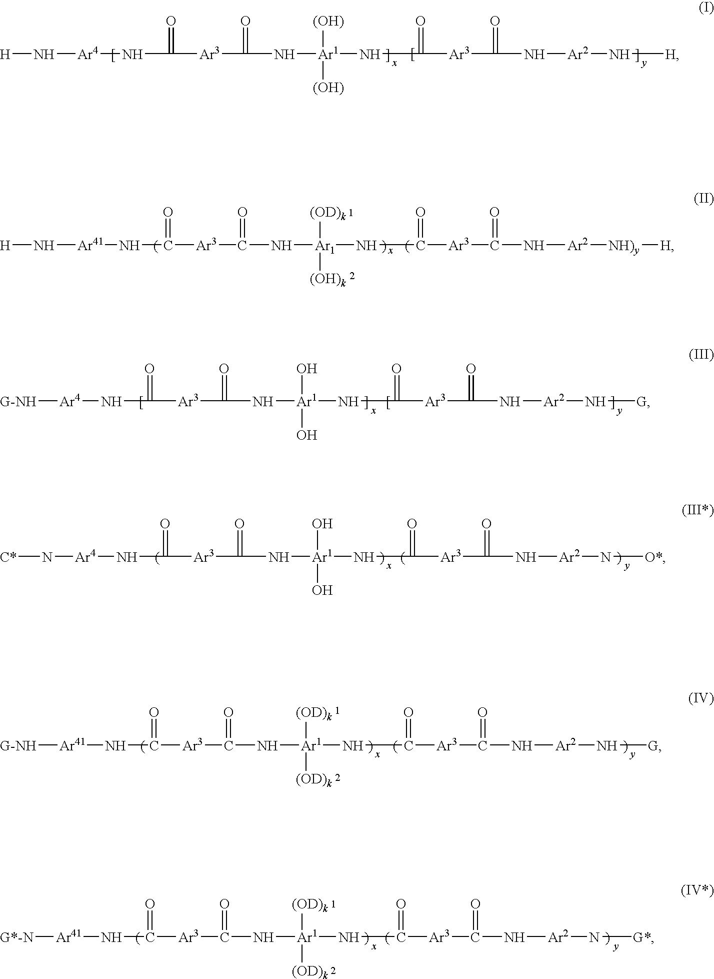
wherein
each Ar¹ independently is a tetravalent aromatic group, a tetravalent heterocyclic group, or mixtures thereof;
each Ar² independently is a divalent aromatic, divalent heterocyclic, divalent alicyclic, or divalent aliphatic group that optionally contains silicon;
each Ar³ independently is a divalent aromatic group, a divalent aliphatic group, a divalent heterocyclic group, or mixtures thereof;
Ar⁴ is Ar¹ (OH)₂ or Ar²;
Ar⁴¹ is Ar¹(OH)₂, Ar¹(OD)ₖ¹(OH)ₖ², or Ar²;
x is from about 4 to about 1000;
y is from 0 to about 900;
k¹ independently is a positive number of up to about 0.5;
k² independently is a number from about 1.5 to about 2 provided that (k¹+k²)=2;
G is a monovalent organic group having a carbonyl, carbonyloxy or sulfonyl group;
G* is a divalent organic group having at least one carbonyl or sulfonyl group; and
each D independently is one of the following moieties: 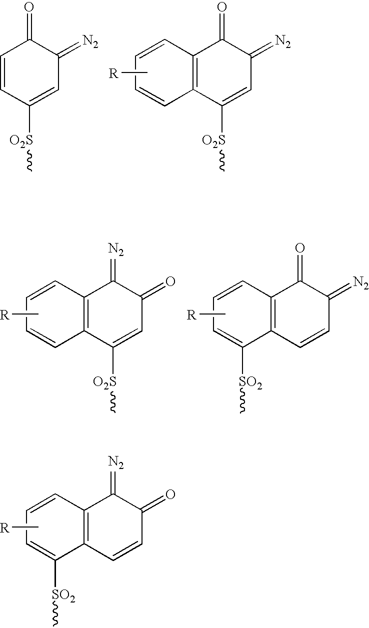
in which R is a hydrogen atom, a halogen, a C₁-C₄ alkyl group, a C₁-C₄ alkoxy group, cyclopentyl, or cyclohexyl.

4. The composition of claim 3, further comprising a diazonaphthquinone compound.

5. The composition of claim 4, further comprising a solvent.

6. The composition of claim 1, wherein the polybenzoxazole precursor polymer is of Structure (XV), (XVI), or (XVI*): 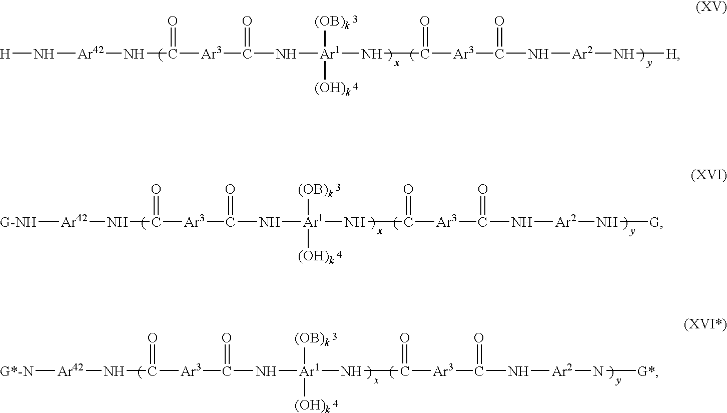
in which
each Ar¹ independently is a tetravalent aromatic group, a tetravalent heterocyclic group, or mixtures thereof;
each Ar² independently is a divalent aromatic, divalent heterocyclic, divalent alicyclic, or divalent aliphatic group that optionally contains silicon;
each Ar³ independently is a divalent aromatic group, a divalent aliphatic group, a divalent heterocyclic group, or mixtures thereof;
Ar⁴² is Ar¹(OB)ₖ³(OH)ₖ⁴ or Ar²;
x is an integer from about 4 to about 1000;
y is an integer from 0 to about 500 provided that x+y≦1000;
each B independently is an acid sensitive group R²⁷ or a moiety A-O—R²⁸, in which R²⁸ is an acid sensitive group; A is a divalent aromatic, aliphatic or heterocyclic group which is not acid labile and makes an -A-OH moiety an alkali solubilizing group;
k³ independently is a number between 0.1 and 2;
k⁴ independently is a number between 0 and 1.9 provided that k³+k⁴=2;
G is a monovalent organic group having a carbonyl, carbonyloxy or sulfonyl group; and
G* is a divalent organic group having at least one carbonyl or sulfonyl group.

7. The composition of claim 6, further comprising a photoacid generator compound.

8. The composition of claim 7, further comprising a solvent.

9. The composition of claim 1, wherein R²⁵ in one siloxane unit is different from R²⁵ in another siloxane unit or R²⁶ in one siloxane unit is different from R²⁶ in another siloxane unit.

10. The composition of claim 9, wherein R⁵ is

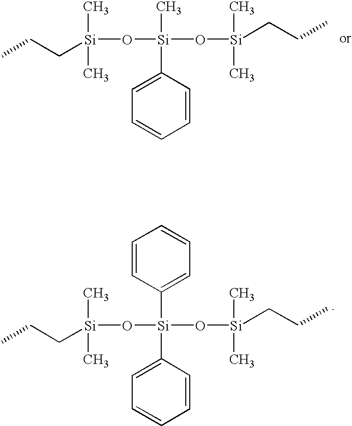

11. A method, comprising treating a composition of claim 1 on a substrate to form a relief image on the substrate.

12. The method of claim 11, wherein treating the composition comprises baking the composition to form a baked composition.

13. The method of claim 12, wherein treating the composition further comprises exposing the baked composition to actinic radiation to form an exposed composition.

14. The method of claim 13, wherein treating the composition further comprises developing the exposed composition with an aqueous developer, thereby forming an uncured relief image on the substrate.

15. The method of claim 14, wherein treating composition further comprises curing the uncured relief image.

16. An article, comprising:
a substrate; and
a buffer coat supported by the substrate;
wherein the buffer coat is prepared by a composition of claim 1.

17. The article of claim 16, wherein the article is a semiconductor device, a semiconductor chip, or an interlayer dielectric.

18. The article of claim 16, wherein the buffer coat has less than about 5% of adhesion loss when subjecting to a tape peel test according to the procedure described in ASTM-3359.

19. An article, comprising:
a substrate; and
a buffer coat supported by the substrate, the buffer coat comprising a polybenzoxazole polymer and a silicon-containing polymer;
wherein the buffer coat has less than about 5% of adhesion loss when subjecting to a tape peel test according to the procedure described in ASTM-3359.

20. The article of claim 19, wherein the article is a semiconductor device, a semiconductor chip, or an interlayer dielectric.

21. A composition, comprising:
(a) at least one polyamic acid; and
(b) at least one silicon-containing polymer comprising a moiety of Structure (V): 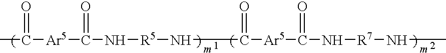
wherein
each R⁵ independently is 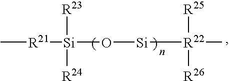
in which each R²¹ and each R²² independently are a divalent aliphatic or aromatic group, each R²³, each R²⁴, each R²⁵ and each R²⁶ independently are a monovalent aliphatic or aromatic group, and n is an integer of 1-100;
each R⁷ independently is a non-silicon containing divalent aromatic group, a non-silicon containing divalent aliphatic group, a non-silicon containing divalent heterocyclic group, or mixtures thereof;
each Ar⁵ independently is a divalent aromatic group, a divalent aliphatic group, a divalent heterocyclic group, or mixtures thereof;
m¹ is an integer of 5-1000; and
m² is an integer of 0-500.

22. The composition of claim 21, wherein the silicon-containing polymer is of Structure (VI) or (VI*): 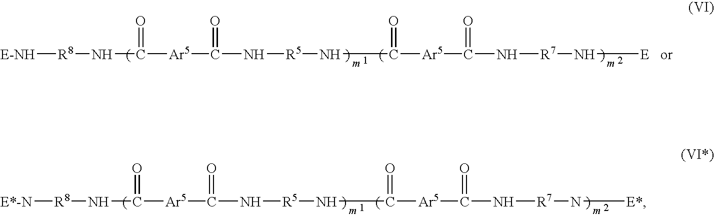
in which R⁸ is R⁵ or R⁷, E is a monovalent organic group, and E* is a divalent organic group.

23. A method, comprising treating a composition of claim 21 on a substrate to form a relief image on the substrate.

24. A polymer of Structure (VI) or (VI*): 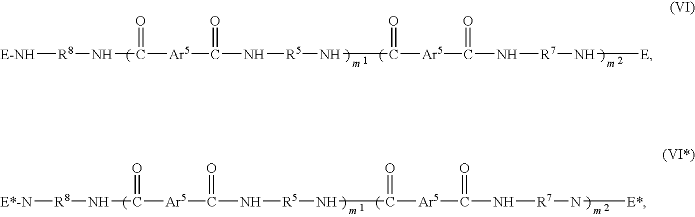
wherein
each R⁵ independently is 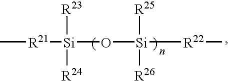
in which each R²¹ and each R²² independently are a divalent aliphatic or aromatic group, each R²³, each R²⁴, each R²⁵ and each R²⁶ independently are a monovalent aliphatic or aromatic group, and n is an integer of 1-100;
each R⁷ independently is a non-silicon containing divalent aromatic group, a non-silicon containing divalent aliphatic group, a non-silicon containing divalent heterocyclic group, or mixtures thereof;
R⁸ is R⁵ or R⁷;
each Ar⁵ independently is a divalent aromatic group, a divalent aliphatic group, a divalent heterocyclic group, or mixtures thereof;
E is a monovalent organic group;
E* is a divalent organic group;
m¹ is an integer of 5-1000; and
m² is an integer of 0-500.

25. The polymer of claim 24, wherein E is a carbonyl, carbonyloxy, or sulfonyl group.

26. The polymer of claim 24, wherein E*, together with the nitrogen atom to which it is attached, is an imide group.

27. A composition, comprising:
(a) at least one polybenzoxazole precursor polymer; and
(b) at least one silicon-containing polymer of Structure (VI) or (VI*): 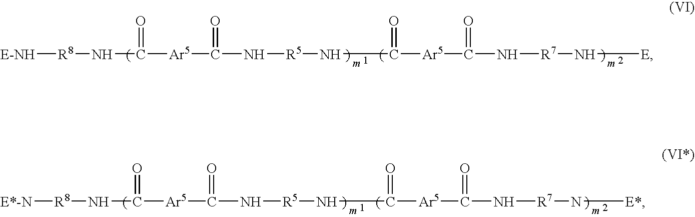
wherein
each R⁵ independently is 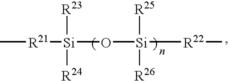
in which each R²¹ and each R²² independently are a divalent aliphatic or aromatic group, each R²³, each R²⁴, each R²⁵ and each R²⁶ independently are a monovalent aliphatic or aromatic group, and n is an integer of 1-100;
each R⁷ is a non-silicon containing divalent aromatic group, a non-silicon containing divalent aliphatic group, a non-silicon containing divalent heterocyclic group, or mixtures thereof;
each Ar⁵ is a divalent aromatic group, a divalent aliphatic group, a divalent heterocyclic group, or mixtures thereof;
E is a monovalent organic group;
E* is a divalent organic group;
m¹ is an integer of 5-1000; and
m² is an integer of 0-500.

28. The composition of claim 27, wherein the polybenzoxazole precursor polymer is of Structure (I), (II), (III), (III*), (IV), or (IV*); 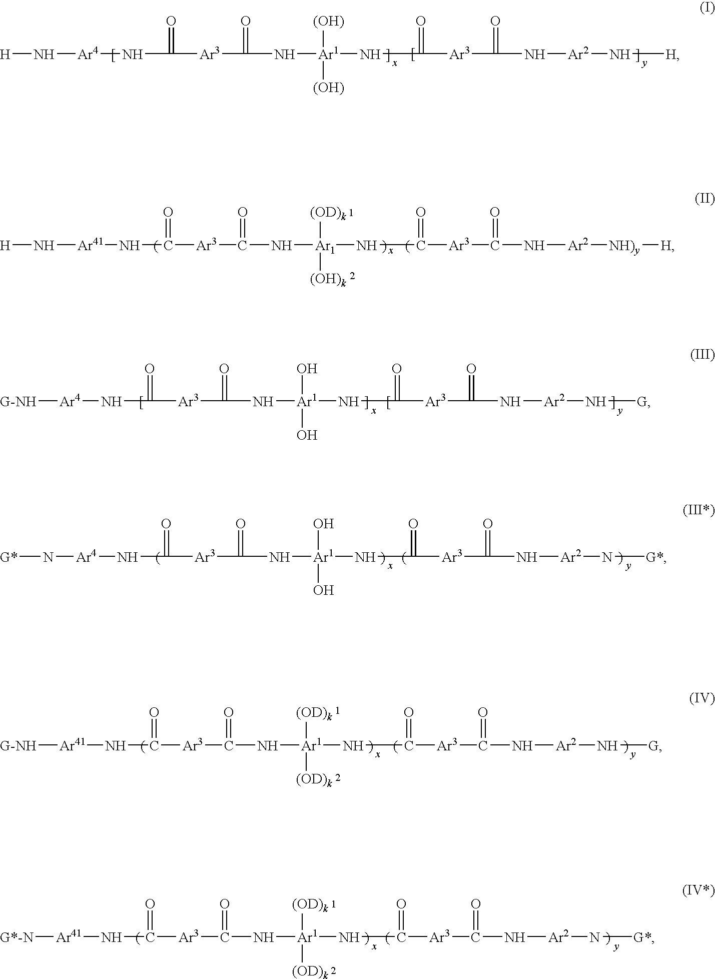
wherein
each Ar¹ independently is a tetravalent aromatic group, a tetravalent heterocyclic group, or mixtures thereof;
each Ar² independently is a divalent aromatic, divalent heterocyclic, divalent alicyclic, or divalent aliphatic group that optionally contains silicon;
each Ar³ independently is a divalent aromatic group, a divalent aliphatic group, a divalent heterocyclic group, or mixtures thereof;
Ar⁴ is Ar¹(OH)₂ or Ar²;
Ar⁴¹ is Ar¹(OH)₂, Ar¹(OD)ₖ¹(OH)ₖ², or Ar²;
x is from about 4 to about 1000;
y is from 0 to about 900;
k¹ independently is a positive number of up to about 0.5;
k² independently is a number from about 1.5 to about 2 provided that (k¹+k²)=2;
G is a monovalent organic group having a carbonyl, carbonyloxy or sulfonyl group;
G* is a divalent organic group having at least one carbonyl or sulfonyl group; and
each D independently is one of the following moieties: 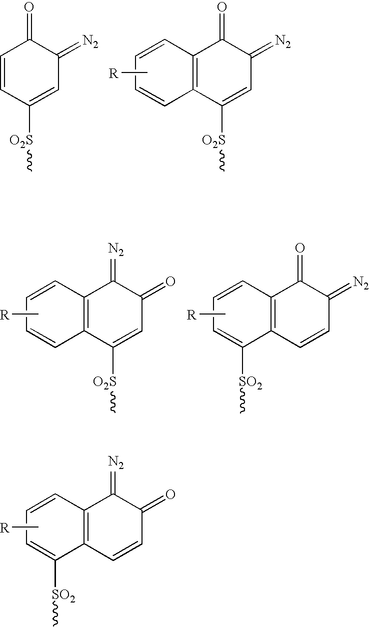
in which R is a hydrogen atom, a halogen, a C₁-C₄ alkyl group, a C₁-C₄ alkoxy group, cyclopentyl, or cyclohexyl.

29. The composition of claim 28, further comprising a diazonaphthquinone compound.

30. The composition of claim 29, further comprising a solvent.

31. The composition of claim 27, wherein the polybenzoxazole precursor polymer is of Structure (XV), (XVI), or (XVI*): 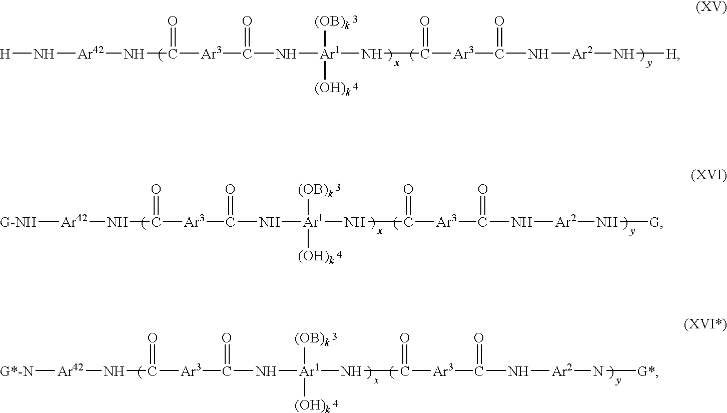
in which
each Ar¹ independently is a tetravalent aromatic group, a tetravalent heterocyclic group, or mixtures thereof;
each Ar² independently is a divalent aromatic, divalent heterocyclic, divalent alicyclic, or divalent aliphatic group that optionally contains silicon;
each Ar³ independently is a divalent aromatic group, a divalent aliphatic group, a divalent heterocyclic group, or mixtures thereof;
Ar⁴² is Ar¹(OB)ₖ³(OH)ₖ⁴ or Ar²;
x is an integer from about 4 to about 1000;
y is an integer from 0 to about 500 provided that x+y≦1000;
each B independently is an acid sensitive group R²⁷ or a moiety A-O—R²⁸, in which R²⁸ is an acid sensitive group; A is a divalent aromatic, aliphatic or heterocyclic group which is not acid labile and makes an -A-OH moiety an alkali solubilizing group;
k³ independently is a number between 0.1 and 2;
k⁴ independently is a number between 0 and 1.9 provided that k³+k⁴=2;
G is a monovalent organic group having a carbonyl, carbonyloxy or sulfonyl group; and
G* is a divalent organic group having at least one carbonyl or sulfonyl group.

32. The composition of claim 31, further comprising a photoacid generator compound.

33. The composition of claim 32, further comprising a solvent.

34. The composition of claim 27, wherein R²⁵ in one siloxane unit is different from R²⁵ in another siloxane unit or R²⁶ in one siloxane unit is different from R²⁶ in another siloxane unit.

35. The composition of claim 34, wherein R⁵ is

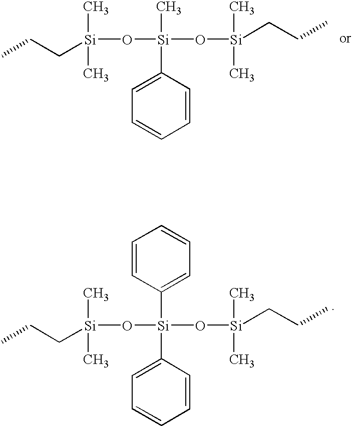

36. A method, comprising treating a composition of claim 27 on a substrate to form a relief image on the substrate.

37. The method of claim 36, wherein treating the composition comprises baking the composition to form a baked composition.

38. The method of claim 37, wherein treating the composition further comprises exposing the baked composition to actinic radiation to form an exposed composition.

39. The method of claim 38, wherein treating the composition further comprises developing the exposed composition with an aqueous developer, thereby forming an uncured relief image on the substrate.

40. The method of claim 39, wherein treating composition further comprises curing the uncured relief image.

41. An article, comprising:
a substrate; and
a buffer coat supported by the substrate,
wherein the buffer coat is prepared by a composition of claim 27.

42. The article of claim 41, wherein the article is a semiconductor device, a semiconductor chip, or an interlayer dielectric.

43. The article of claim 41, wherein the buffer coat has less than about 5% of adhesion loss when subjecting to a tape peel test according to the procedure described in ASTM-3359.

44. A composition, comprising:
(a) at least one polybenzoxazole precursor polymer of Structure (XV), (XVI), or (XVI*): 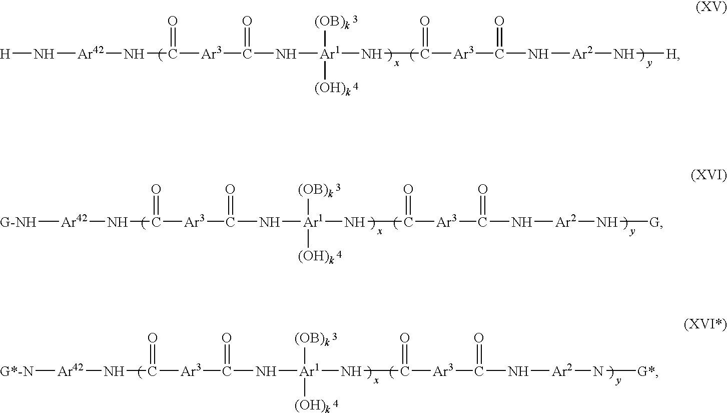
wherein
each Ar¹ independently is a tetravalent aromatic group, a tetravalent heterocyclic group, or mixtures thereof;
each Ar² independently is a divalent aromatic, divalent heterocyclic, divalent alicyclic, or divalent aliphatic group that optionally contains silicon;
each Ar³ independently is a divalent aromatic group, a divalent aliphatic group, a divalent heterocyclic group, or mixtures thereof;
Ar⁴² is Ar¹(OB)ₖ³(OH)ₖ⁴ or Ar²;
x is an integer from about 4 to about 1000;
y is an integer from 0 to about 500 provided that x+y≦1000;
each B independently is an acid sensitive group R²⁷ or a moiety A-O—R²⁸, in which R²⁸ is an acid sensitive group; A is a divalent aromatic, aliphatic or heterocyclic group which is not acid labile and makes an -A-OH moiety an alkali solubilizing group;
k³ independently is a number between 0.1 and 2;
k⁴ independently is a number between 0 and 1.9 provided that k³+k⁴=2;
G is a monovalent organic group having a carbonyl, carbonyloxy or sulfonyl group; and
G* is a divalent organic group having at least one carbonyl or sulfonyl group; and
(b) at least one silicon-containing polymer comprising a moiety of Structure (V): 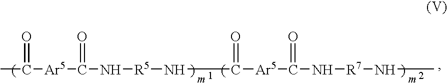
wherein
each R⁵ independently is 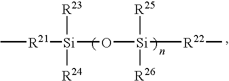
in which each R²¹ and each R²² independently are a divalent aliphatic or aromatic group, each R²³, each R²⁴, each R²⁵ and each R²⁶ independently are a monovalent aliphatic or aromatic group, and n is an integer of 1-100;
each R⁷ is a non-silicon containing divalent aromatic group, a non-silicon containing divalent aliphatic group, a non-silicon containing divalent heterocyclic group, or mixtures thereof;
each Ar⁵ is a divalent aromatic group, a divalent aliphatic group, a divalent heterocyclic group, or mixtures thereof;
m¹ is an integer of 5-1000; and
m² is an integer of 0-500.

45. The composition of claim 44, wherein the silicon-containing polymer is of Structure (VI) or (VI*): 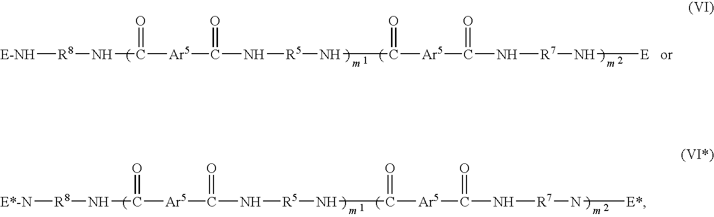
in which R⁸ is R⁵ or R⁷, E is a monovalent organic group, E* is a divalent organic group.

46. The composition of claim 45, further comprising a photoacid generator compound.

47. The composition of claim 46, further comprising a solvent.

48. The composition of claim 44, wherein R²⁵ in one siloxane unit is different from R²⁵ in another siloxane unit or R²⁶ in one siloxane unit is different from R²⁶ in another siloxane unit.

49. The composition of claim 48, wherein R⁵ is

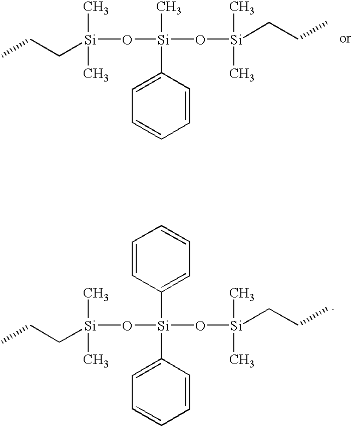

50. A method, comprising treating a composition of claim 44 on a substrate to form a relief image on the substrate.

51. The method of claim 50, wherein treating the composition comprises baking the composition to form a baked composition.

52. The method of claim 51, wherein treating the composition further comprises exposing the baked composition to actinic radiation to form an exposed composition.

53. The method of claim 52, wherein treating the composition further comprises developing the exposed composition with an aqueous developer, thereby forming an uncured relief image on the substrate.

54. The method of claim 53, wherein treating composition further comprises curing the uncured relief image.

55. An article, comprising:
a substrate; and
a buffer coat supported by the substrate,
wherein the buffer coat is prepared by a composition of claim 44.

56. The article of claim 55, wherein the article is a semiconductor device, a semiconductor chip, or an interlayer dielectric.

57. The article of claim 55, wherein the buffer coat has less than about 5% of adhesion loss when subjecting to a tape peel test according to the procedure described in ASTM-3359.
